(19) United States
(12) Patent Application Publication
(10) Pub. No.: US 2024/0334724 A1
(43) Pub. Date: Oct. 3, 2024

(54) ORGANIC COMPOUND AND ORGANIC LIGHT EMITTING ELEMENT

(71) Applicant: CANON KABUSHIKI KAISHA, Tokyo (JP)

(72) Inventors: NAOKI YAMADA, Tokyo (JP); JUN KAMATANI, Tokyo (JP); HIROKAZU MIYASHITA, Miyagi (JP); YOSUKE NISHIDE, Kanagawa (JP); HIRONOBU IWAWAKI, Kanagawa (JP)

(21) Appl. No.: 18/664,095

(22) Filed: May 14, 2024

Related U.S. Application Data
(63) Continuation of application No. PCT/JP2022/040369, filed on Oct. 28, 2022.

(30) Foreign Application Priority Data
Nov. 15, 2021 (JP) 2021-185519

(51) Int. Cl. H10K 50/12; C09K 11/06; H10K 85/30

(52) U.S. Cl. CPC H10K 50/121; C09K 11/06; H10K 85/342; C09K 2211/1033; C09K 2211/1037; C09K 2211/185

(57) ABSTRACT

An organic light emitting element including an anode, a light emitting layer, and a cathode in this order, in which the light emitting layer contains a dopant material and a host material, the dopant material is a compound represented by General Formula [1], and the host material is a hydrocarbon.

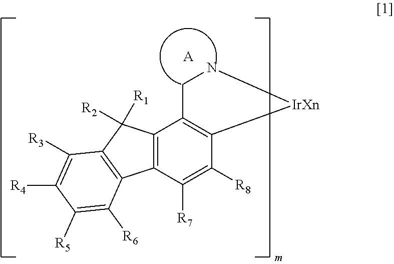

R₁ to R₈ are each independently selected from the group consisting of a hydrogen atom, an alkyl group, and the like, where R₁ to R₈ do not represent a cyano group, m represents an integer of 1 or greater and 3 or less, and n represents an integer of 0 or greater and 2 or less, where m+n is 3, and X represents a bidentate ligand.

### CROSS-REFERENCE TO RELATED APPLICATIONS

This application is a Continuation of International Patent Application No. PCT/JP2022/040369, filed Oct. 28, 2022, which claims the benefit of Japanese Patent Application No. 2021-185519, filed Nov. 15, 2021, both of which are hereby incorporated by reference herein in their entirety.

### TECHNICAL FIELD

The present disclosure relates to an organic compound and an organic light emitting element formed of the organic compound.

### BACKGROUND ART

An organic light emitting element (hereinafter, also referred to as “organic electroluminescence element” or “organic EL element”) is an electron element including a pair of electrodes and an organic compound layer disposed between these electrodes. When electrons and positive holes are injected from the pair of these electrodes, excitons of a luminescent organic compound in the organic compound layer are generated, and the organic light emitting element emits light in a case where the excitons return to a ground state. The recent progress in organic light emitting elements is remarkable, and the organic light emitting elements have characteristics such as a low drive voltage, various emission wavelengths, high-speed responsiveness, and an ability to make light emitting devices thinner and lighter.

Examples of a light emitting element with high efficiency include an element obtained by using a material with high efficiency such as a phosphorescent material. PTL 1 describes the following compound A-1. PTL 2 describes an organic light emitting element obtained by using the following compound A-2 as a light emitting dopant and the following compound B-1 as a host material. PTLs 3 and 4 describe iridium complexes obtained by using ligands represented by the following compounds C-1 and C-2. Further, PTL 5 describes an organic light emitting element obtained by using the following compound B-2 as a host material.

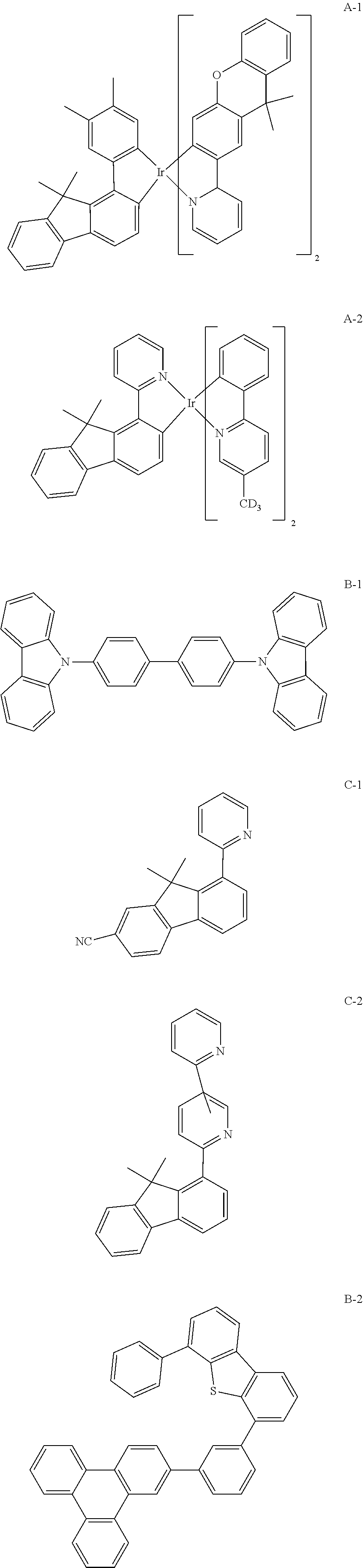

### CITATION LIST

### Patent Literature

PTL 1 Chinese Patent Application Publication No.
PTL 2 Chinese Patent Application Publication No. 111690016
PTL 3 Japanese Patent Laid-Open No. 2020-125289
PTL 4 Japanese Patent Laid-Open No. 2016-104722
PTL 5 Japanese Patent Laid-Open No. 2018-172366

In a case where the compound A-1 described in PTL 1 is used in a light emitting layer of an organic light emitting element, a disadvantage occurs in emission efficiency due to the relationship between the compound A-1 and the host material. Further, the organic light emitting elements described in PTLs 2 and 5 and organic light emitting elements formed of the iridium complexes described in PTLs 3 and 4 have disadvantages in emission efficiency.

### SUMMARY OF INVENTION

The present disclosure has been made in consideration of the above-described disadvantages, and an object thereof is to provide an organic light emitting element with high color purity and excellent emission efficiency.

According to the present disclosure, there is provided an organic light emitting element including at least: an anode; a light emitting layer; and a cathode in this order, in which the light emitting layer contains at least a dopant material and a host material, the dopant material is a compound represented by General Formula [1], and the host material is a hydrocarbon.

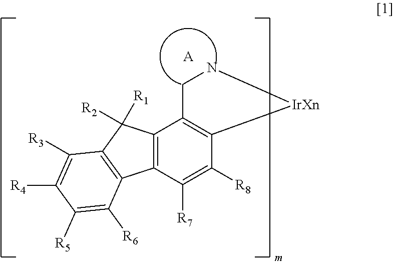

In Formula [1], R₁ to R₈ are each independently selected from the group consisting of a hydrogen atom, a deuterium atom, a substituted or unsubstituted alkyl group, a substituted or unsubstituted silyl group, and a substituted or unsubstituted aryl group. Here, R₁ to R₈ do not represent a cyano group.

m represents an integer of 1 or greater and 3 or less, and n represents an integer of 0 or greater and 2 or less. Here, m+n is 3.

X represents a bidentate ligand, and a partial structure IrX is any one of structures represented by General Formulae [2] and [3].

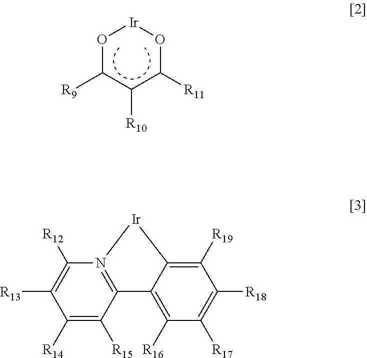

In Formulae [2] and [3], R₉ to R₁₉ are each independently selected from the group consisting of a hydrogen atom, a deuterium atom, a halogen atom, a cyano group, a substituted or unsubstituted alkyl group, a substituted or unsubstituted alkoxy group, a substituted or unsubstituted silyl group, a substituted or unsubstituted aryl group, and a substituted or unsubstituted heterocyclic group. R₁₆ to R₁₉ adjacent to each other may be bonded to each other to form a ring.

A ring A has any one of structures represented by General Formulae [4] to [7].

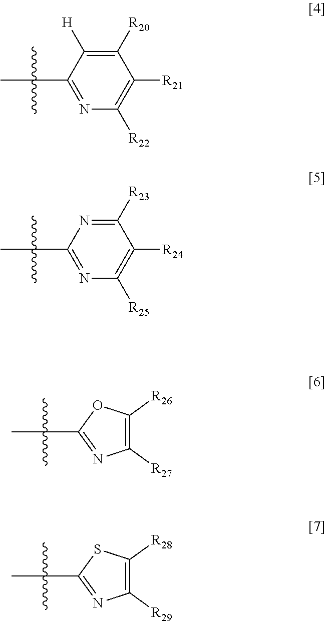

In Formulae [4] to [7], R₂₀ to R₂₉ are each independently selected from the group consisting of a group, a substituted or unsubstituted alkyl group, a substituted or unsubstituted alkoxy group, a substituted or unsubstituted silyl group, and a substituted or unsubstituted aryl group.

Further, the organic compound of the present disclosure is represented by General Formula [1].

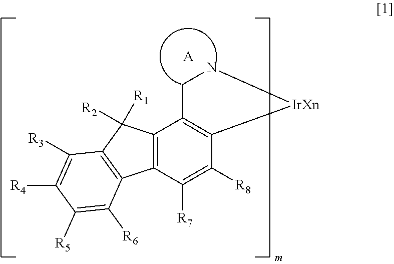

In Formula [1], R₁ to R₈ are each independently selected from the group consisting of a hydrogen atom, a deuterium atom, a substituted or unsubstituted alkyl group, a substituted or unsubstituted silyl group, and a substituted or unsubstituted aryl group. Here, at least one of R₁ to R₈ represents a tertiary alkyl group.

m represents an integer of 1 or greater and 3 or less, and n represents an integer of 0 or greater and 2 or less. Here, m+n is 3.

X represents a bidentate ligand, and a partial structure IrX is any one of structures represented by General Formulae [2] and [3].

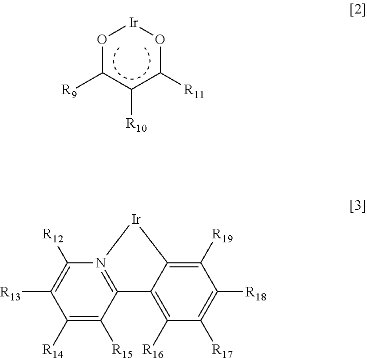

In Formulae [2] and [3], R₉ to R₁₉ are each independently selected from the group consisting of a hydrogen atom, a deuterium atom, a halogen atom, a cyano group, a substituted or unsubstituted alkyl group, a substituted or unsubstituted alkoxy group, a substituted or unsubstituted silyl group, a substituted or unsubstituted aryl group, and a substituted or unsubstituted heterocyclic group. R₁₆ to R₁₉ adjacent to each other may be bonded to each other to form a ring.

The ring A has any one of structures represented by General Formulae [4] to [7].

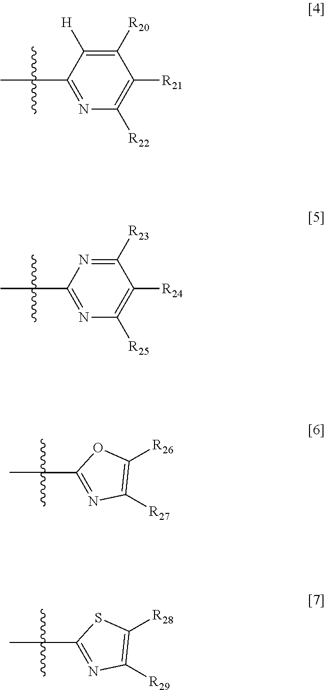

In Formulae [4] to [7], R₂₀ to R₂₉ are each independently selected from the group consisting of a hydrogen atom, a deuterium atom, a halogen atom, a cyano group, a substituted or unsubstituted alkyl group, a substituted or unsubstituted alkoxy group, a substituted or unsubstituted silyl group, and a substituted or unsubstituted aryl group.

Further features of the present disclosure will become apparent from the following description of exemplary embodiments with reference to the attached drawings.

### BRIEF DESCRIPTION OF DRAWINGS

FIG. 1A is a view showing features of an organic compound according to the present disclosure.

FIG. 1B is a view showing features of an organic compound according to the present disclosure.

FIG. 2A is a schematic cross-sectional view showing an example of pixels of a display device according to an embodiment of the present disclosure.

FIG. 2B is a schematic cross-sectional view showing an example of a display device formed of an organic light emitting element according to an embodiment of the present disclosure.

FIG. 3 is a schematic view showing an example of a display device according to an embodiment of the present disclosure.

FIG. 4A is a schematic view showing an example of an imaging device according to an embodiment of the present disclosure.

FIG. 4B is a schematic view showing an example of an electronic device according to an embodiment of the present disclosure.

FIG. 5A is a schematic view showing an example of a display device according to an embodiment of the present disclosure.

FIG. 5B is a schematic view showing an example of a foldable display device.

FIG. 6A is a schematic view showing an example of a lighting device according to an embodiment of the present disclosure.

FIG. 6B is a schematic view showing an example of a moving body that includes a lamp for a vehicle according to an embodiment of the present disclosure.

FIG. 7A is a schematic view showing an example of a wearable device according to an embodiment of the present disclosure.

FIG. 7B is a schematic view showing another example of a wearable device according to an embodiment of the present disclosure.

FIG. 8A is a schematic view showing an example of an image forming apparatus according to an embodiment of the present disclosure.

FIG. 8B is a schematic view showing an example of an exposure light source of the image forming apparatus according to an embodiment of the present disclosure.

FIG. 8C is a schematic view showing an example of an exposure light source of the image forming apparatus according to an embodiment of the present disclosure.

### DESCRIPTION OF EMBODIMENTS

### (1) Organic Compound and Dopant Material of Present Disclosure

An organic compound and a dopant material of the present disclosure are compounds represented by General Formula [1]. The organic compound of the present disclosure is a compound in which at least one of R₁ to R₈ represents a tertiary alkyl group, and the dopant material of the present disclosure is a compound in which R₁ to R₈ do not represent a cyano group. Further, in the present specification, a coordinate bond is indicated by a straight line or an arrow.

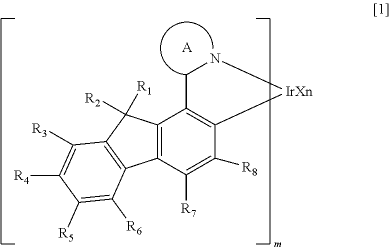

<R₁ to R₈>

In Formula [1], R₁ to R₈ are each independently selected from the group consisting of a hydrogen atom, a deuterium atom, a substituted or unsubstituted alkyl group, a substituted or unsubstituted silyl group, and a substituted or unsubstituted aryl group. Here, in the organic compound of the present embodiment, at least one of R₁ to R₈ represents a tertiary alkyl group. Further, in the dopant material of the present embodiment, R₁ to R₈ do not represent a cyano group.

Examples of the alkyl group include a methyl group, an ethyl group, a normal propyl group, an isopropyl group, a normal butyl group, a tertiary butyl group, a secondary butyl group, an octyl group, a cyclohexyl group, a tertiary pentyl group, a 3-methylpentan-3-yl group, a 1-adamantyl group, and a 2-adamantyl group, but the present disclosure is not limited thereto. An alkyl group having 1 or more and 10 or less carbon atoms is preferable as the alkyl group.

Examples of the silyl group include a trimethylsilyl group and a triphenylsilyl group, but the present disclosure is not limited thereto.

Examples of the aryl group include a phenyl group, a naphthyl group, an indenyl group, a biphenyl group, a terphenyl group, a fluorenyl group, a phenanthryl group, a triphenylenyl group, a pyrenyl group, an anthranyl group, a perylenyl group, a chrysenyl group, and a fluoranthenyl group, but the present disclosure is not limited thereto. An aryl group having 6 or greater and 30 or less carbon atoms is preferable as the aryl group.

Examples of the substituent that the alkyl group, the silyl group, or the aryl group may further have include a deuterium atom, an alkyl group such as a methyl group, an ethyl group, a normal propyl group, an isopropyl group, a normal butyl group, or a tertiary butyl group, an aralkyl group such as a benzyl group, an aryl group such as a phenyl group or a biphenyl group, a hydroxy group, and a thiol group, but the present disclosure is not limited thereto.

In the organic compound of the present embodiment, it is preferable that R₁ to Ra do not represent a cyano group. Further, in the dopant material of the present embodiment, it is preferable that at least one of R₁ to R₈ represent a tertiary alkyl group.

In the organic compound and the dopant material of the present embodiment, it is preferable that at least one of R₁ and R₈ represent a tertiary butyl group.

<m and n>

In Formula [1], m represents an integer of 1 or greater and 3 or less, and n represents an integer of 0 or greater and 2 or less. Here, m+n is 3. When m represents 2 or greater, a plurality of ligands may be the same as or different from each other. When n represents 2, a plurality of X's may be the same as or different from each other.

### <X>

In Formula [1], X represents a bidentate ligand, and a partial structure IrX is any one of structures represented by General Formulae [2] and [3].

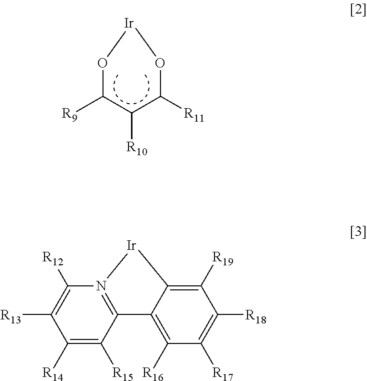

[R₉ to R₁₉]

In Formulae [2] and [3], R₉ to R₁₉ are each independently selected from the group consisting of a group, a substituted or unsubstituted alkyl group, a substituted or unsubstituted alkoxy group, a substituted or unsubstituted silyl group, a substituted or unsubstituted aryl group, and a substituted or unsubstituted heterocyclic group.

Examples of the halogen atom include fluorine, chlorine, bromine, and iodine, but the present disclosure is not limited thereto.

Examples of the alkoxy group include a methoxy group, an ethoxy group, an isopropoxy group, and a tertiary butoxy group, but the present disclosure is not limited thereto. An alkoxy group having 1 or greater and 10 or less carbon atoms is preferable as the alkoxy group.

Examples of the heterocyclic group include a pyridyl group, a pyrimidyl group, a pyrazyl group, a triazyl group, a benzofuranyl group, a benzothiophenyl group, a dibenzofuranyl group, a dibenzothiophenyl group, an oxazolyl group, an oxadiazolyl group, a thiazolyl group, a thiadiazolyl group, a carbazolyl group, an acridinyl group, a phenanthrolyl group, and a thienyl group, but the present disclosure is not limited thereto. A heterocyclic group having 3 or more and 27 or less carbon atoms is preferable as the heterocyclic group.

Specific examples of the alkyl group, the silyl group, and the aryl group represented by R₉ to R₁₉ include the same groups as described in the section of R₁ to R₈, but the present disclosure is not limited thereto. An alkyl group having 1 or more and 10 or less carbon atoms is preferable as the alkyl group. An aryl group having 6 or more and 30 or less carbon atoms is preferable as the aryl group. Further, specific examples of the substituent that the alkyl group, the alkoxy group, the silyl group, the aryl group, or the heterocyclic group may further have include the same substituents that the alkyl group, the silyl group, or the aryl group may further have, which have been described in the section of R₁ to R₈, but the examples are not limited thereto.

Further, R₁₆ to R₁₉ adjacent to each other may be bonded to each other to form a ring. The expression “R₁₆ to R₁₉ adjacent to each other may be bonded to each other to form a ring” denotes that a ring formed by R₁₆ and R₁₇, R₁₇ and R₁₈, and R₁₈ and R₁₉ being bonded to each other and a benzene ring formed by R₁₆ to R₁₉ being bonded to each other form a fused ring. The ring formed by adjacent R₁₆ to R₁₉ being bonded to each other may be an aromatic ring.

In the organic compound and the dopant material of the present embodiment, the partial structure IrX is a structure represented by General Formula [3], and it is preferable that R₁₂ to R₁₉ be each independently selected from the group consisting of a hydrogen atom, a deuterium atom, a substituted or unsubstituted alkyl group, and a substituted or unsubstituted silyl group. Further, at least one of R₉ to R₁ or at least one of R₁₂ to R₁₉ represents a tertiary alkyl group and preferably a tertiary butyl group.

### <A>

The ring A has any one of structures represented by General Formulae [4] to [7].

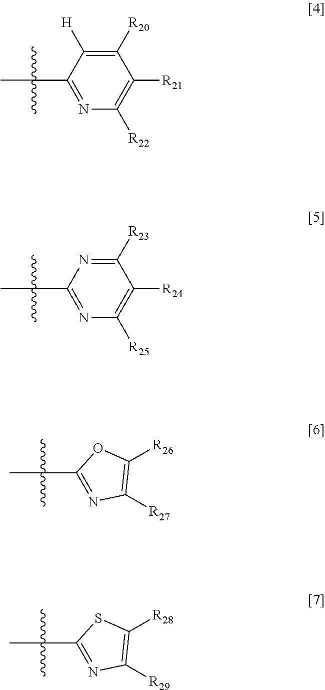

[R₂₀ to R₂₉]

In Formulae [4] to [7], R₂₀ to R₂₉ are each independently selected from the group consisting of a hydrogen atom, a deuterium atom, a halogen atom, a cyano group, a substituted or unsubstituted alkyl group, a substituted or unsubstituted alkoxy group, a substituted or unsubstituted silyl group, and a substituted or unsubstituted aryl group.

Specific examples of the halogen atom, the alkyl group, the alkoxy group, the silyl group, and the aryl group represented by R₂₀ to R₂₉ include the same groups as described in the section of R₉ to R₁₉, but the present disclosure is not limited thereto. An alkyl group having 1 or more and 10 or less carbon atoms is preferable as the alkyl group. An alkoxy group having 1 or more and 10 or less carbon atoms is preferable as the alkoxy group. An aryl group having 6 or more and 30 or less carbon atoms is preferable as the aryl group. Further, specific examples of the substituent that the alkyl group, the alkoxy group, the silyl group, or the aryl group may further have include the same substituents that the alkyl group, the silyl group, or the aryl group may further have, which have been described in the section of R₁ to R₈, but the examples are not limited thereto.

In the organic compound and the dopant material of the present embodiment, it is preferable that the ring A have a structure represented by General Formula [4] and R₂₀ represent a tertiary butyl group.

### Features

The compound represented by General Formula [1] according to the present embodiment has the following features.
(1-1) Since the ligand has a fluorene ring to which the ring A is bonded at the 1-position, the half width of the emission spectrum is narrow and the compound exhibits light emission with high color purity.
(1-2) Since the ligand has a fluorene ring, the positive hole transport property is high.
(1-3) R₁ to R₈ do not represent a group with high polarity.

The features will be described below.
(1-1) Since the ligand has a fluorene ring to which the ring A is bonded at the 1-position, the half width of the emission spectrum is narrow and the compound exhibits light emission with high color purity.

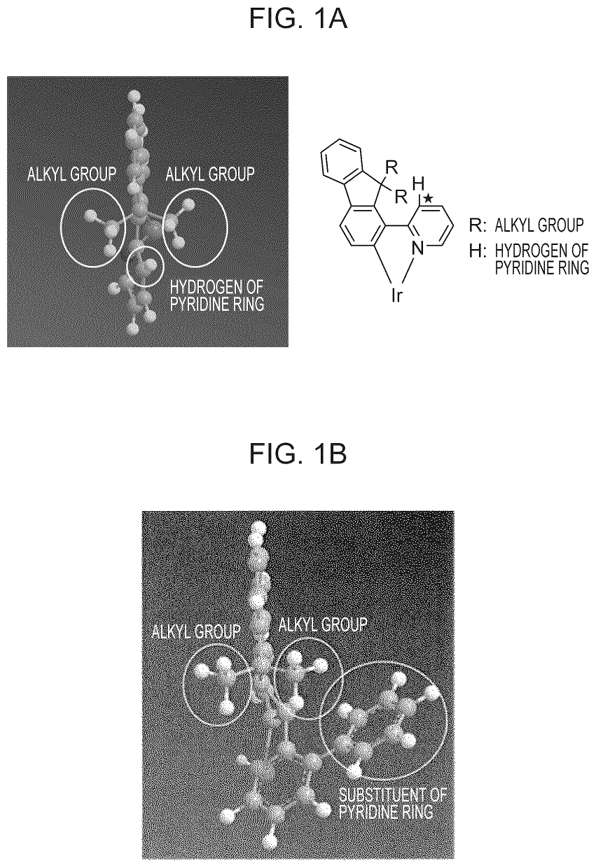

The iridium complex of the present embodiment has, in the ligand, a fluorene ring to which the ring A is bonded at the 1-position (1-position substituted fluorene ring). When the ring A has a structure represented by Formula [4], R₁, R₂, and preferably alkyl groups at the 9-position of the fluorene ring shown in FIG. 1A are disposed to sandwich hydrogen of the pyridine ring. Since the hydrogen of the pyridine ring is repulsive to R₁, R₂, and particularly alkyl group of the fluorene ring on both sides, the dihedral angle between the pyridine ring and the fluorene ring is fixed, the rotation energy of the two rings is extremely high, and rotation of the bond between the pyridine ring and the fluorene ring is suppressed. As a result, the vibration mode due to the rotation control is suppressed in the emission spectrum, the half width of the emission spectrum is decreased, and thus the color purity is high.

Therefore, in a case where the ring A has a structure represented by Formula [4] in the compound represented by General Formula [1] according to the present embodiment, the carbon at the asterisk position shown in FIG. 1A is required to have no substituent, that is, the carbon is required to be bonded to a hydrogen atom. FIG. 1B shows a case where the carbon at the asterisk position is bonded to a phenyl group. The phenyl group is not sandwiched between the alkyl groups of the fluorene ring as shown in FIG. 1B and has a structure in which the phenyl group is positioned outside the space between the alkyl groups. In this case, the dihedral angle between the fluorene ring plane and the pyridine ring plane is extremely increased, and accordingly, the ligand is greatly distorted and thus cannot be synthesized. Further, it is considered that a complex with iridium metal cannot be formed even when the ligand can be synthesized.

Further, in a case where the ring A has a structure represented by Formulae [5] to [7], the lone electron pair functions similarly to the hydrogen atom at the position corresponding to the asterisk position of FIG. 1A, and thus the same effects as described above can be obtained.
(1-2) Since the ligand has a fluorene ring, the positive hole transport property is high.

The iridium complex represented by General Formula [1] has a fluorene ring in the ligand, and thus the positive hole transport property is high. The reason for this is considered to be the structure in which the fluorene rings in the ligands are likely to overlap with each other and positive holes are likely to be hopped between the ligands.
(1-3) R₁ to R₈ do not represent a group with high polarity.

In the light emitting element according to the present embodiment, since the dopant material of the light emitting layer is a compound represented by General Formula [1] and the host material is a hydrocarbon, the interaction between the dopant material and the host material is strong and the energy is likely to be transferred as described in the section of (2-1). That is, the energy is efficiently transferred from the host material to the dopant material by shortening the intermolecular distance between the host material and the dopant material. The dopant material has a fluorene ring that is a fused ring structure with aromaticity and low polarity, in the ligand. Therefore, the energy is likely to be transferred from the host to the dopant by introducing a hydrocarbon and preferably a hydrocarbon-based fused ring structure to the host and allowing the ligands of the host and the dopant to easily cause a n-n interaction.

In order to obtain the above-described effects, it is preferable that R₁ to R₈ represent a group having low polarity. Further, it is more preferable that R₁ to R₈ and R₂₀ to R₂₉ represent a group with low polarity. Specific examples of the group with low polarity include a hydrogen atom, a deuterium atom, an alkyl group formed of hydrocarbons, and an aryl group. When the iridium complex contains a group with low polarity, the polarity of the iridium complex is decreased, the iridium complexes in the host material are unlikely to undergo molecular association. In this manner, the I-interaction between the host material and the dopant material is unlikely to be disturbed. Further, concentration quenching is unlikely to be caused. As described above, the energy is likely to be transferred from the host material to the dopant material and the concentration quenching is unlikely to be caused, and thus the emission efficiency of the organic light emitting element is improved. Examples of the group with high polarity include a cyano group, a halogen group, and an azine ring such as a pyridyl group, and specific examples thereof include ligands having the following structures.

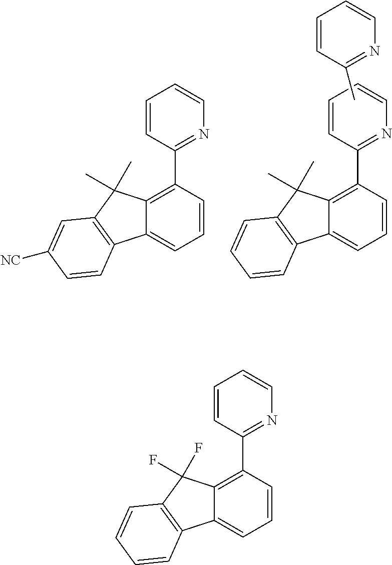

Further, it is preferable that the compound represented by General Formula [1] according to the present embodiment have the following features.
(1-4) Since an auxiliary ligand X is a ligand with low planarity, the sublimation property is improved.
(1-5) Since at least one of R₁ to R₈ or at least one of R₂₀ to R₂₉ represents a tertiary alkyl group, the sublimation property is improved.

The features will be described below.
(1-4) Since an auxiliary ligand X is a ligand with low planarity, the sublimation property is improved.

The compound represented by General Formula [1] according to the present embodiment has at least one ligand having a 1-position substituted fluorene ring (1-position substituted fluorene ligand) and may have an auxiliary ligand X. Since the 1-position substituted fluorene ligand according to the present embodiment has high planarity, it is preferable that the compound have the auxiliary ligand X which does not further increase the planarity. The reason for this is that since the 1-position substituted fluorene ligand of the compound represented by General Formula [1] according to the present embodiment has the ring A bonded to the 1-position of the fluorene ring as described in the section of (1-1), the dihedral angle between the ring A and the fluorene ring is fixed, the half width of the emission spectrum is narrow, and the compound exhibits light emission with high color purity. On the contrary, the 1-position substituted fluorene ligand has high planarity. Therefore, when the planarity of the auxiliary ligand X is decreased, stacking of complexes is weakened, and thus concentration quenching is unlikely to be caused in the light emitting layer. In this manner, the half width of the emission spectrum is narrow, and the emission efficiency is improved. Further, sublimation purification due to stacking and an increase in temperature during vacuum deposition are reduced, and accordingly, decomposition of complexes is unlikely to occur.

Therefore, in a case where a high sublimation property is required, it is preferable that the auxiliary ligand X be a ligand with low planarity. Specifically, in General Formulae [2] and [3], it is preferable that R₉ to R₁₉ represent, for example, a group that does not strengthen the planarity, such as a hydrogen atom, an alkyl group, or a silyl group. Therefore, it is preferable that Ry to R₁₉ be each independently selected from the group consisting of a hydrogen atom, a deuterium atom, a halogen atom, a cyano group, a substituted or unsubstituted alkyl group, a substituted or unsubstituted alkoxy group, and a substituted or unsubstituted silyl group. It is more preferable that R₉ to R₁₉ be each independently selected from the group consisting of a hydrogen atom, a deuterium atom, a substituted or unsubstituted alkyl group, and a substituted or unsubstituted silyl group. Further, it is preferable that one or more of R₉ to R₁ or R₁₂ to R₁₉ represent a tertiary alkyl group. In a case where the auxiliary ligand X has a tertiary alkyl group, an effect of reducing stacking of complexes and decreasing the temperature during the sublimation purification or vacuum deposition is obtained. A tertiary alkyl group having 4 or more carbon atoms is preferable, and a tertiary butyl group is more preferable as the tertiary alkyl group.

Table 1 shows results of the sublimation temperature and the sublimation purification yield during the sublimation purification of each compound. The compounds 1 to 3 are respectively exemplary compounds F-1 and J-16 described below and the compound A-1 described in PTL 1. Further, the degree of vacuum during the sublimation purification is in a range of 1×10⁻³ Pa to 1×10⁻² Pa. As listed in Table 1, the planarity of the auxiliary ligand X of the compound 1 is decreased, and thus the sublimation temperature is lower and the yield during the sublimation purification is higher as compared with the cases of the compounds 2 and 3 in which the auxiliary ligand X has a xanthene ring or a biphenyl ring.

TABLE 1

| | | | Sublimation |
|---|---|---|---|
| | | Sublimation | purification |
| Compound | Compound structure | temperature | yield |
| Compound 1 (F-1) | 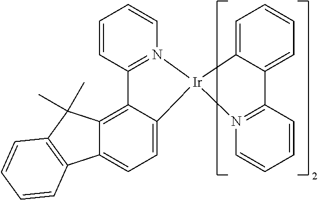 | 370° C. | 72% |
| Compound 2 (J-16) | 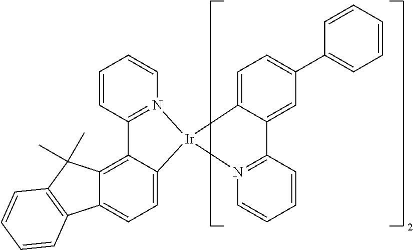 | 410° C. | 63% |
| Compound 3 (A-1) | 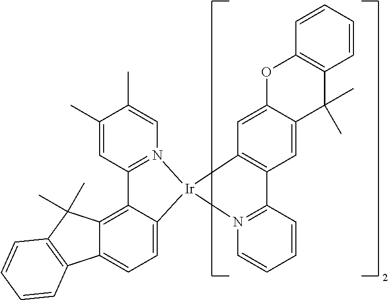 | 440° C. | 35% |

(1-5) Since at least one of R₁ to R₈ or at least one of R₂₀ to R₂₉ represents a tertiary alkyl group, the sublimation property is improved.

The iridium complex of the present embodiment has the above-described feature due to having a fluorene ring in a ligand, but the molecular weight of the complex is large and the sublimation property is poor due to having a fused polycycle in some cases. Specific examples thereof include a case where the temperature during the sublimation purification is high and a case where the complex after the sublimation purification is partially decomposed.

Therefore, at least one of R₁ to R₈ or at least one of R₂₀ to R₂₉ (at least one of R₂₀ to R₂₂, R₂₃ to R₂₅, R₂₆ and R₂₇, or R₂₈ and R₂₉) represent a tertiary alkyl group. In this manner, molecular stacking between complexes is suppressed, and the sublimation temperature is decreased. In a case where the tertiary alkyl group has 4 or more carbon atoms, the exclusion effect between complexes is high, and the effect of suppressing molecular stacking is also high. When the compound contains a tertiary alkyl group, radical cleavage of hydrogen at the benzylic position due to the temperature can be reduced in a case where the temperature load is high.

Here, the bond dissociation energies of the carbon-hydrogen bonds described in ACC. Chem. Res. 36, pp. 255 to 263 (2003) are listed in Table 2.

TABLE 2

| | | Bond dissociation energy |
|---|---|---|
| | Bond | (kcal/mol) |
| Methyl group | 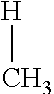 | 105 |
| Ethyl group | 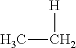 | 101 |
| Phenyl group | 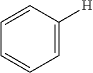 | 113 |
| Benzyl group | 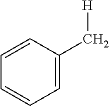 | 90 |

The bond is stronger as the numerical value of the bond dissociation energy increases, and the bond is weaker as the numerical value thereof decreases. That is, it can be seen that the carbon-hydrogen bond at the benzylic position is a weak bond. The reason for this is that when the hydrogen atom at the benzylic position is desorbed to form a radical, the radical is stabilized by the resonance of the radical with I electrons of the benzene ring adjacent thereto. Therefore, the carbon-hydrogen bond at the benzylic position is a weak bond. That is, when the molecular structure does not have a structure such as a benzyl group, a compound in which the carbon-hydrogen bond is unlikely to be cut is obtained, which is preferable.

Further, since the iridium complex represented by General Formula [1] according to the present embodiment has a fluorene ring in the ligand, the positive hole transport property is high. The reason for this is considered to be the structure in which the fluorene rings of the ligands are likely to overlap with each other and positive holes are likely to be hopped between the ligands. Therefore, it is more preferable that the ring A side, that is, at least one of R₂₀ to R₂₉ represent a tertiary alkyl group so that overlapping of the fluorene rings is not reduced.

### Specific Examples

Specific examples of the organic compound and the dopant material according to the present embodiment will be described below, but the present disclosure is not limited thereto.

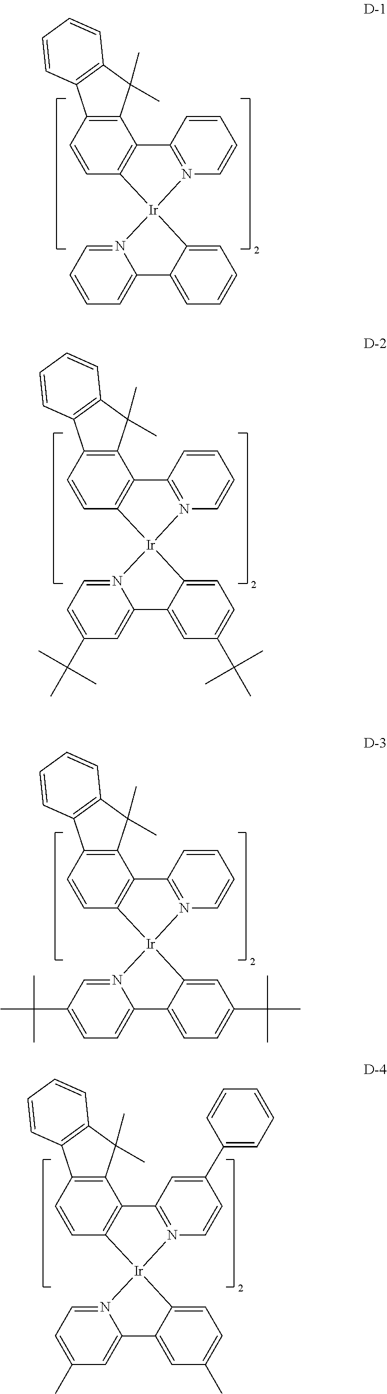

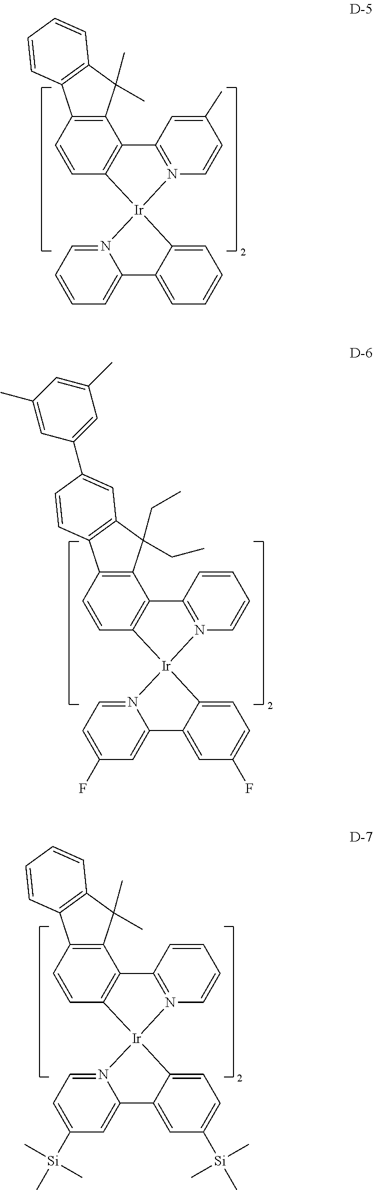

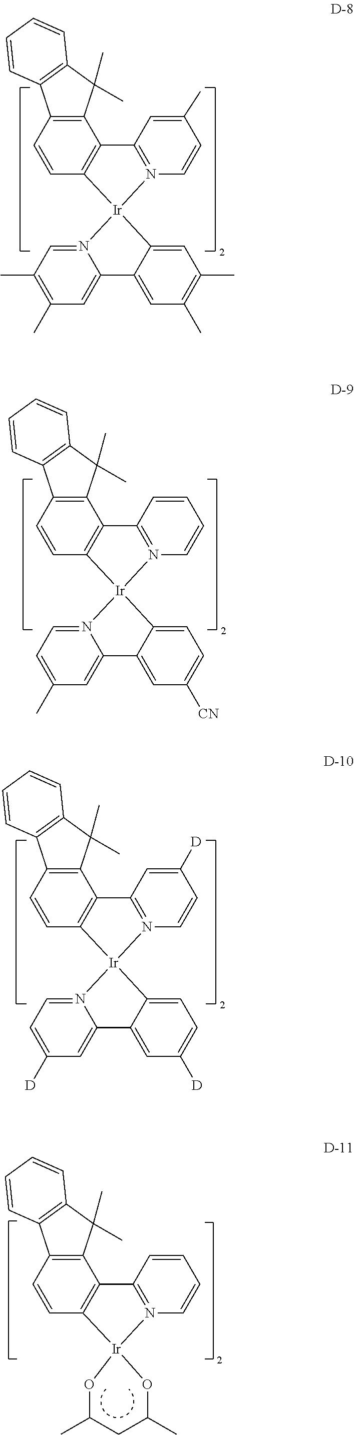

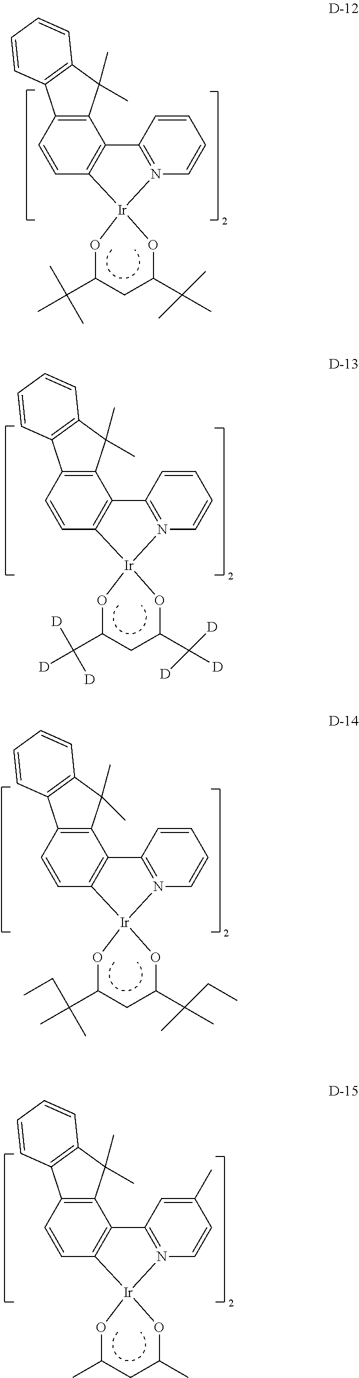

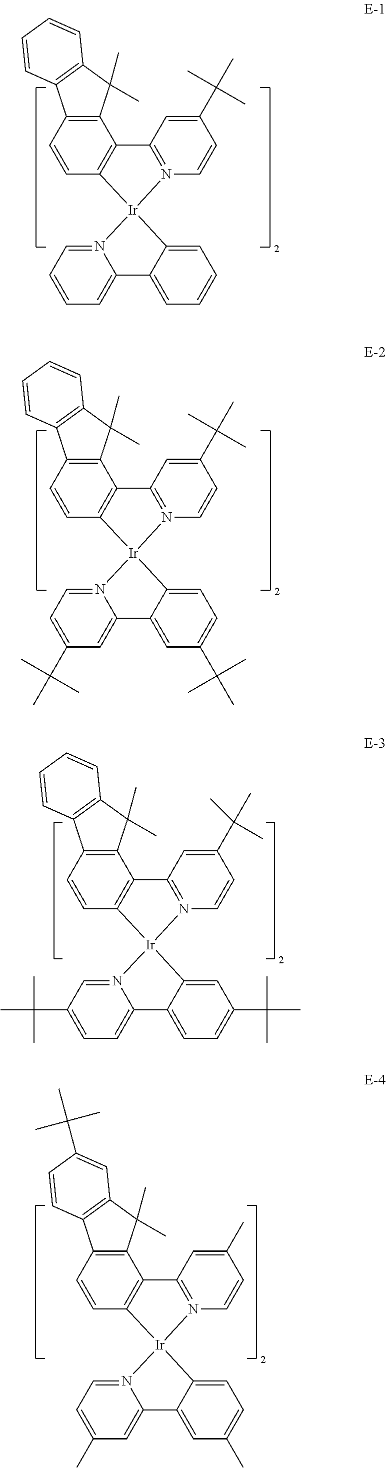

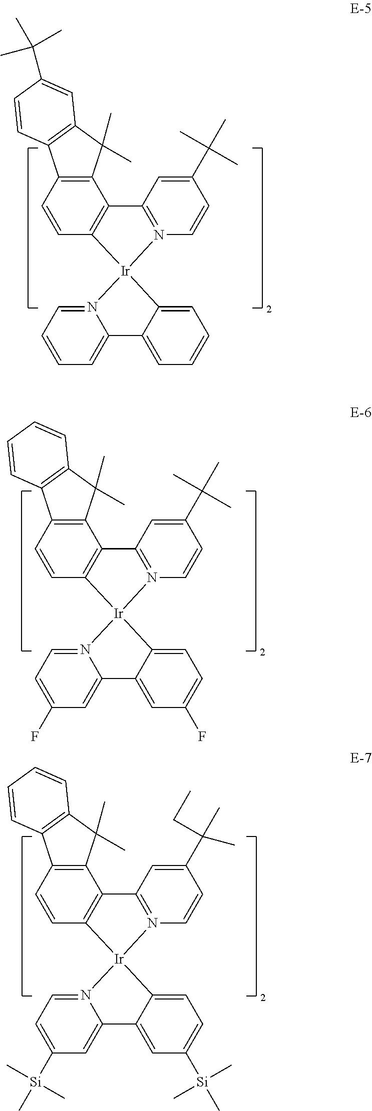

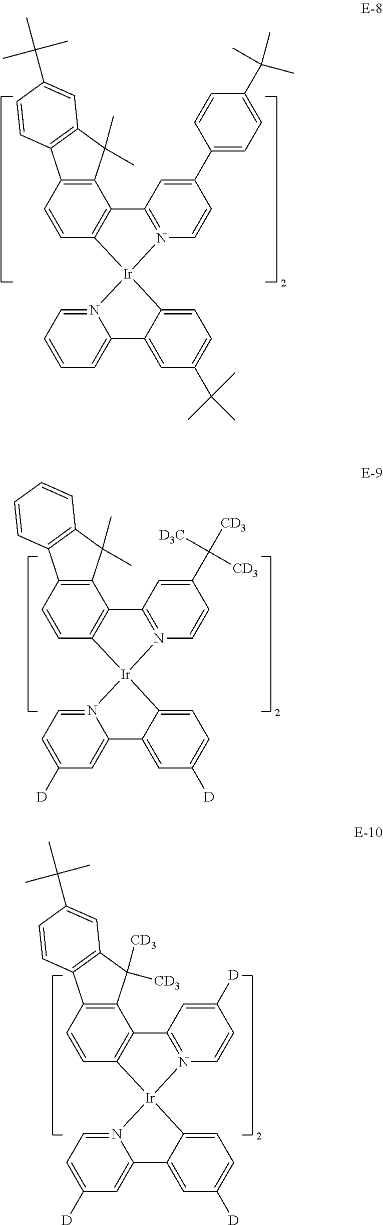

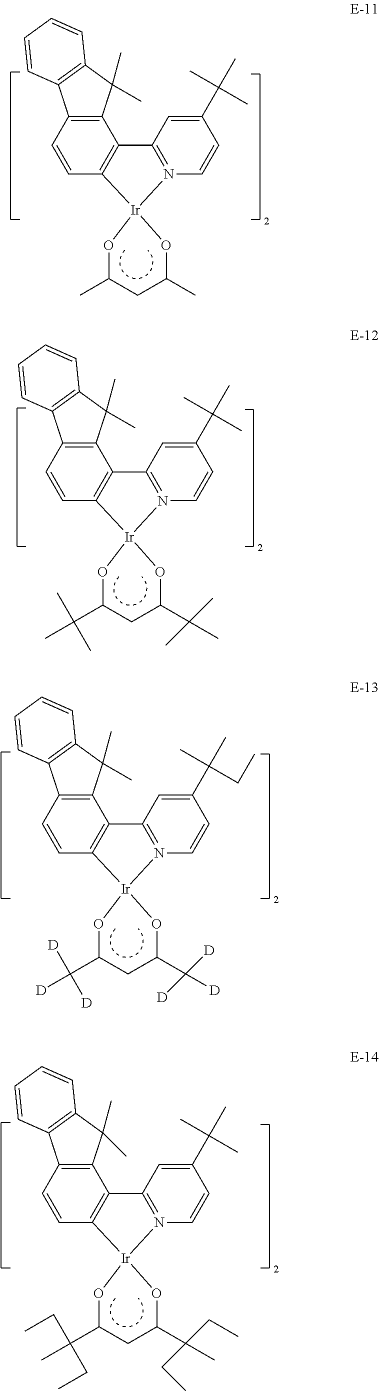

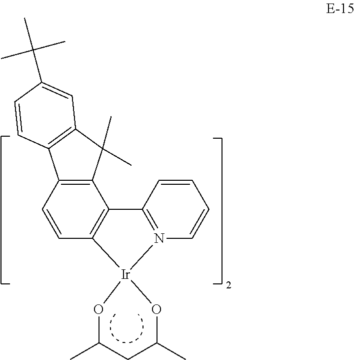

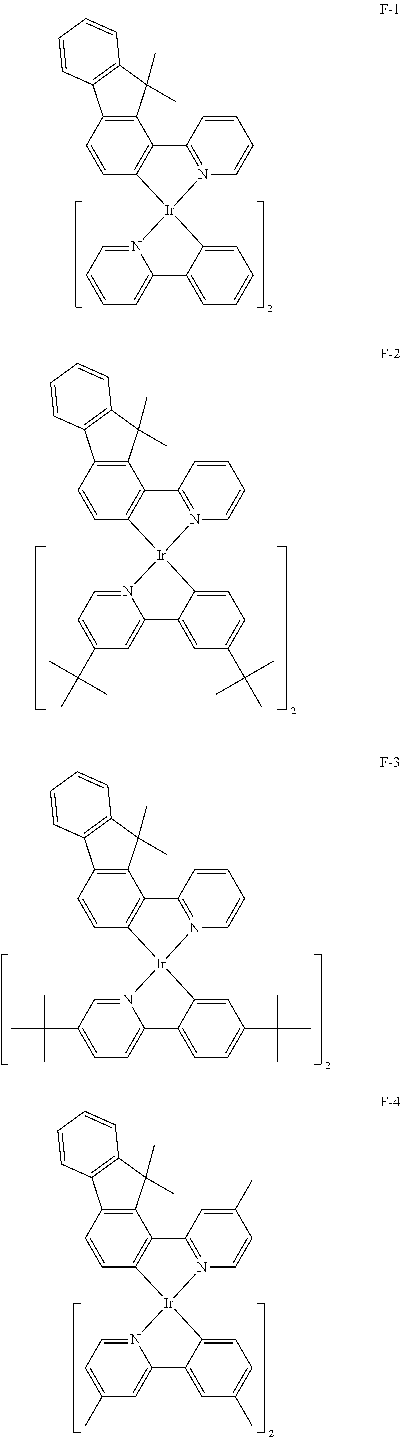

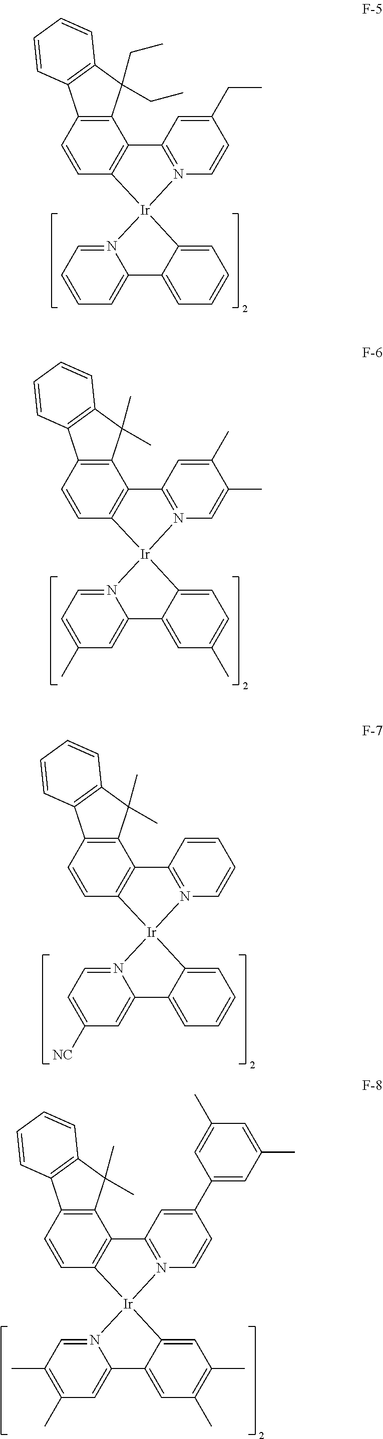

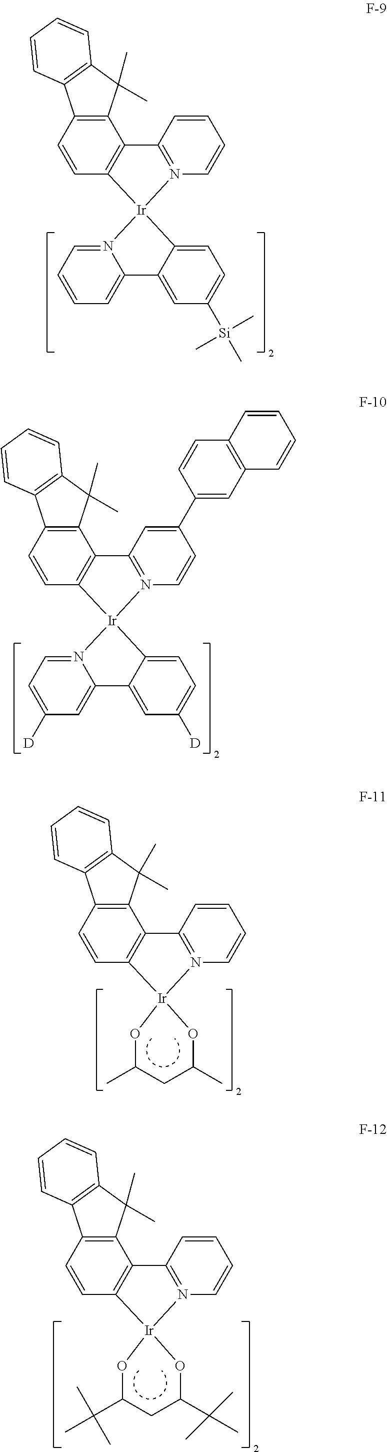

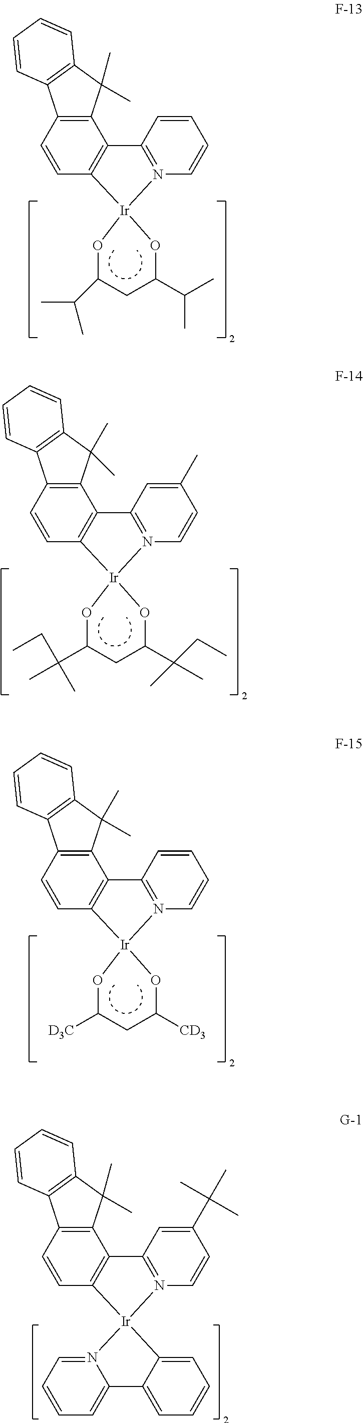

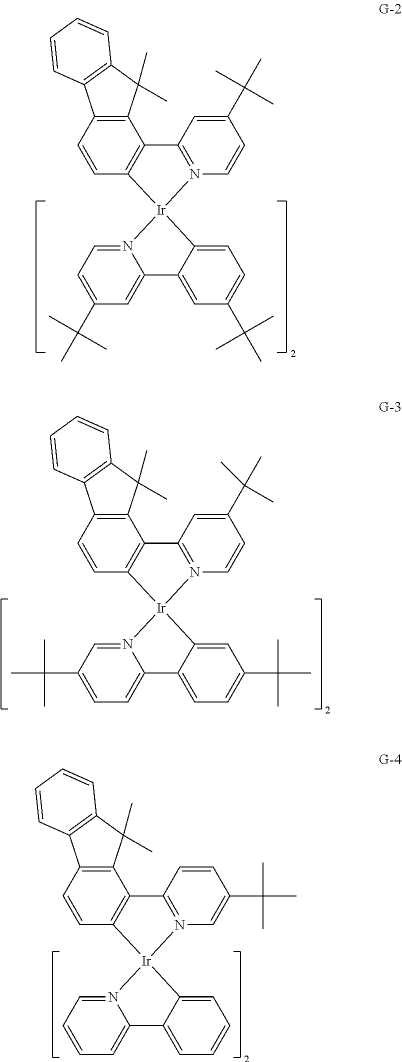

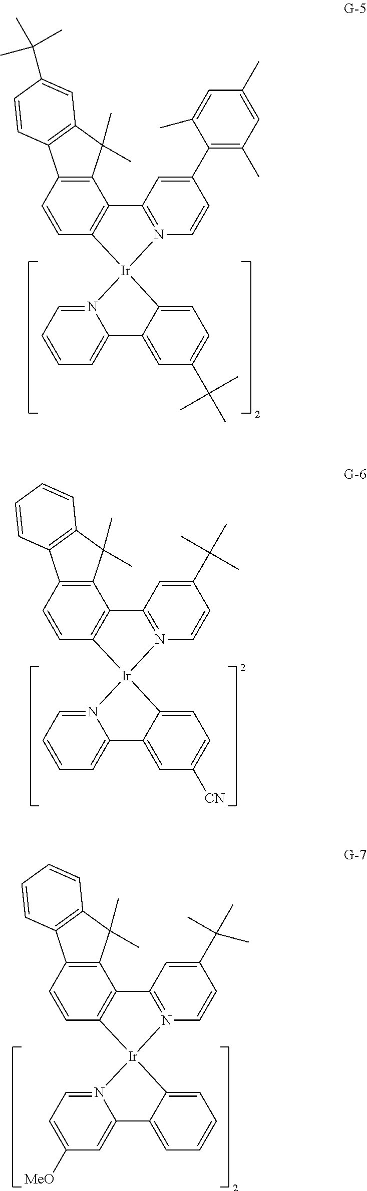

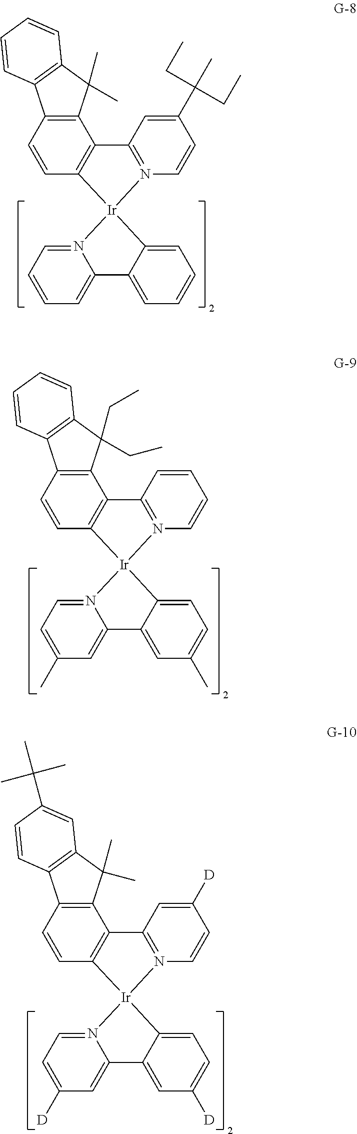

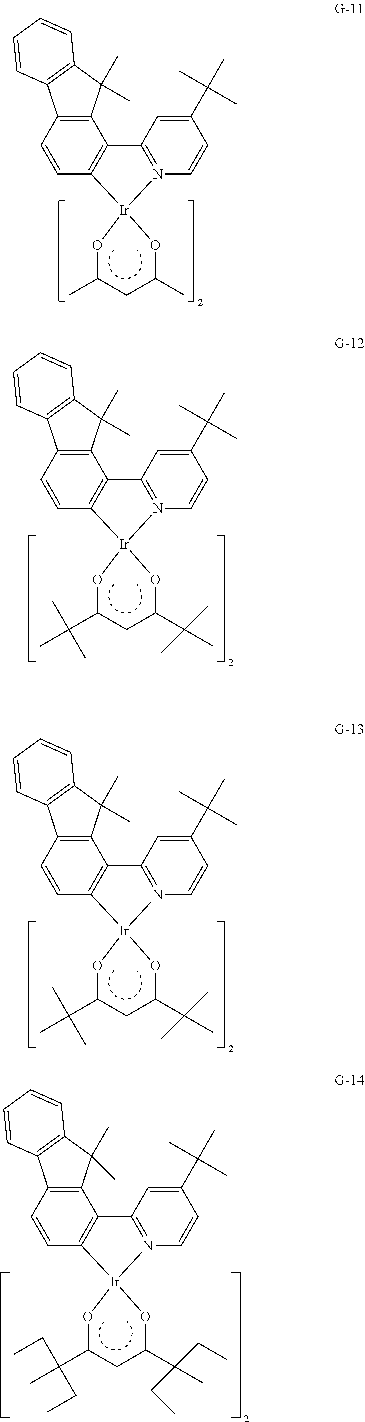

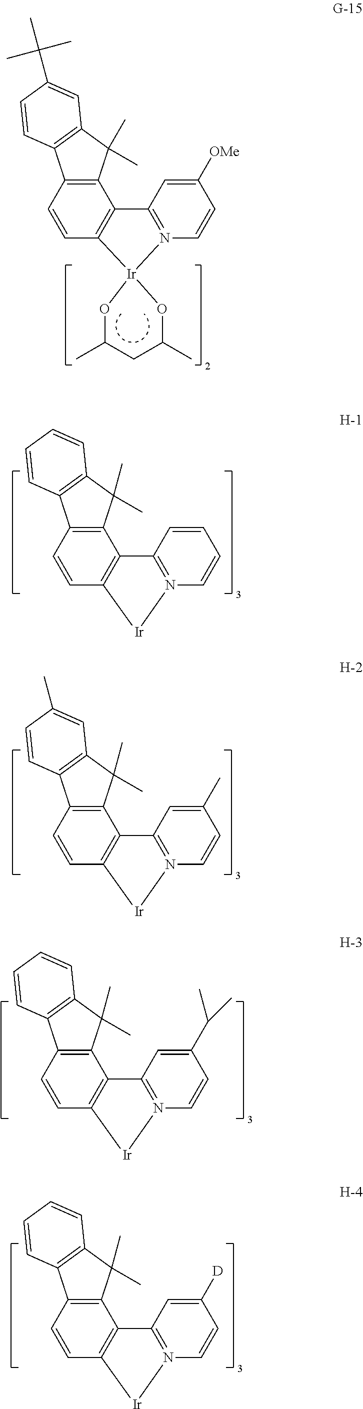

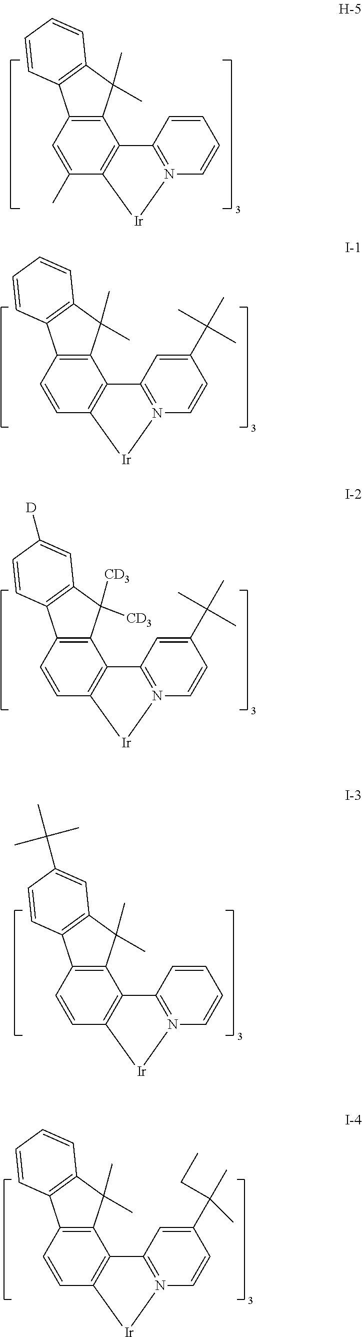

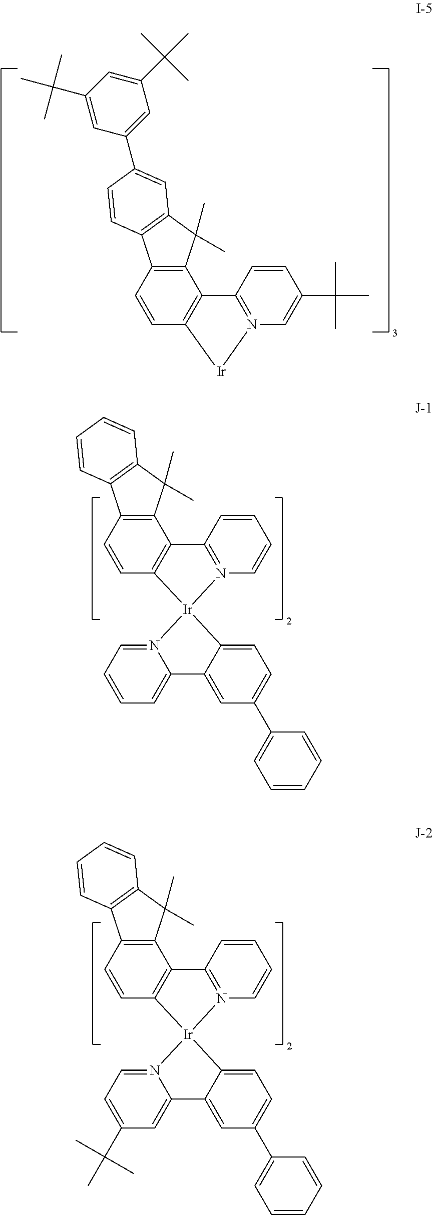

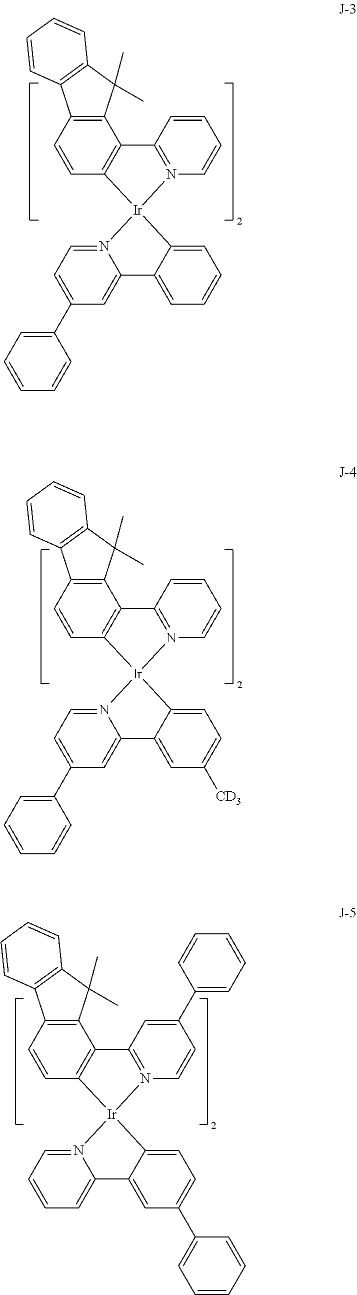

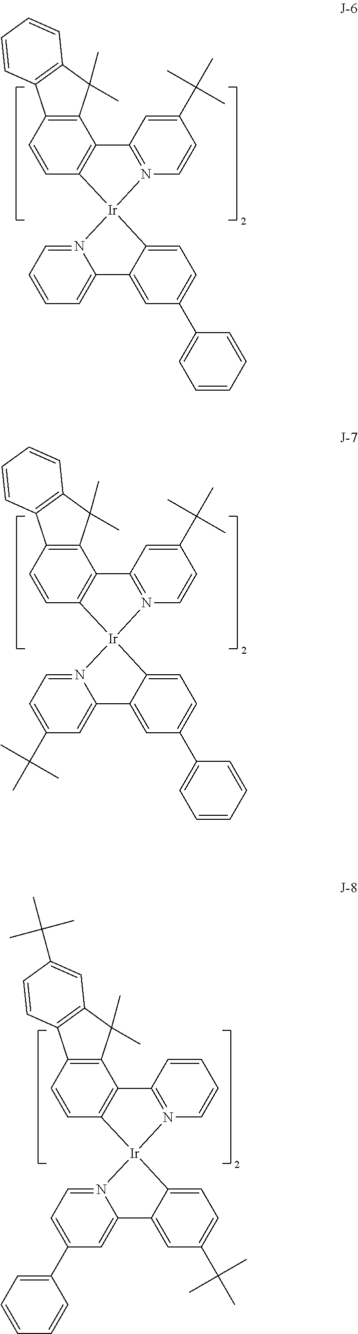

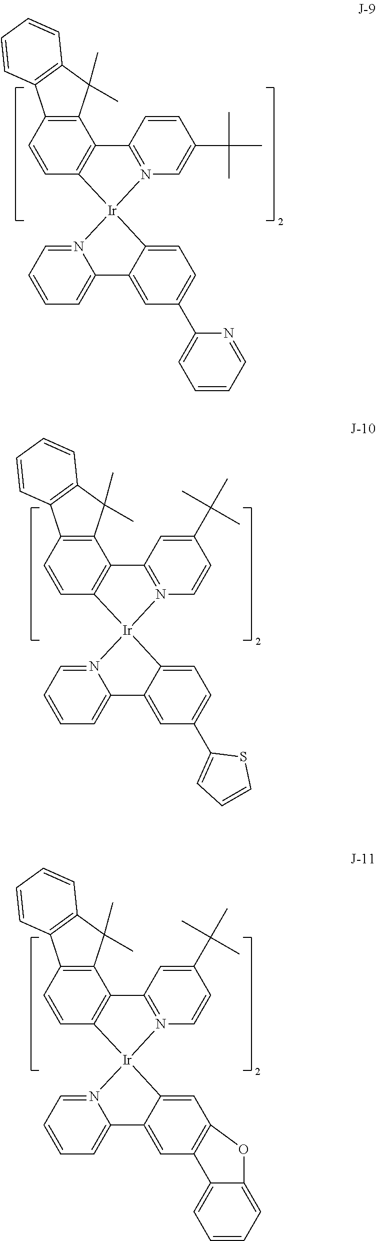

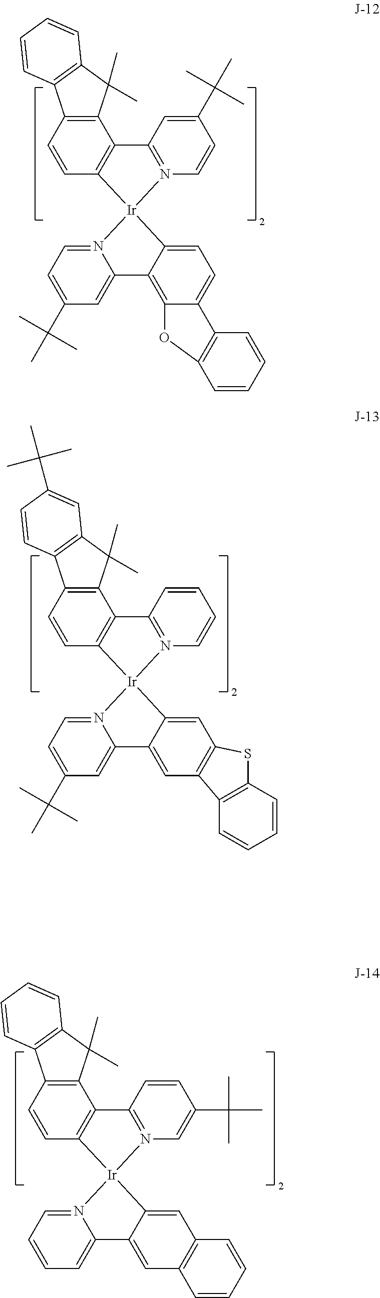

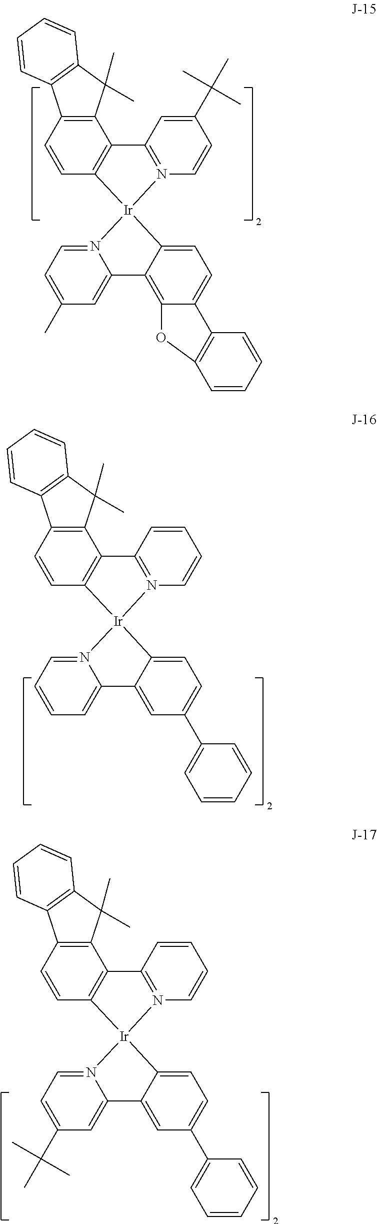

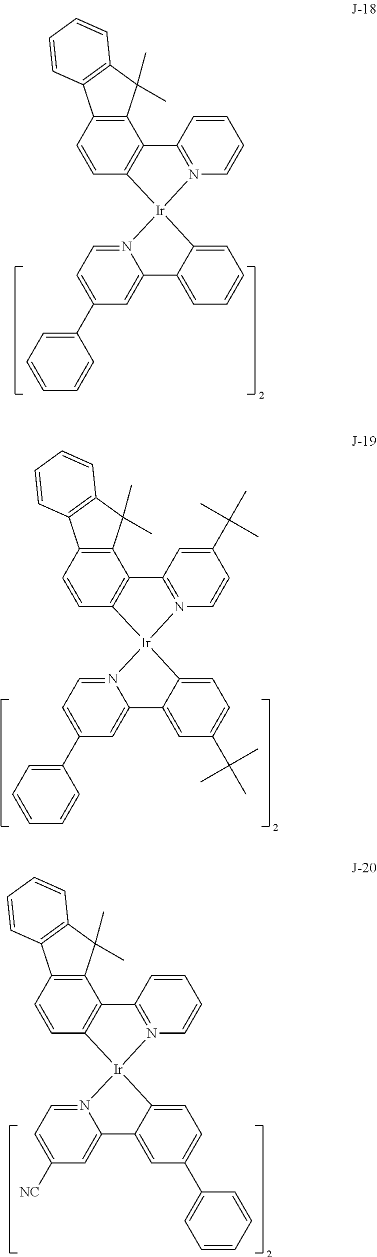

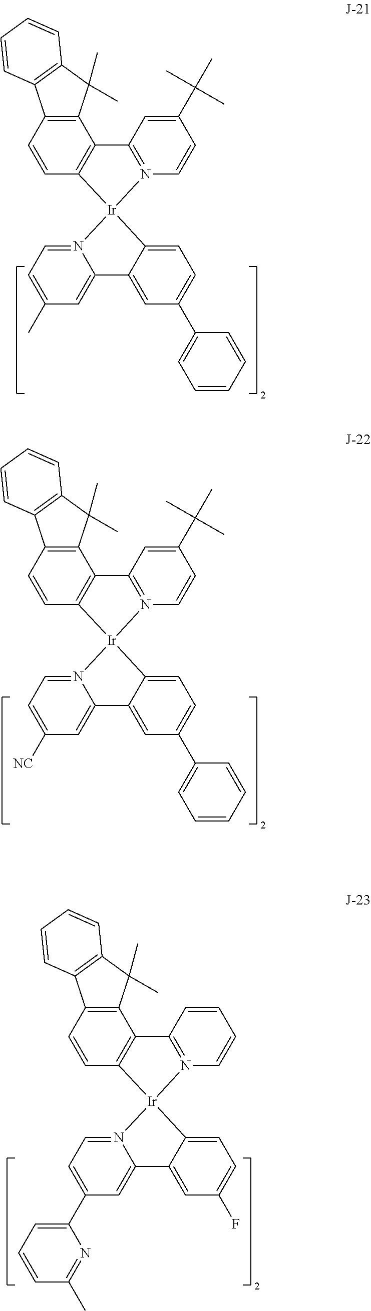

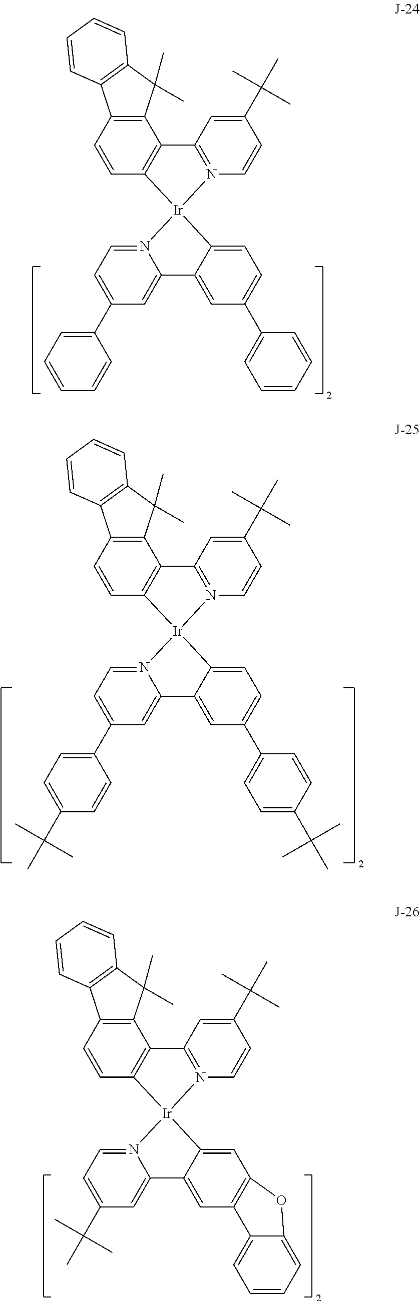

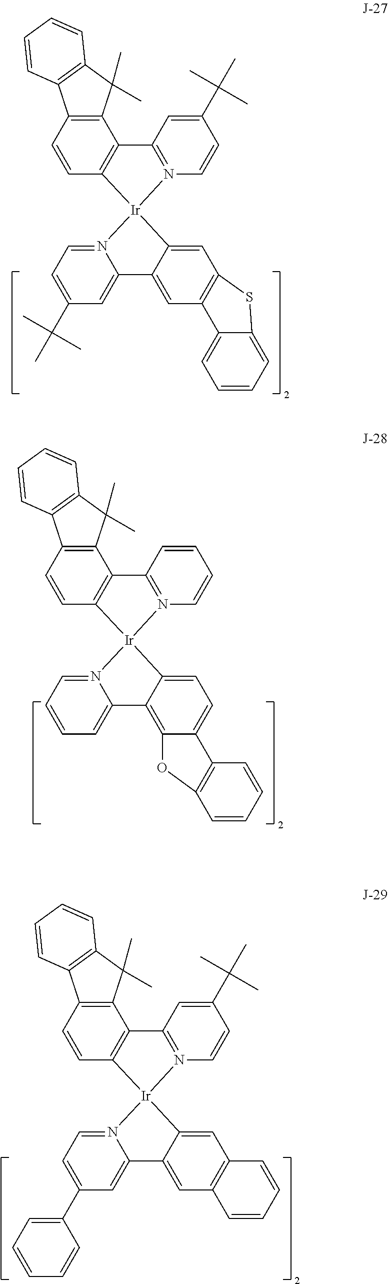

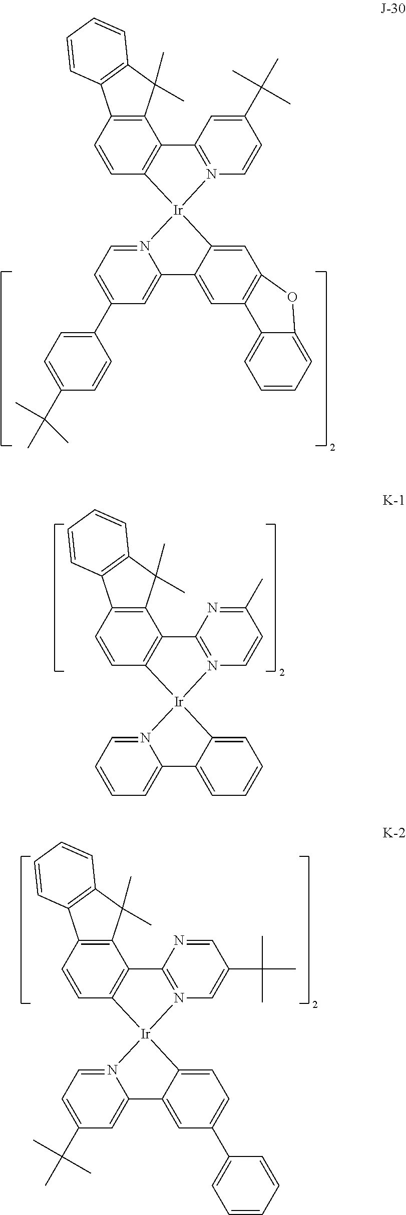

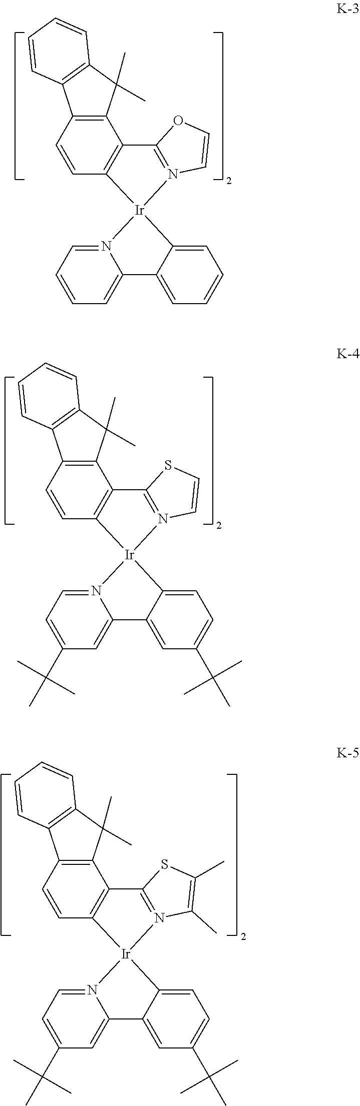

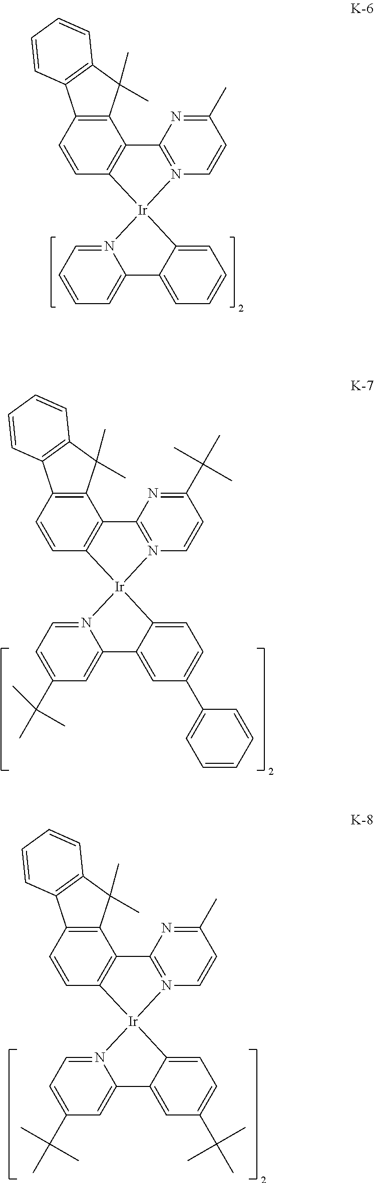

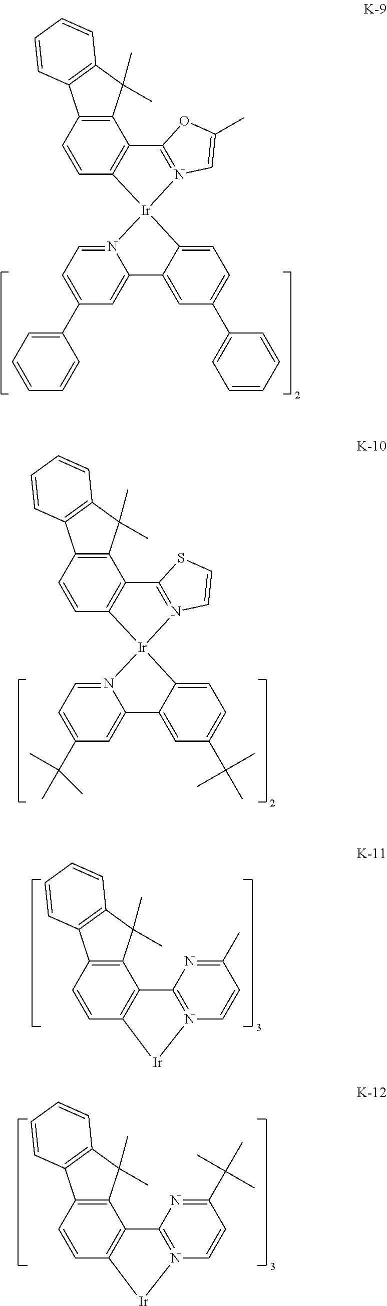

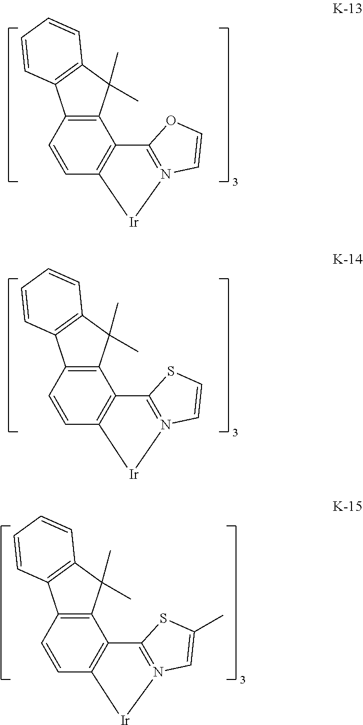

Exemplary compounds belonging to Group D are compounds in which in General Formula [1], m represents 2 and the ring A has a structure represented by General Formula [4]. Since the compounds have two fluorene rings with high planarity, the positive hole mobility is high, the alignment degree of the compounds is high, and thus light extraction of the light emitting element is improved.

Exemplary compounds belonging to Group E are compounds in which in General Formula [1], m represents 2, the ring A has a structure represented by General Formula [4], and at least one of R₁ to R₈ and R₂₀ to R₂₂ represents a tertiary alkyl group. Since molecular stacking is reduced, the sublimation property is improved, and the concentration quenching in the light emitting layer can be suppressed.

Exemplary compounds belonging to Group F are compounds in which in General Formula [1], m represents 1 and the ring A has a structure represented by General Formula [4]. Since the compounds have a fluorene ring with high planarity, the positive hole mobility is high. Further, the compounds have a low molecular weight and a low sublimation temperature as compared with the compounds belonging to Group D.

Exemplary compounds belonging to Group G are compounds in which in General Formula [1], m represents 1, the ring A has a structure represented by General Formula [4], and at least one of R₁ to R₈ and R₂₀ to R₂₂ represents a tertiary alkyl group. Since molecular stacking is more reduced than the case of the compounds belonging to Group F, the sublimation property is improved, and the concentration quenching in the light emitting layer can be suppressed.

Exemplary compounds belonging to Groups H and I are compounds in which in General Formula [1], m represents 3 and the ring A has a structure represented by General Formula [4]. Since the compounds have three fluorene rings with high planarity, the positive hole mobility is extremely high.

Exemplary compounds belonging to Group J are compounds in which in General Formula [1], m represents 1 or 2 and the ring A has a structure represented by General Formula [4] and which have ligands with high planarity as the auxiliary ligands X. Since the compounds have ligands with high planarity, the positive hole mobility is extremely high.

Exemplary compounds belonging to Group K are compounds in which in General Formula [1], m represents 1, 2, or 3 and the ring A has any one of structures represented by General Formulae [5] to [7]. The electron-withdrawing properties are high, and the carrier balance in the element is satisfactory.

### (2) Features of Organic Light Emitting Element

An organic light emitting element of the present disclosure includes at least an anode, a light emitting layer, and a cathode in this order, in which the light emitting layer contains at least a dopant material and a host material. Further, the organic light emitting element has the following features.
(2-1) Since the dopant material of the light emitting layer is a compound represented by General Formula [1] and the host material is a hydrocarbon, the interaction between the dopant material and the host material is strong, and the energy is likely to be transferred.
(2-2) Since the effect of the feature (2-1) described above is to promote transport and hopping of positive holes between the dopant material and the host material, the positive hole transport property in the light emitting layer is improved.

The features will be described below.
(2-1) Since the dopant material of the light emitting layer is a compound represented by General Formula [1] and the host material is a hydrocarbon, the interaction between the dopant material and the host material is strong, and the energy is likely to be transferred.

The compound represented by General Formula [1] has, in the ligand, a fluorene ring which is a fused polycycle formed of a hydrocarbon, in which three rings are fused. Meanwhile, a hydrocarbon and preferably a fused polycyclic compound is used as the host material. The dopant material has a fused ring structure with aromaticity and low polarity in the ligand. Therefore, the energy is likely to be transferred from the host to the dopant by introducing a hydrocarbon and preferably a fused polycyclic group to the host and allowing the ligands of the host and the dopant to easily cause a n-n interaction.

Here, triplet energy used for a phosphorescent light emitting element is known to undergo energy transfer based on Dexter electron transfer. According to the Dexter electron transfer, the energy transfer is carried out by the contact of molecules. That is, the energy transfer from the host material to the dopant material is efficiently made by decreasing the intermolecular distance between the host material and the dopant material. The dopant material has a fused ring structure with aromaticity and low polarity in the ligand. Therefore, the energy is likely to be transferred from the host to the dopant by introducing a hydrocarbon and preferably a hydrocarbon-based fused ring structure to the host and allowing the ligands of the host and the dopant to easily cause a n-n interaction.

Due to the above-described effects, triplet excitons generated in the host material are quickly consumed by light emission, highly efficient light emission is exhibited. Further, material degradation due to a high-energy triplet excited state caused by further excitation of triplet excitons that are not used for light emission can be prevented, and thus the driving durability of the organic light emitting element is satisfactory.

The concentration of the dopant material is preferably 0.01% by mass or greater and 30% by mass or less and more preferably 2% by mass or greater and 20% by mass or less with respect to the total concentration of the light emitting layer.
(2-2) Since the effect of the feature (2-1) described above is to promote transport and hopping of positive holes between the dopant material and the host material, the positive hole transport property in the light emitting layer is improved.

The compound represented by General Formula [1] has a low HOMO level (close to a vacuum level) due to the effect of having a fluorene ring in the ligand and thus tends to have a lower HOMO level than that of the host material. The host material transports positive holes injected from a positive hole transport layer, and the positive holes are transported while being continuously trapped and detrapped between the dopant material and the host material. Here, it is preferable that similar skeletons be used in the host material and the dopant material. In this case, the fused rings of the host material and the dopant material strongly overlap with each other, and positive hole transport is efficiently made between the dopant material and the host material. In this manner, an organic light emitting element that suppresses an increase in voltage in the light emitting layer and has a low voltage and satisfactory driving durability is provided.

Further, it is preferable that the organic light emitting element according to the present embodiment have the following features.
(2-3) The light emitting layer further contains an assist material. It is preferable that the LUMO level of the assist material be lower (far from the vacuum level) than the LUMO level of the host material. In this manner, both carriers of electrons and positive holes are trapped in the light emitting layer, and thus an element with high efficiency is provided.
(2-4) The effect of the feature (2-3) described above is to reduce injection of carriers through the light emitting layer into the transport layer adjacent to the light emitting layer and to reduce deterioration of the transport layer, and thus an element with high durability is provided.

The features will be described below.
(2-3) The light emitting layer further contains an assist material. It is preferable that the LUMO level of the assist material be lower (far from the vacuum level) than the LUMO level of the host material. In this manner, both carriers of electrons and positive holes are trapped in the light emitting layer, and thus an element with high efficiency is provided.

Since the iridium complex represented by General Formula [1] promotes injection of positive holes into the light emitting layer, it is preferable that the efficiency be increased by injecting electrons and positive holes into the light emitting layer in a well-balanced manner and more preferable that injection of electrons into the light emitting layer be promoted. The host material is a hydrocarbon and thus has a wide band gap. Therefore, the host material has a higher LUMO level (close to the vacuum level), electrons may be unlikely to be injected from an electron transport layer or a positive hole blocking layer. Accordingly, in order to make it easier to inject electrons into the light emitting layer, it is preferable that the compound further contain an assist material. In addition, it is preferable that the LUMO level of the assist material be lower than the LUMO level of the host material. In this manner, the injection property of both the positive holes and the electrons into the light emitting layer is improved so that the carrier balance in the light emitting layer is maintained, and thus a light emitting element with high efficiency is provided.
(2-4) The effect of the feature (2-3) described above is to reduce injection of carriers through the light emitting layer into the transport layer adjacent to the light emitting layer and to reduce deterioration of the transport layer, and thus an element with high durability is provided.

The element of the present embodiment exhibits an effect that the dopant material promotes the positive hole injection property in the light emitting layer as described above and the positive holes are trapped in the light emitting layer by positive hole trapping. In this manner, injection of positive holes from the light emitting layer to the positive hole blocking layer and the electron transport layer is prevented, and thus deterioration of the positive hole blocking layer and the electron transport layer due to the positive holes is reduced.

Further, the element exhibits an effect that the assist material having a LUMO level lower than that of the host material promotes the electron injection property and the electrons are trapped in the light emitting layer by electron trapping. In this manner, injection of electrons from the light emitting layer to the electron blocking layer and the positive hole transport layer is reduced, and thus deterioration of the electron blocking layer and the positive hole transport layer due to the electrons is reduced.

### (3) Host Material

The host material is a hydrocarbon. It is preferable that the host material have a minimum triplet excitation energy (Ti) greater than that of the iridium complex represented by General Formula [1]. Specifically, since the dopant material according to the present embodiment has a light emission region of 500 nm to 540 nm, Ti is preferably 2.3 eV or greater and more preferably 2.5 eV or greater. Further, as described above, it is preferable that the host material be a fused polycyclic compound in order to increase the interaction between the host material and the fluorene ring in the ligand of the iridium complex. Specific examples of the fused polycyclic group having a Ti of 2.3 eV or greater include fluoranthene, benzo[e]pyrene, benzo[g] chrysene, benzo[c] chrysene, coronene, benzofluorene, chrysene, picene, naphthalene, phenanthrene, triphenylene, and fluorene. Among these, chrysene, picene, naphthalene, phenanthrene, triphenylene, and fluorene with a Ti of 2.5 eV or greater are preferable.

Further, it is preferable that the host material of the present disclosure have the following features.
(3-1) The host material has at least any one of a chrysene ring, a picene ring, a phenanthrene ring, a triphenylene ring, and a fluoranthene ring in the skeleton.
(3-2) The host material has no SP³ carbon.

The features will be described below.
(3-1) The host material has at least any one of a chrysene ring, a picene ring, a phenanthrene ring, a triphenylene ring, and a fluoranthene ring in the skeleton.

The dopant material according to the present embodiment has a fluorene skeleton in the ligand. The fluorene skeleton is a structure with high planarity. As in the features (2-1) and (2-2), it is preferable that the host material similarly have a structure with high planarity so that the iridium complex and the host material according to the present embodiment interact with each other. The reason for this is that when the host material has a structure with high planarity, moieties with high planarity can approach each other through the interaction. More specifically, the fluorene moiety of the iridium complex and the moiety of the host material with high planarity are likely to approach each other. Therefore, the intermolecular distance between the iridium complex and the host material can be expected to be decreased. The above-described effect leads to the effect of increasing the efficiency of energy transfer described in the feature (2-1).

Here, examples of the structure with high planarity include a structure having three or more fused polycycles. Among the examples, a structure having a fused polycycle which is a hydrocarbon such as a chrysene ring, a picene ring, a phenanthrene ring, a triphenylene ring, or a fluoranthene ring with a Ti of 2.5 eV or greater is preferable.

Further, it is preferable that the host material have a ring other than the fluorene ring which is the same structure as in the ligand of the iridium complex so that the host material strongly interacts with the iridium complex according to the present embodiment to prevent the emission wavelength of the iridium complex from being increased.
(3-2) The host material has no SP³ carbon.

The dopant material according to the present embodiment is a compound having a feature of improving the interaction and the emission characteristics by shortening the distance between the dopant material and the host material, as described in the feature (3-1) above. When a material having no SP³ carbon is used as the host material, the distance between the host material and the iridium complex can be shortened.

### Specific Examples

Specific examples of the host material will be described below, but the present disclosure is not limited thereto.

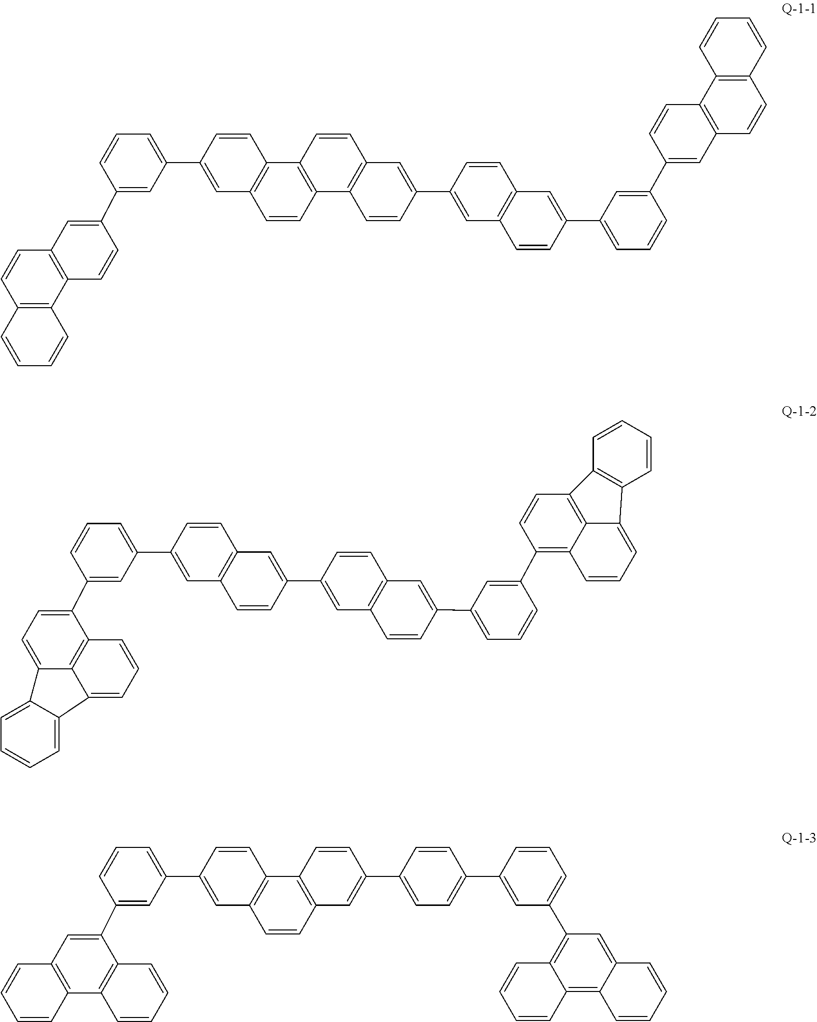

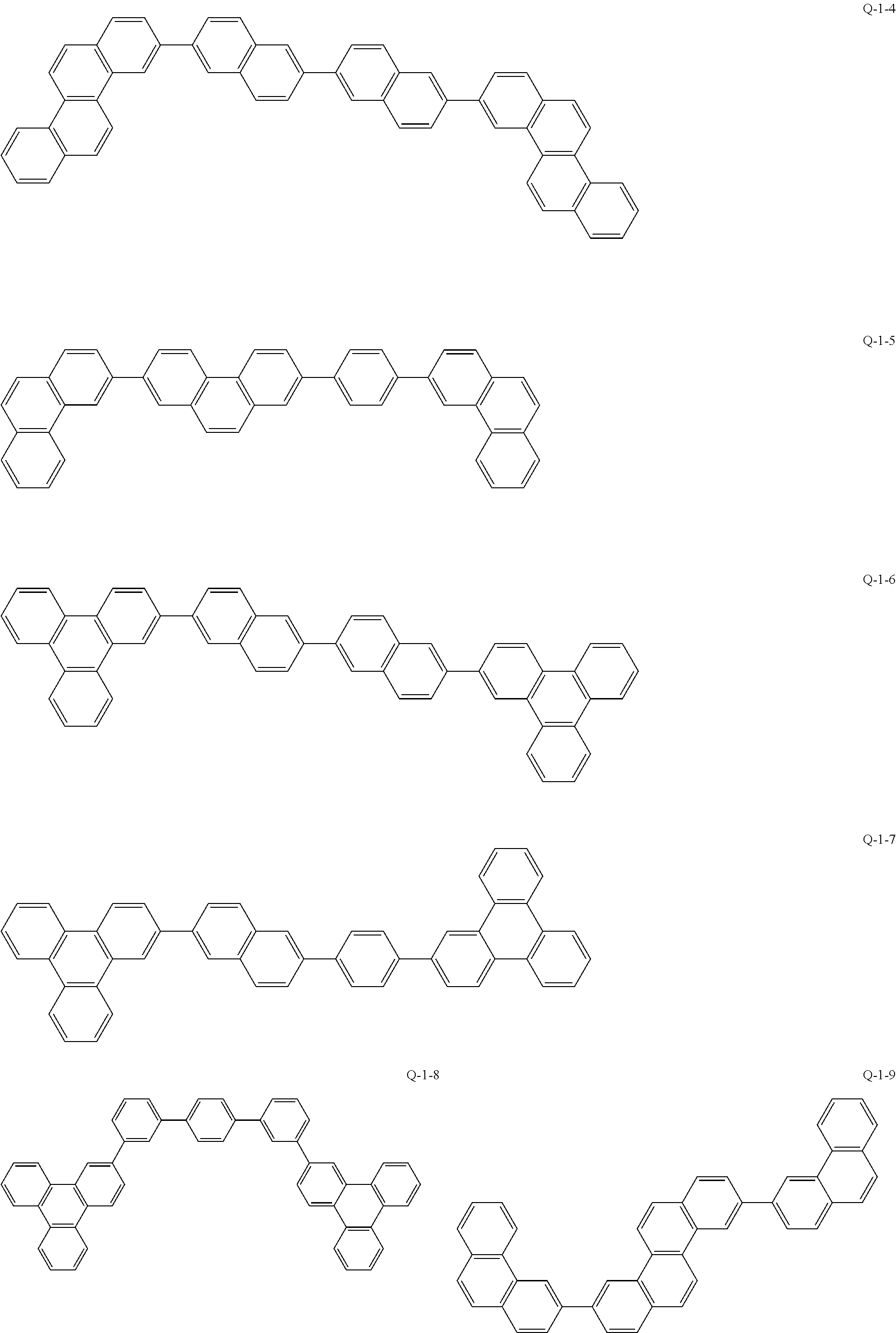

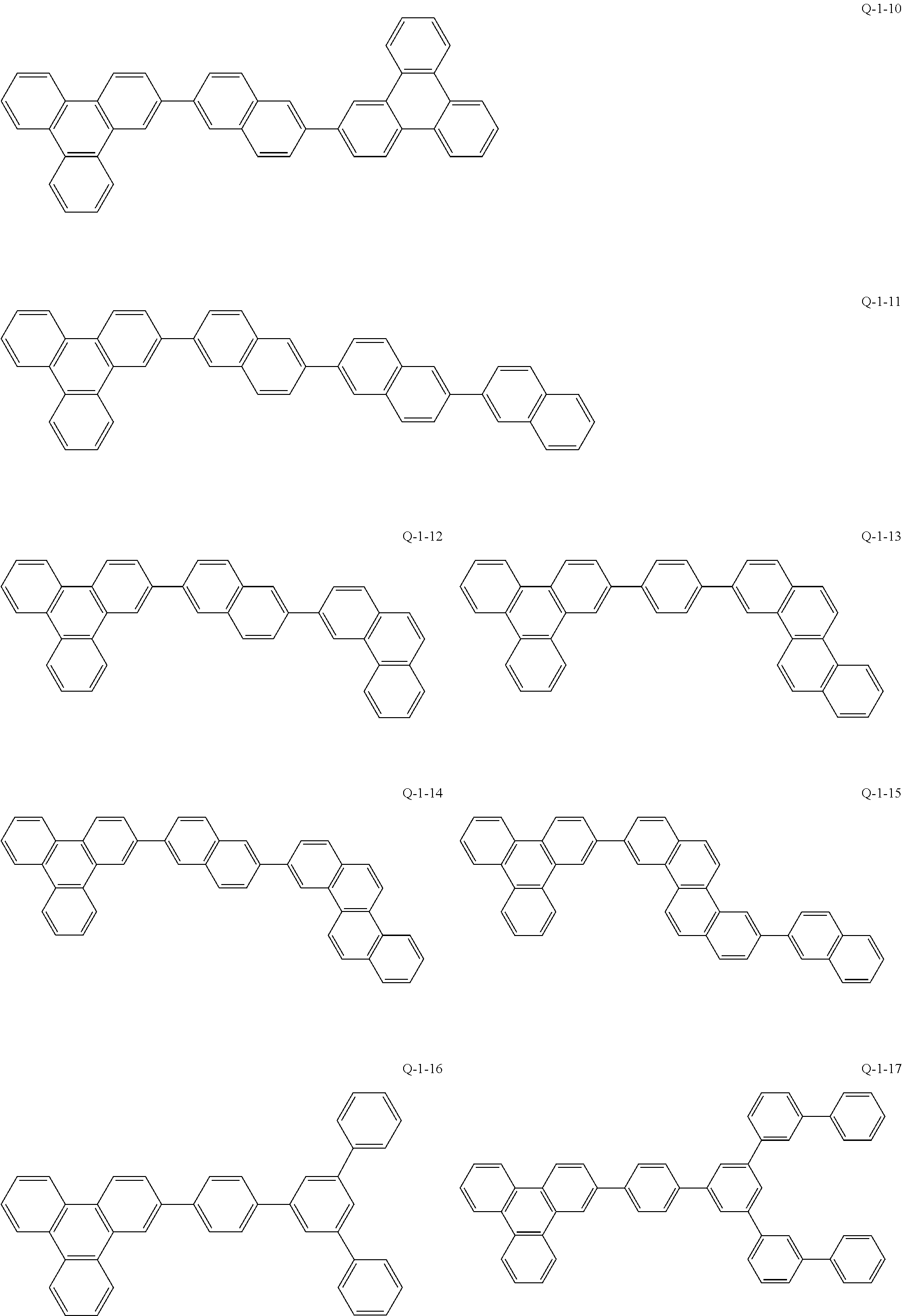

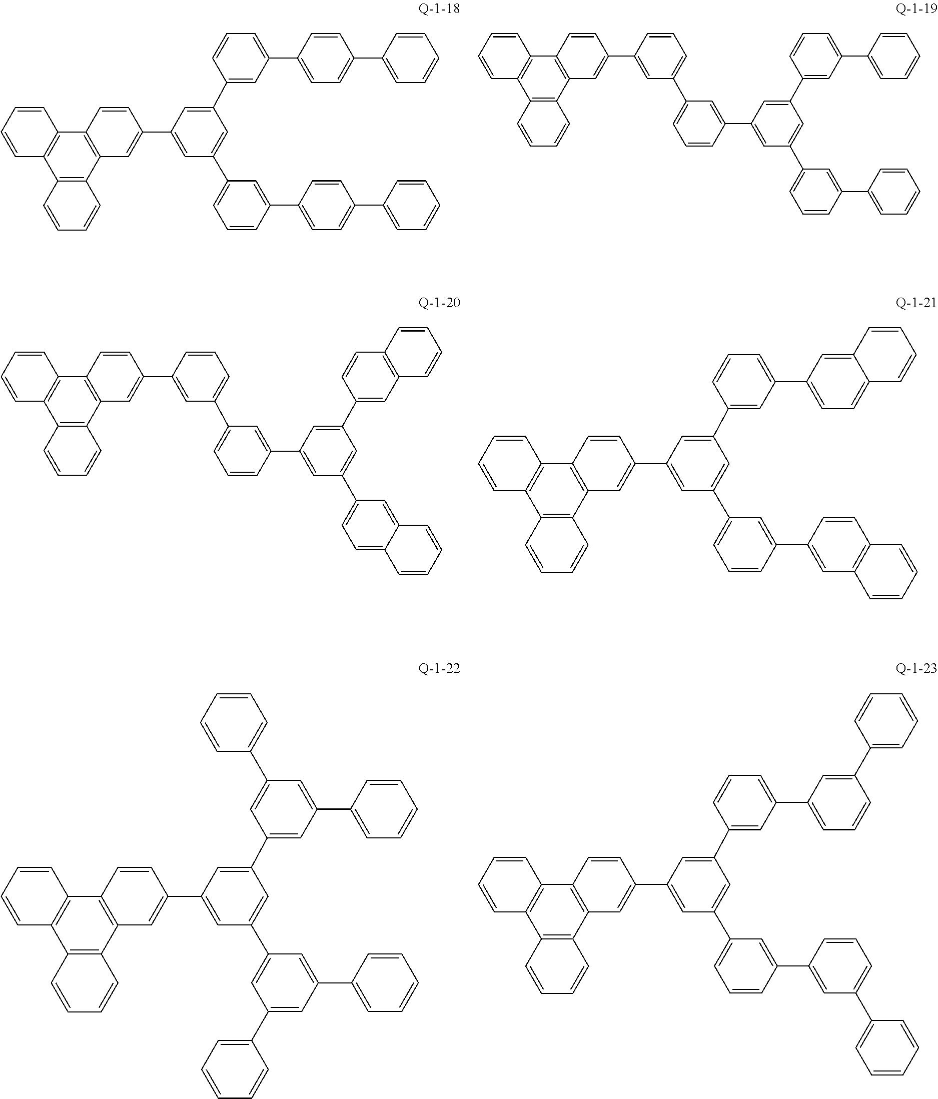

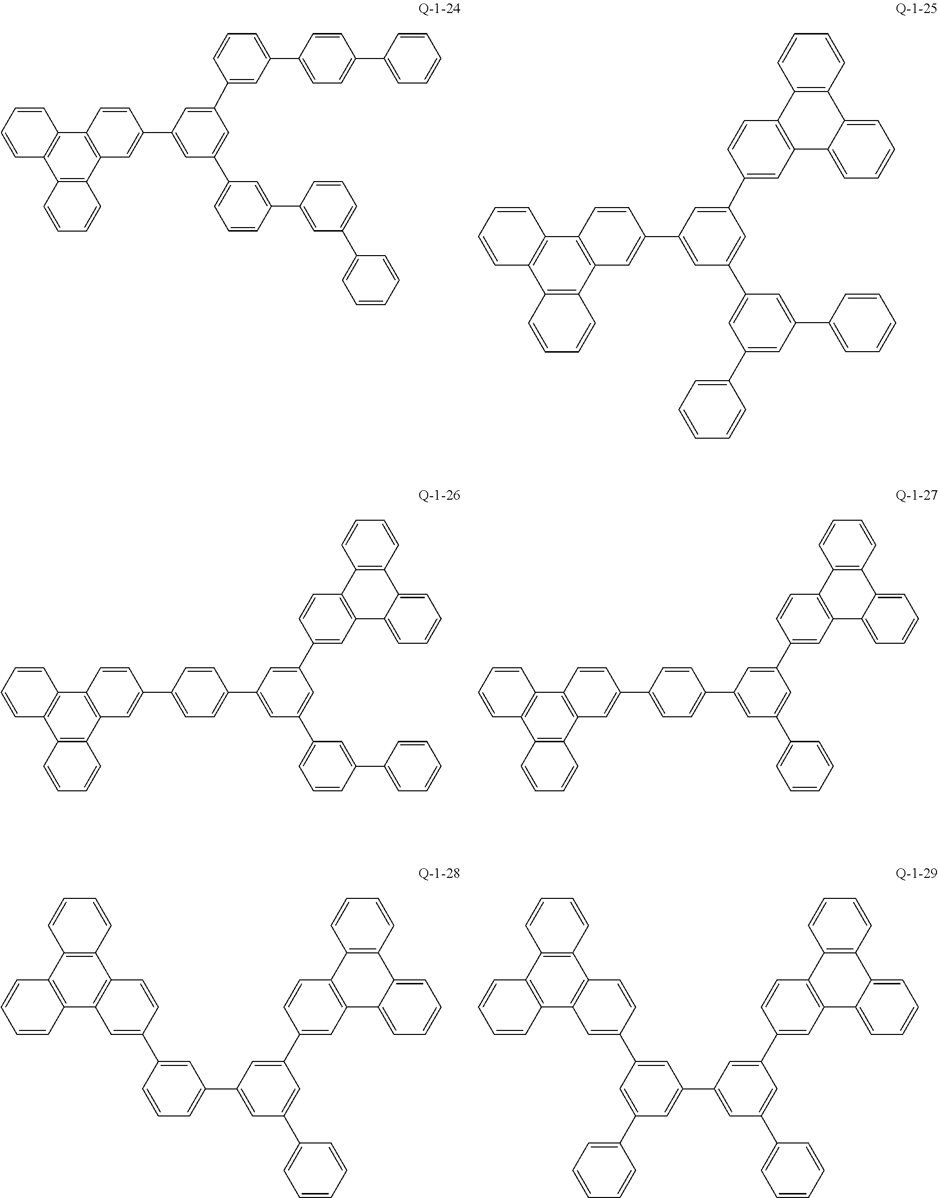

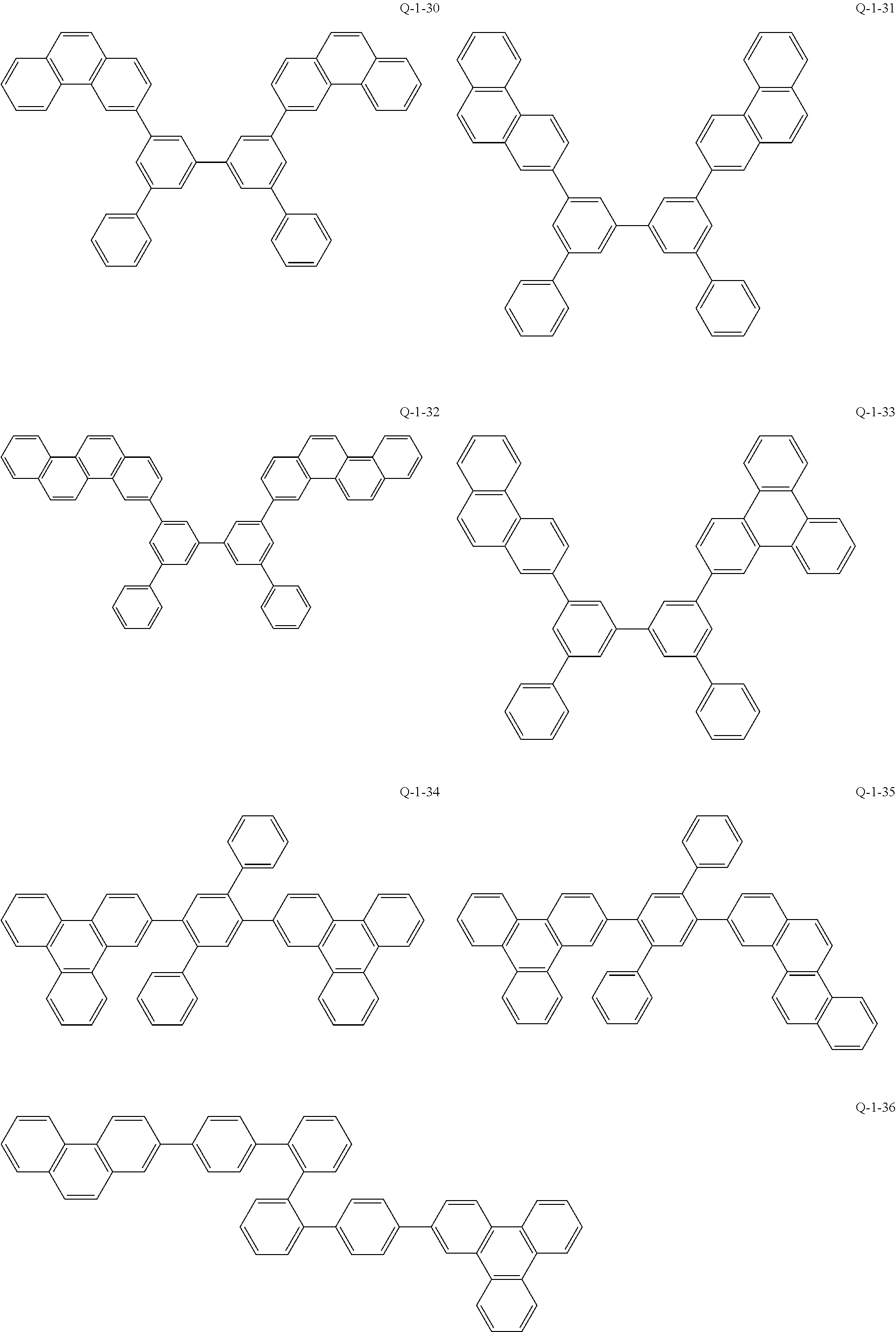

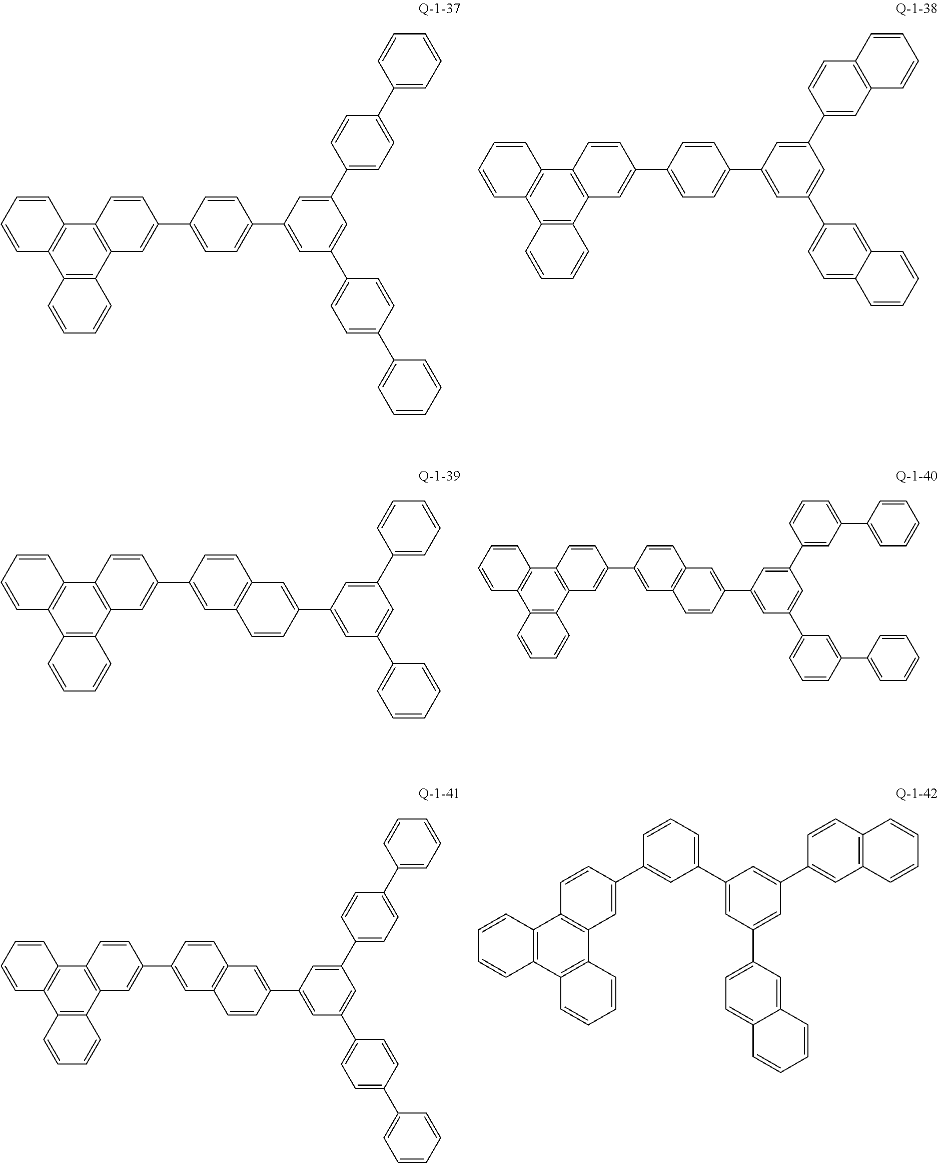

Exemplary compounds of the host compounds shown above are compounds having at least any one of a triphenylene ring, a naphthalene ring, a phenanthrene ring, a chrysene ring, and a fluoranthene ring in the skeleton and having no SP³ carbon. Therefore, since these compounds can further approach the dopant material of the present embodiment, the compounds are host materials that strongly interact with the dopant material and satisfactorily transfer energy to the dopant material of the present embodiment. Among the compounds, a compound having a triphenylene ring in the skeleton has high planarity, which is particularly preferable.

### (4) Assist Material

It is preferable that the light emitting layer further contains an assist material. Further, it is preferable that the assist material is a compound partially having any of the following structures.

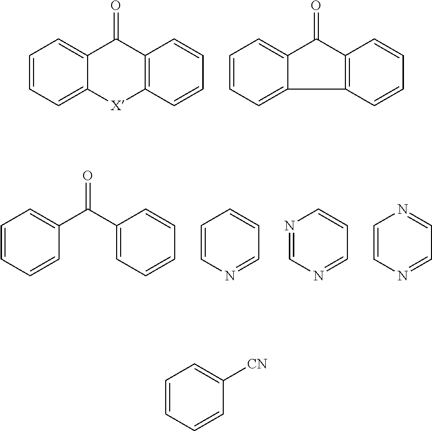

(In the structures shown above, X′ represents any of an oxygen atom, a sulfur atom, or a substituted or unsubstituted carbon atom.)

The structures shown above are effective because the structures have electron-withdrawing properties and can decrease the LUMO level of the assist material. The iridium complex represented by General Formula [1] has a high HOMO level and tends to easily trap positive holes, but tends to be difficult to trap electrons due to having a high LUMO level. Therefore, in a case where the light emitting layer contains an assist material having a low LUMO level, electrons are trapped in the light emitting layer, and thus an element with an appropriate carrier balance, high efficiency, and a long life is provided.

It is considered that since the assist material having any of the above-described structures as a partial structure has appropriately high electron-withdrawing properties and the structure has an appropriate size, an exciplex is unlikely to be formed with the dopant material according to the present embodiment, which is preferable. Examples of the assist material considered to easily form an exciplex with the dopant material according to the present embodiment include a compound having a triazine ring as a partial structure.

Further, the above-described structures may be unsubstituted or may have a substituent. Further, the carbon atom represented by X′ may be unsubstituted or may have a substituent. Examples of the substituent include a halogen atom, an alkyl group, an alkoxy group, an aryloxy group, a heteroaryloxy group, an aryl group, a heterocyclic group, a silyl group, and an amino group.

Examples of the halogen atom include fluorine, chlorine, bromine, and iodine, but the present disclosure is not limited thereto.

Examples of the alkyl group include a methyl group, an ethyl group, a normal propyl group, an isopropyl group, a normal butyl group, a tertiary butyl group, a secondary butyl group, an octyl group, a cyclohexyl group, a 1-adamantyl group, and a 2-adamantyl group, but the present disclosure is not limited thereto.

Examples of the alkoxy group include a methoxy group, an ethoxy group, a propoxy group, a 2-ethyl-octyloxy group, and a benzyloxy group, but the present disclosure is not limited thereto.

Examples of the aryloxy group include a phenoxy group and a naphthoxy group, but the present disclosure is not limited thereto.

Examples of the heteroaryloxy group include a furanyloxy group and a thienyloxy group, but the present disclosure is not limited thereto.

Examples of the aryl group include a phenyl group, a naphthyl group, an indenyl group, a biphenyl group, a terphenyl group, a fluorenyl group, a phenanthryl group, a triphenylenyl group, a pyrenyl group, an anthranyl group, a perylenyl group, a chrysenyl group, and a fluoranthenyl group, but the present disclosure is not limited thereto.

Examples of the heterocyclic group include a pyridyl group, a pyrimidyl group, a pyrazyl group, a triazyl group, a benzofuranyl group, a benzothiophenyl group, a dibenzofuranyl group, a dibenzothiophenyl group, an oxazolyl group, an oxadiazolyl group, a thiazolyl group, a thiadiazolyl group, a carbazolyl group, an acridinyl group, and a phenanthrolyl group, but the present disclosure is not limited thereto.

Examples of the silyl group include a trimethylsilyl group and a triphenylsilyl group, but the present disclosure is not limited thereto.

Examples of the amino group include a N-methylamino group, a N-ethylamino group, a N,N-dimethylamino group, a N,N-diethylamino group, a N-methyl-N-ethylamino group, a N-benzylamino group, a N-methyl-N-benzylamino group, a N,N-dibenzylamino group, an anilino group, a N,N-diphenylamino group, a N,N-dinaphthylamino group, a N,N-difluorenylamino group, a N-phenyl-N-tolylamino group, a N,N-ditolylamino group, a N-methyl-N-phenylamino group, a N,N-dianisolylamino group, a N-mesityl-N-phenylamino group, a N,N-dimesitylamino group, a N-phenyl-N-(4-tert-butylphenyl)amino group, a N-phenyl-N-(4-trifluoromethylphenyl)amino group, a N-piperidyl group, a carbazolyl group, and an acridyl group, but the present disclosure is not limited thereto.

Examples of the substituent that the alkyl group, the alkoxy group, the aryloxy group, the heteroaryloxy group, the aryl group, the heterocyclic group, the silyl group, and the amino group may further have include a deuterium atom, an alkyl group such as a methyl group, an ethyl group, a normal propyl group, an isopropyl group, a normal butyl group, or a tertiary butyl group, an aralkyl group such as a benzyl group, an aryl group such as a phenyl group or a biphenyl group, a heterocyclic group such as a pyridyl group or a pyrrolyl group, an amino group such as a dimethylamino group, a diethylamino group, a dibenzylamino group, a diphenylamino group, or a ditolylamino group, an alkoxy group such as a methoxy group, an ethoxy group, or a propoxy group, an aryloxy group such as a phenoxy group, a halogen atom such as fluorine, chlorine, bromine, or iodine, and a cyano group, but the present disclosure is not limited thereto.

### Specific Examples

Specific examples of the assist material are shown below, but the present disclosure is not limited thereto.

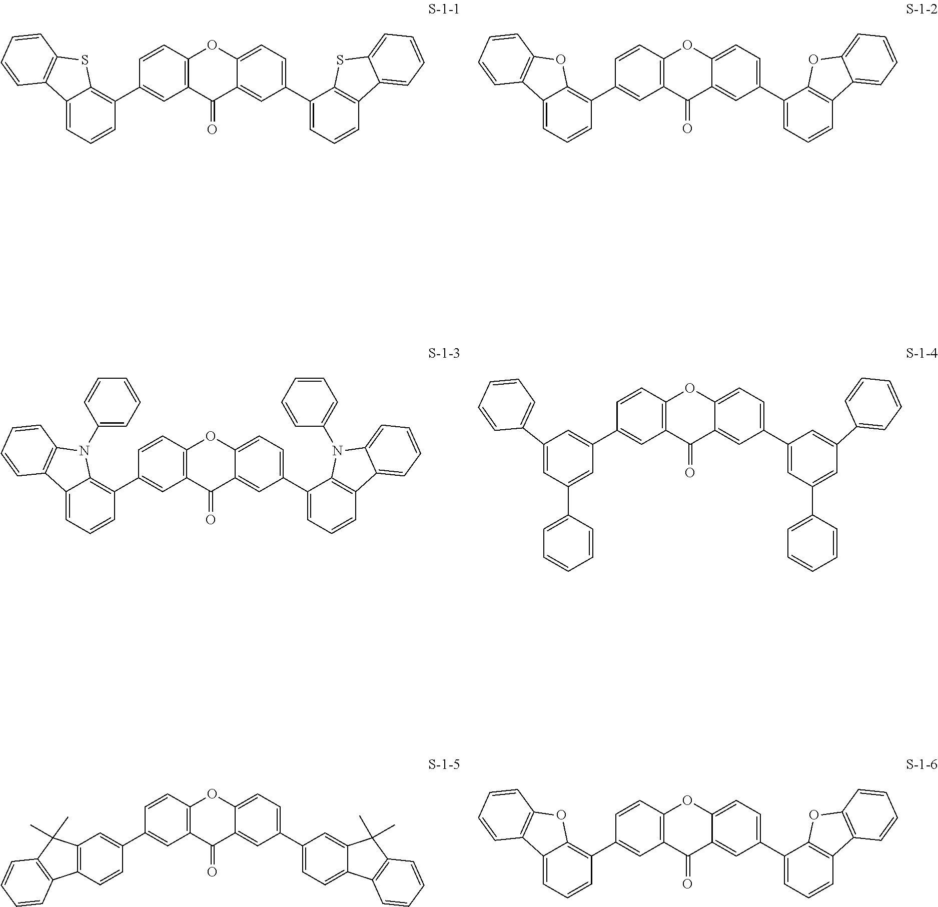 [SMILES: O=c1c2cc(-c3cccc4c3sc3ccccc34)ccc2oc2ccc(-c3cccc4c3sc3ccccc34)cc12 ; O=c1c2cc(-c3cccc4c3oc3ccccc34)ccc2oc2ccc(-c3cccc4c3oc3ccccc34)cc12 ; O=c1c2cc(-c3cccc4c5ccccc5n(-c5ccccc5)c34)ccc2oc2ccc(-c3cccc4c5ccccc5n(-c5ccccc5)c34)cc12 ; O=c1c2cc(-c3cc(-c4ccccc4)cc(-c4ccccc4)c3)ccc2oc2ccc(-c3cc(-c4ccccc4)cc(-c4ccccc4)c3)cc12 ; CC1(C)c2ccccc2-c2ccc(-c3ccc4oc5ccc(-c6ccc7c(c6)C(C)(C)c6ccccc6-7)cc5c(=O)c4c3)cc21 ; O=c1c2cc(-c3cccc4c3oc3ccccc34)ccc2oc2ccc(-c3cccc4c3oc3ccccc34)cc12]

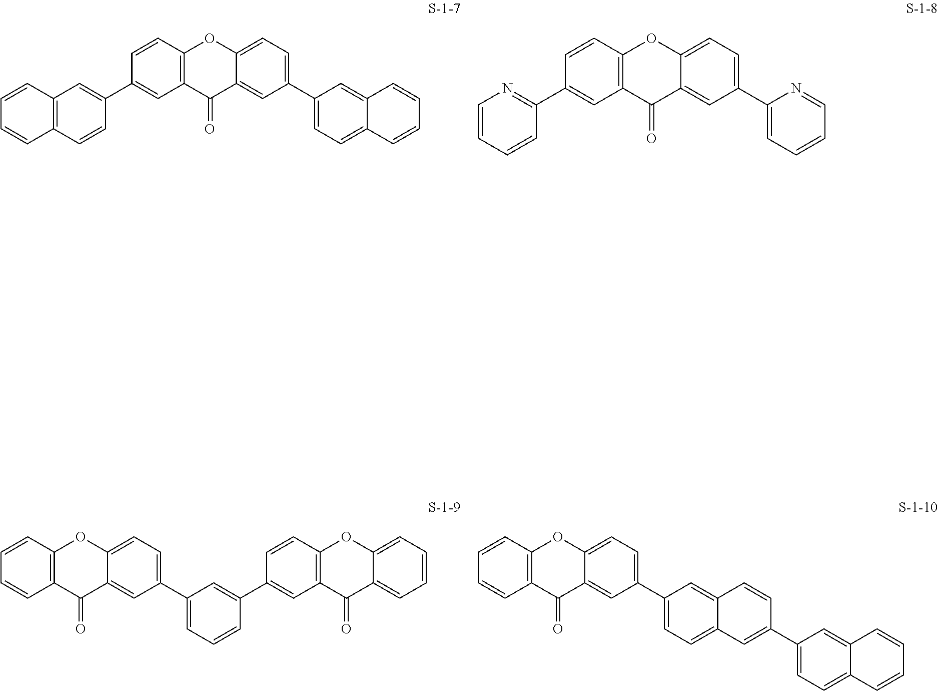 [SMILES: O=c1c2cc(-c3ccc4ccccc4c3)ccc2oc2ccc(-c3ccc4ccccc4c3)cc12 ; O=c1c2cc(-c3ccccn3)ccc2oc2ccc(-c3ccccn3)cc12 ; O=c1c2ccccc2oc2ccc(-c3cccc(-c4ccc5oc6ccccc6c(=O)c5c4)c3)cc12 ; O=c1c2ccccc2oc2ccc(-c3ccc4cc(-c5ccc6ccccc6c5)ccc4c3)cc12]

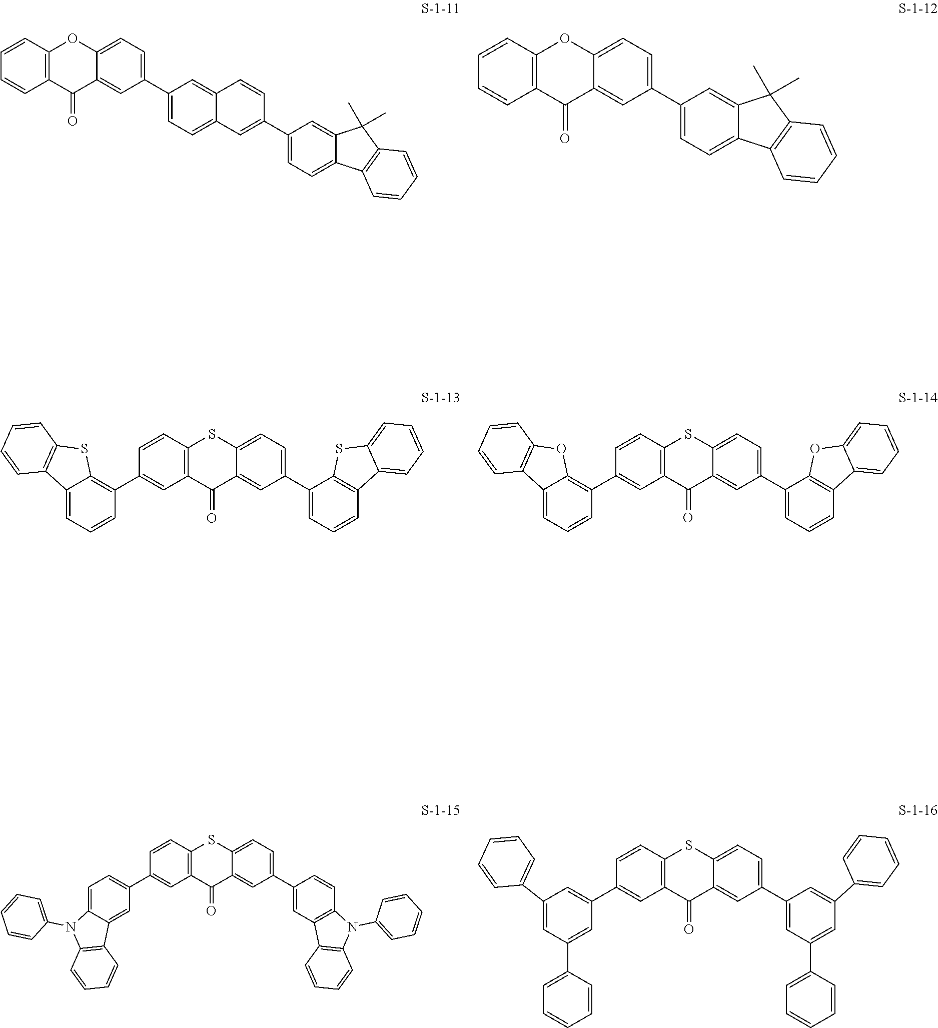 [SMILES: CC1(C)c2ccccc2-c2ccc(-c3ccc4cc(-c5ccc6oc7ccccc7c(=O)c6c5)ccc4c3)cc21 ; CC1(C)c2ccccc2-c2ccc(-c3ccc4oc5ccccc5c(=O)c4c3)cc21 ; O=c1c2cc(-c3cccc4c3sc3ccccc34)ccc2sc2ccc(-c3cccc4c3sc3ccccc34)cc12 ; O=c1c2cc(-c3cccc4c3oc3ccccc34)ccc2sc2ccc(-c3cccc4c3oc3ccccc34)cc12 ; O=c1c2cc(-c3ccc4c(c3)c3ccccc3n4-c3ccccc3)ccc2sc2ccc(-c3ccc4c(c3)c3ccccc3n4-c3ccccc3)cc12 ; O=c1c2cc(-c3cc(-c4ccccc4)cc(-c4ccccc4)c3)ccc2sc2ccc(-c3cc(-c4ccccc4)cc(-c4ccccc4)c3)cc12]

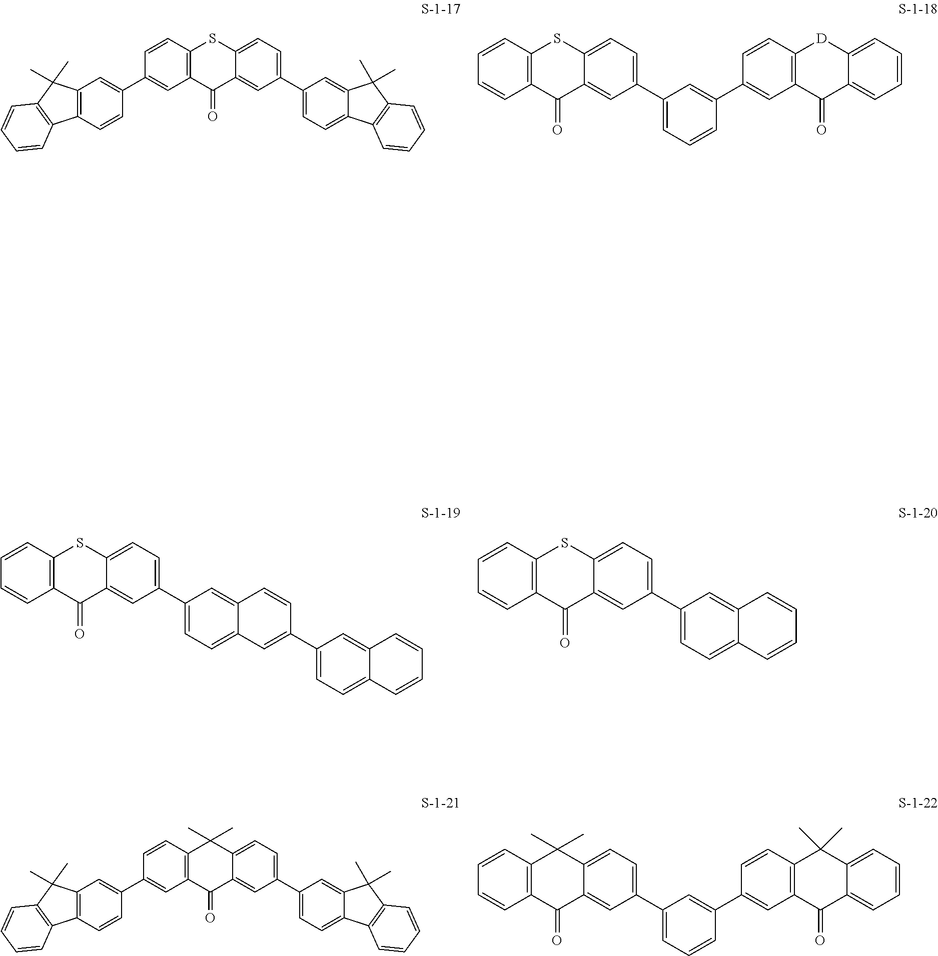

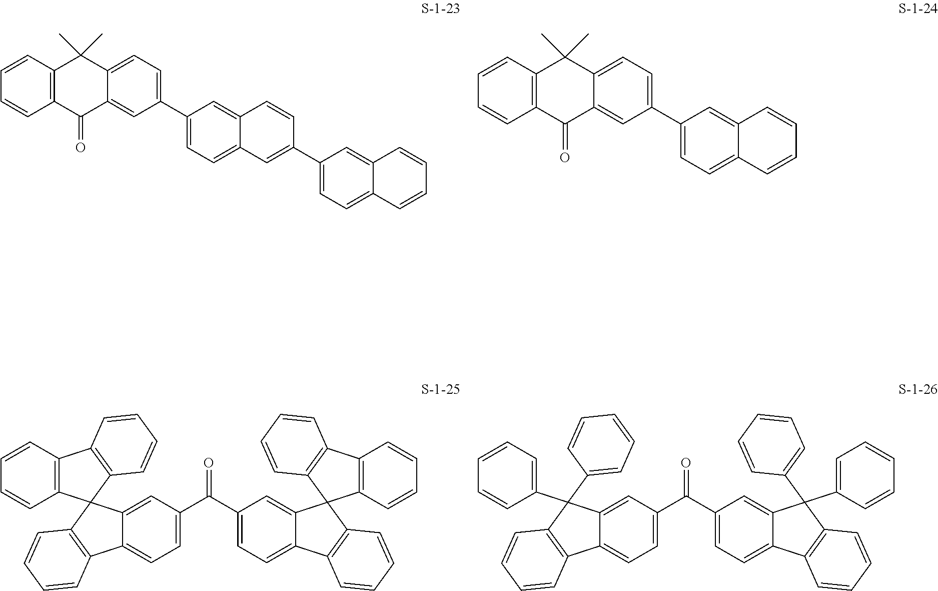 [SMILES: CC1(C)c2ccccc2C(=O)c2cc(-c3ccc4cc(-c5ccc6ccccc6c5)ccc4c3)ccc21 ; CC1(C)c2ccccc2C(=O)c2cc(-c3ccc4ccccc4c3)ccc21 ; O=C(c1ccc2c(c1)C1(c3ccccc3-c3ccccc31)c1ccccc1-2)c1ccc2c(c1)C1(c3ccccc3-c3ccccc31)c1ccccc1-2 ; O=C(c1ccc2c(c1)C(c1ccccc1)(c1ccccc1)c1ccccc1-2)c1ccc2c(c1)C(c1ccccc1)(c1ccccc1)c1ccccc1-2]

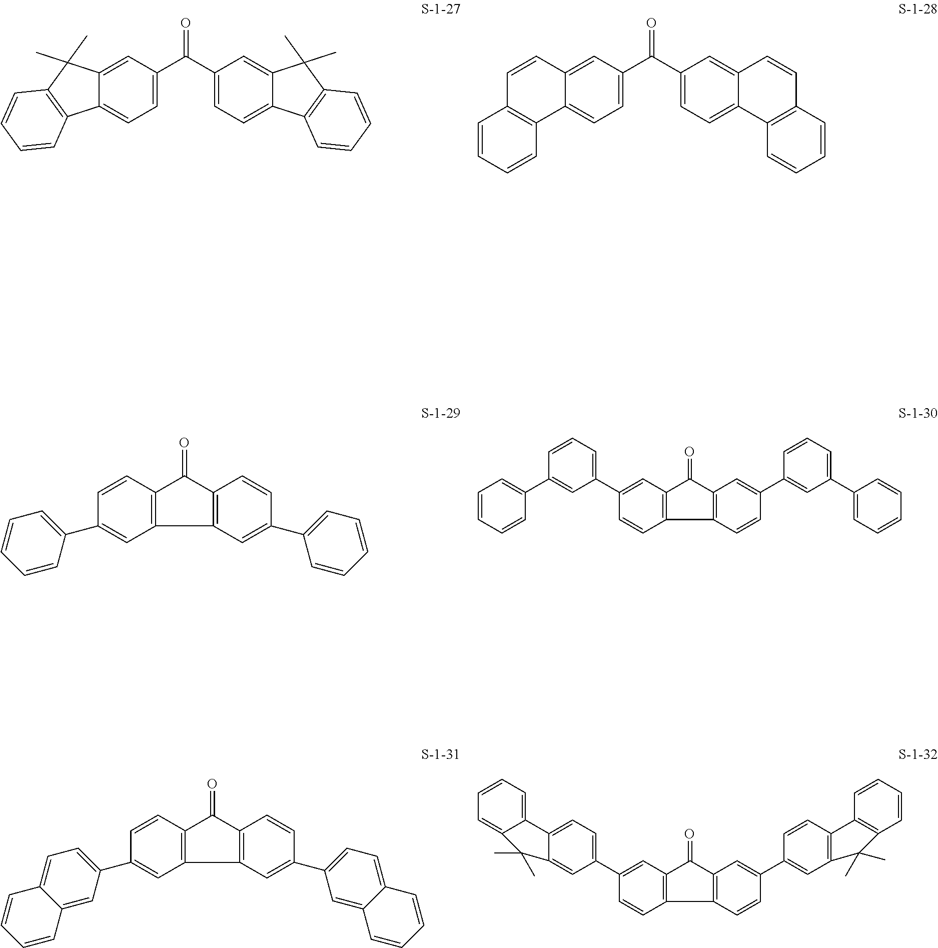 [SMILES: CC1(C)c2ccccc2-c2ccc(C(=O)c3ccc4c(c3)C(C)(C)c3ccccc3-4)cc21 ; O=C(c1ccc2c(ccc3ccccc32)c1)c1ccc2c(ccc3ccccc32)c1 ; O=C1c2ccc(-c3ccccc3)cc2-c2cc(-c3ccccc3)ccc21 ; O=C1c2cc(-c3cccc(-c4ccccc4)c3)ccc2-c2ccc(-c3cccc(-c4ccccc4)c3)cc21 ; O=C1c2ccc(-c3ccc4ccccc4c3)cc2-c2cc(-c3ccc4ccccc4c3)ccc21 ; CC1(C)c2ccccc2-c2ccc(-c3ccc4c(c3)C(=O)c3cc(-c5ccc6c(c5)C(C)(C)c5ccccc5-6)ccc3-4)cc21]

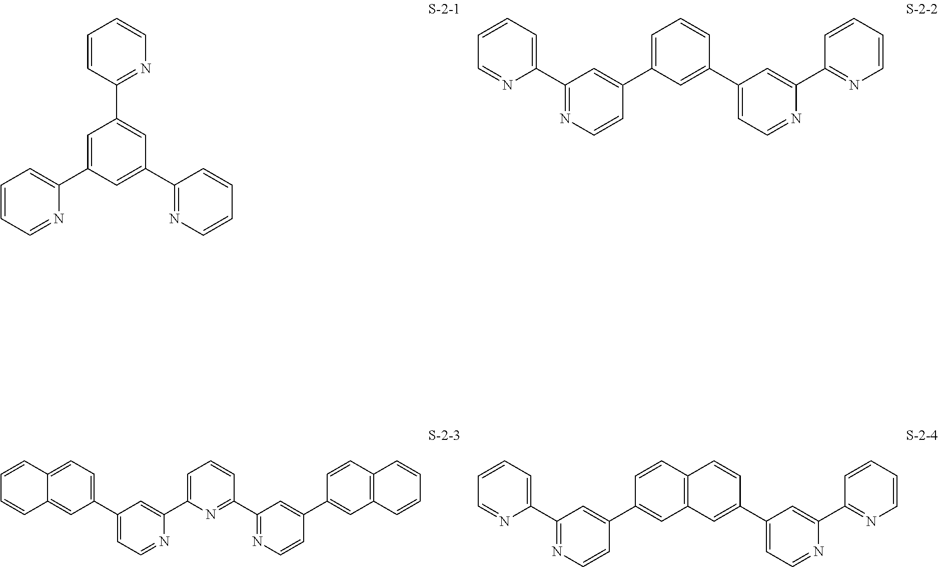 [SMILES: c1ccc(-c2cc(-c3ccccn3)cc(-c3ccccn3)c2)nc1 ; c1ccc(-c2cc(-c3cccc(-c4ccnc(-c5ccccn5)c4)c3)ccn2)nc1 ; c1cc(-c2cc(-c3ccc4ccccc4c3)ccn2)nc(-c2cc(-c3ccc4ccccc4c3)ccn2)c1 ; c1ccc(-c2cc(-c3ccc4ccc(-c5ccnc(-c6ccccn6)c5)cc4c3)ccn2)nc1]

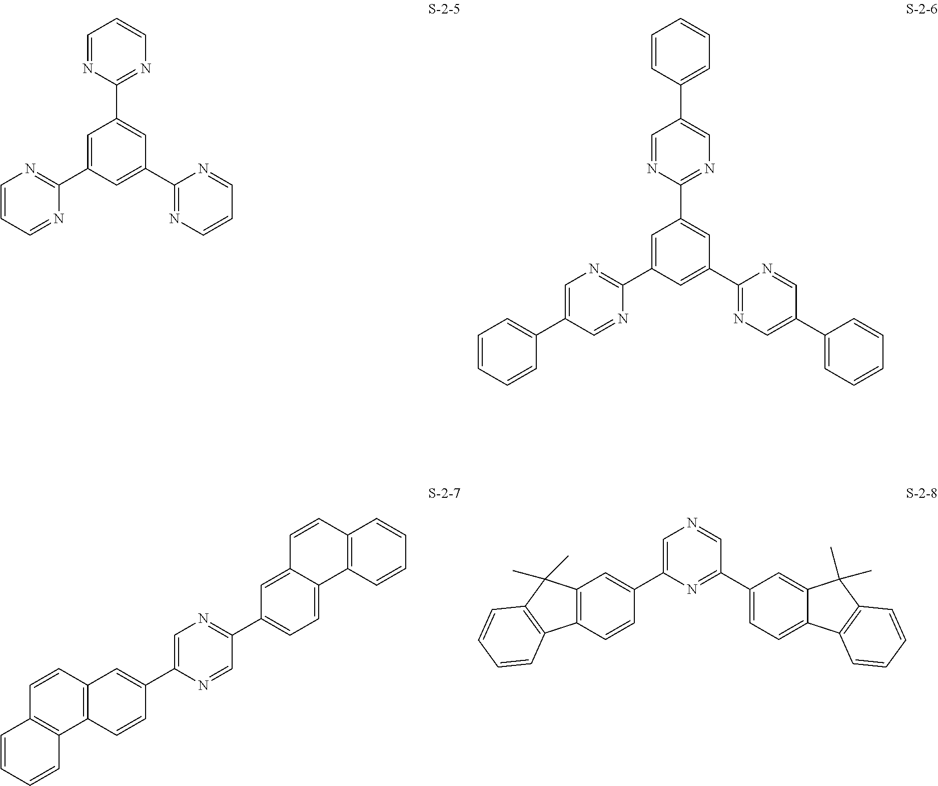 [SMILES: c1cnc(-c2cc(-c3ncccn3)cc(-c3ncccn3)c2)nc1 ; c1ccc(-c2cnc(-c3cc(-c4ncc(-c5ccccc5)cn4)cc(-c4ncc(-c5ccccc5)cn4)c3)nc2)cc1 ; c1ccc2c(c1)ccc1cc(-c3cnc(-c4ccc5c(ccc6ccccc65)c4)cn3)ccc12 ; CC1(C)c2ccccc2-c2ccc(-c3cncc(-c4ccc5c(c4)C(C)(C)c4ccccc4-5)n3)cc21]

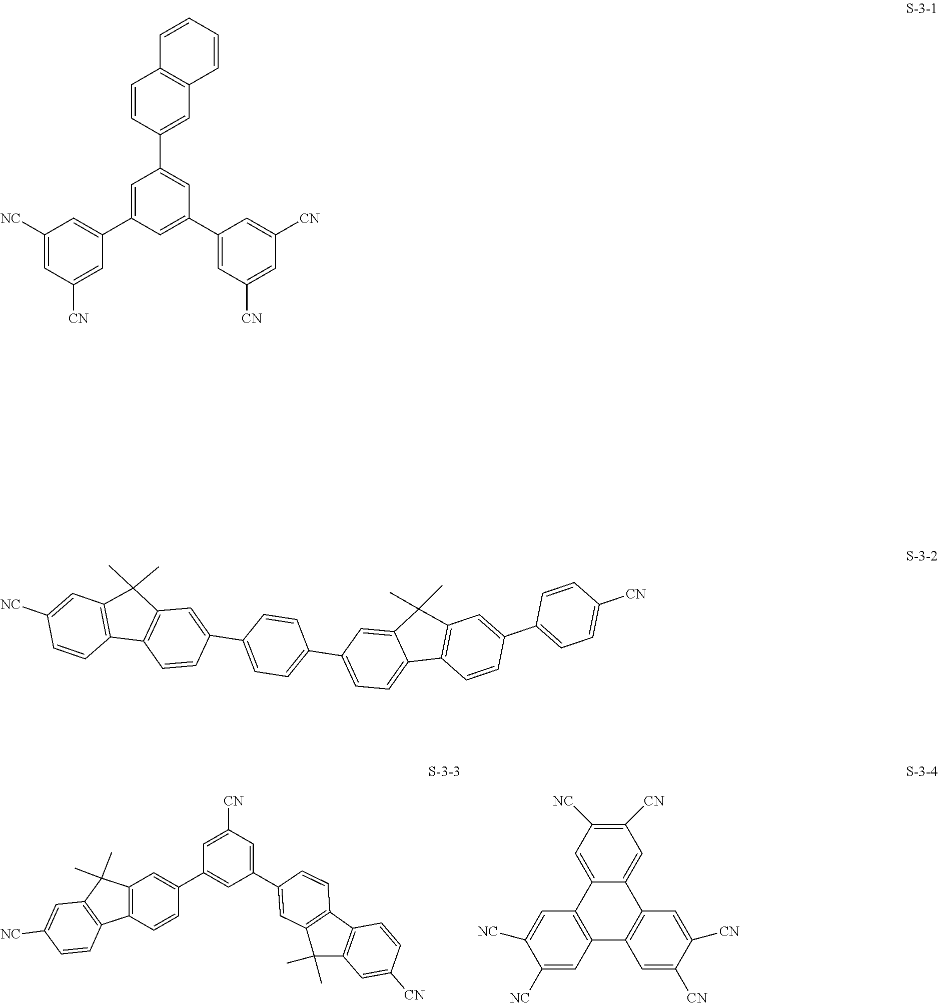 [SMILES: N#Cc1cc(C#N)cc(-c2cc(-c3cc(C#N)cc(C#N)c3)cc(-c3ccc4ccccc4c3)c2)c1 ; CC1(C)c2cc(C#N)ccc2-c2ccc(-c3ccc(-c4ccc5c(c4)C(C)(C)c4cc(-c6ccc(C#N)cc6)ccc4-5)cc3)cc21 ; CC1(C)c2cc(C#N)ccc2-c2ccc(-c3cc(C#N)cc(-c4ccc5c(c4)C(C)(C)c4cc(C#N)ccc4-5)c3)cc21 ; N#Cc1cc2c3cc(C#N)c(C#N)cc3c3cc(C#N)c(C#N)cc3c2cc1C#N]

The concentration of the assist material is preferably 0.1% by mass or greater and 45% by mass or less and more preferably 58 by mass or greater and 40% by mass or less with respect to the total concentration of the light emitting layer.

### (5) Details of Organic Light Emitting Element

The organic light emitting element of the present embodiment includes at least a first electrode and a second electrode and an organic compound layer disposed between these electrodes. One of the first electrode and the second electrode is an anode and the other is a cathode. In the organic light emitting element of the present embodiment, the organic compound layer may be a single layer or a laminate formed of a plurality of layers as long as the organic compound layer includes a light emitting layer. Here, when the organic compound layer is a laminate formed of a plurality of layers, the organic compound layer may include, in addition to the light emitting layer, a hole injection layer, a hole transport layer, an electron blocking layer, a hole/exciton blocking layer, an electron transport layer, and an electron injection layer. Further, the light emitting layer may be a single layer or a laminate formed of a plurality of layers.

In the organic light emitting element of the present embodiment, at least one of the organic compound layers described above contains the organic compound of the present embodiment. Specifically, the organic compound according to the present embodiment is contained in any of the light emitting layer, the hole injection layer, the hole transport layer, the electron blocking layer, the hole/exciton blocking layer, the electron transport layer, or the electron injection layer described above. It is preferable that the organic compound according to the present embodiment be contained in a light emitting layer.

In the organic light emitting element of the present embodiment, when the organic compound according to the present embodiment is contained in a light emitting layer, the light emitting layer may be a layer formed of only the organic compound according to the present embodiment or a layer formed of the organic compound according to the present embodiment and other compounds. Here, when the light emitting layer is a layer formed of the organic compound according to the present embodiment and other compounds, the organic compound according to the present embodiment may be used as a host or a guest (dopant) in the light emitting layer. Further, the organic compound may be used as an assist material that can be contained in the light emitting layer. Here, the host is a compound having the highest mass ratio among the compounds constituting the light emitting layer. Further, the guest is a compound that has a mass ratio less than that of the host among the compounds constituting the light emitting layer and is responsible for main light emission. Further, the assist material is a compound which has a mass ratio less than that of the host among the compounds constituting the light emitting layer and supports light emission of the guest. In addition, the assist material is referred to as a second host. The host material can be referred to as a first compound and the assist material can also be referred to as a second compound.

Here, when the organic compound according to the present embodiment is used as the guest of the light emitting layer, the concentration of the guest is preferably 0.01% by mass or greater and 30% by mass or less and more preferably 2% by mass or greater and 20% by mass or less with respect to the total concentration of the light emitting layer.

As a result of various research conducted by the present inventors, it was found that when the organic compound according to the present embodiment is used as a host or a guest of the light emitting layer, particularly as a guest of the light emitting layer, an element that outputs light with high efficiency and high brightness and has extremely high durability can be obtained. The light emitting layer may be formed of a single layer or a plurality of layers, and emission colors can be mixed by allowing the light emitting layer to contain light emitting materials having other emission colors. The plurality of layers denote a state where the light emitting layer and other light emitting layers are laminated. In this case, the emission color of the organic light emitting element is not particularly limited. More specifically, the emission color may be white or an intermediate color. When the emission color is white, other light emitting layers emit light of colors different from the emission color of the light emitting layer. Further, the film formation is also performed by a vapor deposition method or a coating film forming method. The details will be described in examples below.

The organic compound according to the present embodiment can be used as a constituent material for the organic compound layer other than the light emitting layer constituting the organic light emitting element of the present embodiment. Specifically, the organic compound may be used as a constituent material for an electron transport layer, an electron injection layer, a hole transport layer, a hole injection layer, a hole blocking layer, or the like. In this case, the emission color of the organic light emitting element is not particularly limited. More specifically, the emission color may be white or an intermediate color.

<Compound Other than Organic Compound of Present Embodiment>

Here, known low-molecular-weight and high-molecular-weight hole injecting compounds or hole transporting compounds, compounds serving as a host, light emitting compounds, electron injecting compounds, or electron transporting compounds of the related art can be used together as necessary in addition to the organic compound according to the present embodiment. Examples of such compounds will be described below.

A material with high hole mobility formed such that hole injection from an anode is easily carried out and the injected holes can be transported to the light emitting layer is preferable as the hole injecting and transporting material. Further, a material with a high glass transition temperature is preferable from the viewpoint of suppressing deterioration of the film quality such as crystallization in the organic light emitting element. Examples of the low-molecular-weight and high-molecular-weight materials having a hole injecting transporting ability include a triarylamine derivative, an arylcarbazole derivative, a phenylene diamine derivative, a stilbene derivative, a phthalocyanine derivative, a porphyrin derivative, poly(vinylcarbazole), poly(thiophene), and other conductive polymers. Further, the above-described hole injecting and transporting material is suitably used in the electron blocking layer. Specific examples of the compound used as the hole injecting and transporting material will be shown below, but the present disclosure is not limited thereto.

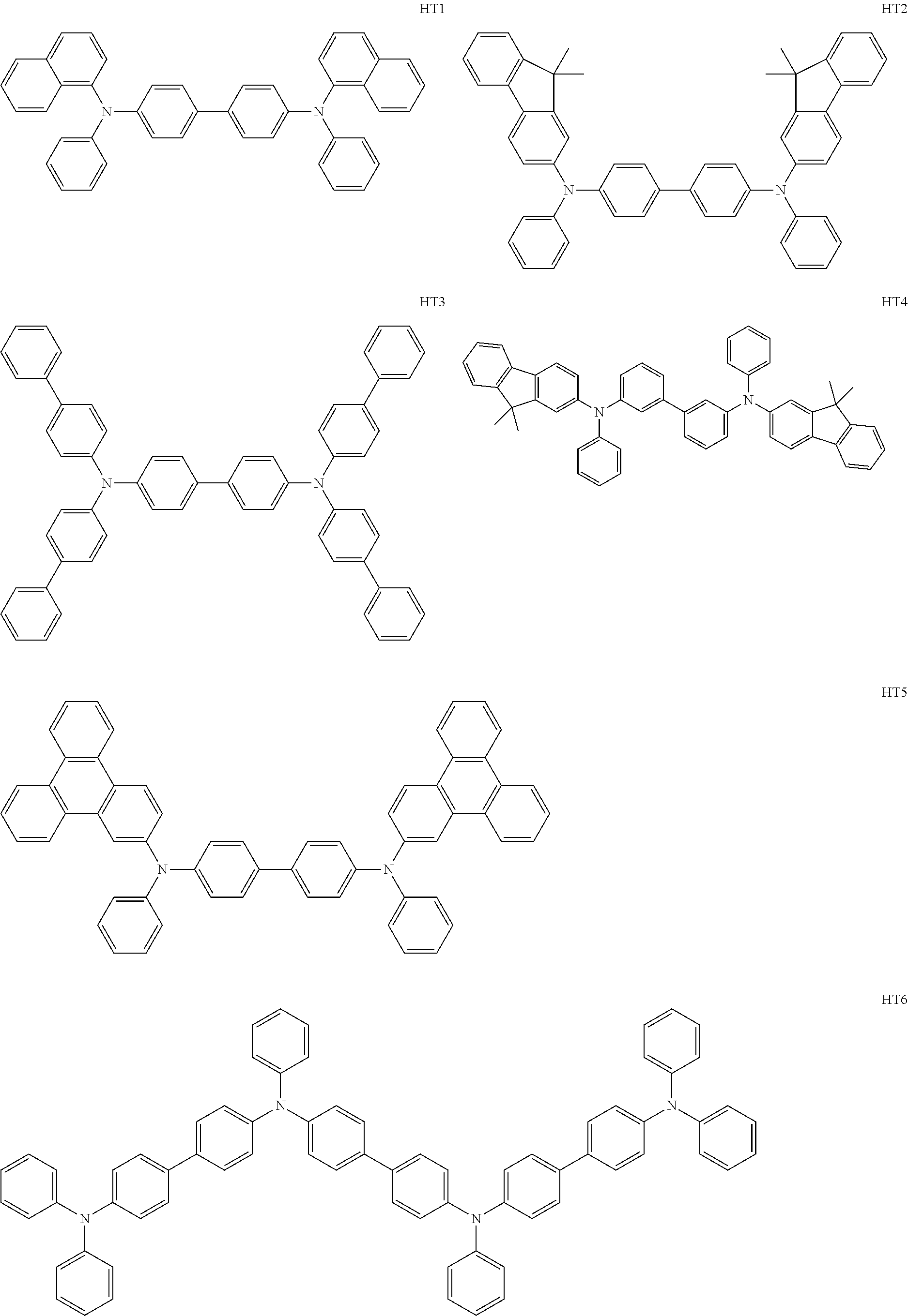

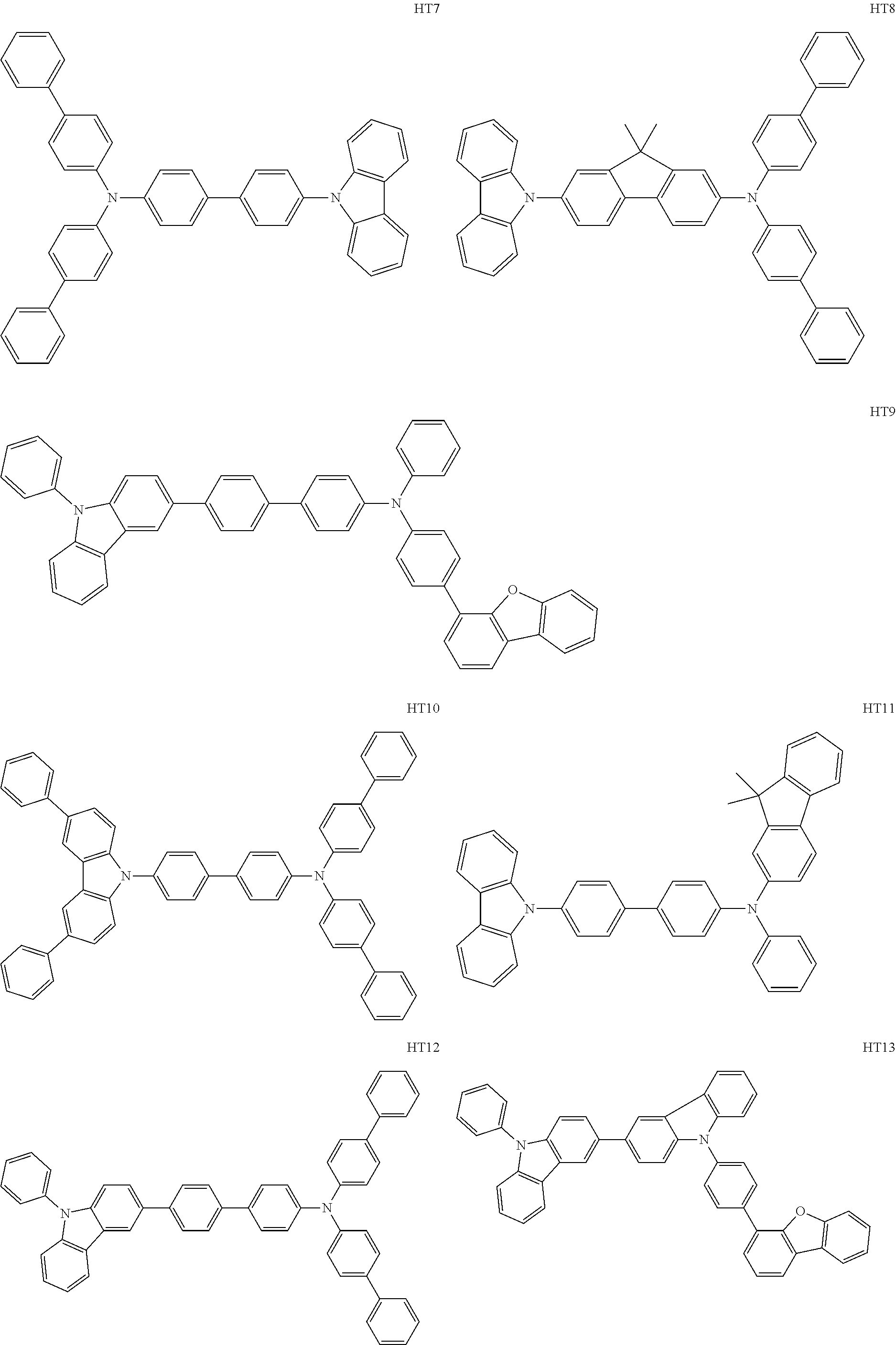

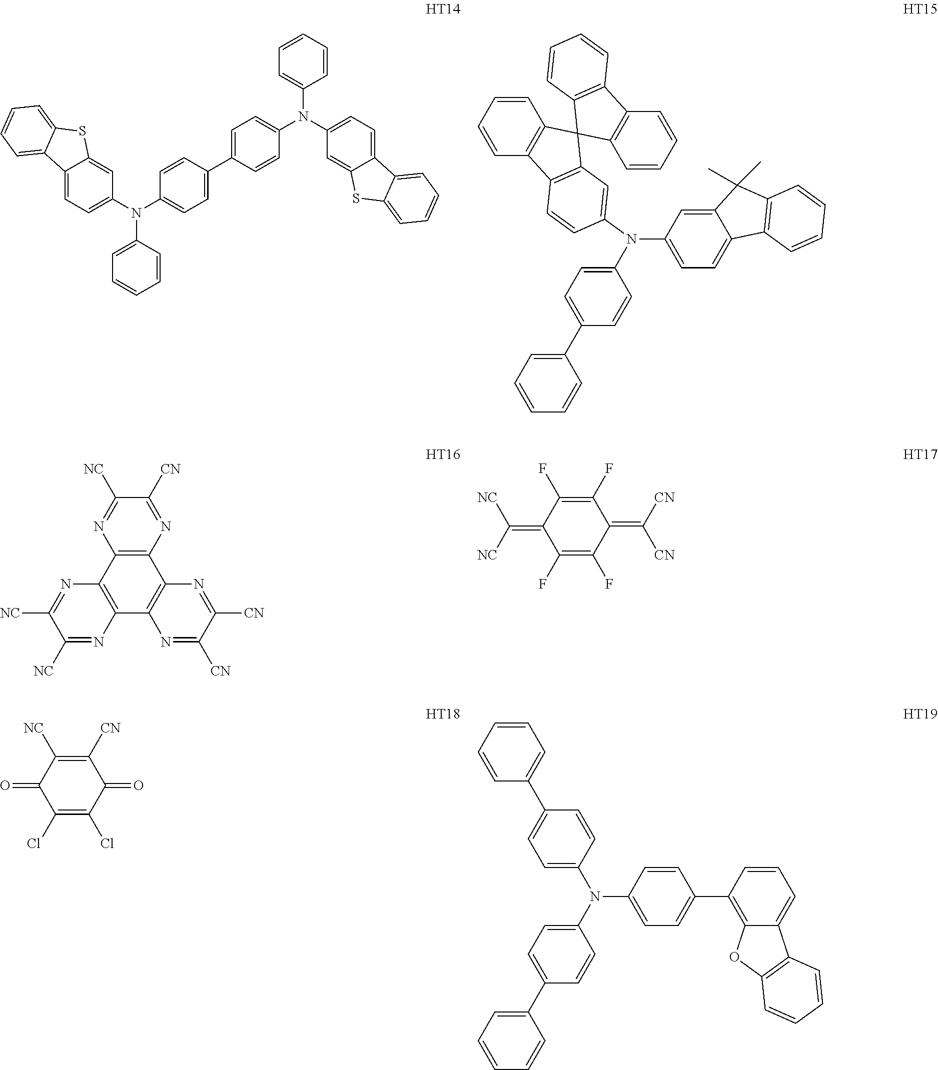 [SMILES: c1ccc(N(c2ccc(-c3ccc(N(c4ccccc4)c4ccc5c(c4)sc4ccccc45)cc3)cc2)c2ccc3c(c2)sc2ccccc23)cc1 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; N#CC1=C(C#N)C(=O)C(Cl)=C(Cl)C1=O ; c1ccc(-c2ccc(N(c3ccc(-c4ccccc4)cc3)c3ccc(-c4cccc5c4oc4ccccc45)cc3)cc2)cc1]

Among the examples of the positive hole transport material, materials HT16 to HT18 can reduce the driving voltage by being used in a layer adjacent to the anode. The material HT16 has been widely used in an organic light emitting element. Materials HT2, HT3, HT4, HT5, HT6, HT10, and HT12 may be used in an organic compound layer adjacent to the material HT16. Further, a plurality of materials may be used in one organic compound layer.

Examples of the light emitting material mainly related to the light emitting function include a fused ring compound (such as a fluorene derivative, a naphthalene derivative, a pyrene derivative, a perylene derivative, a tetracene derivative, an anthracene derivative, or rubrene), a quinacridone derivative, a coumarin derivative, a stilbene derivative, an organic aluminum complex such as tris(8-quinolinolato)aluminum, an iridium complex, a platinum complex, a rhenium complex, a copper complex, a europium complex, a ruthenium complex, and a polymer derivative such as a poly(phenylenevinylene) derivative, a poly(fluorene) derivative, or a poly(phenylene) derivative. Specific examples of the compound used as the light emitting material are shown below, but the present disclosure is not limited thereto.

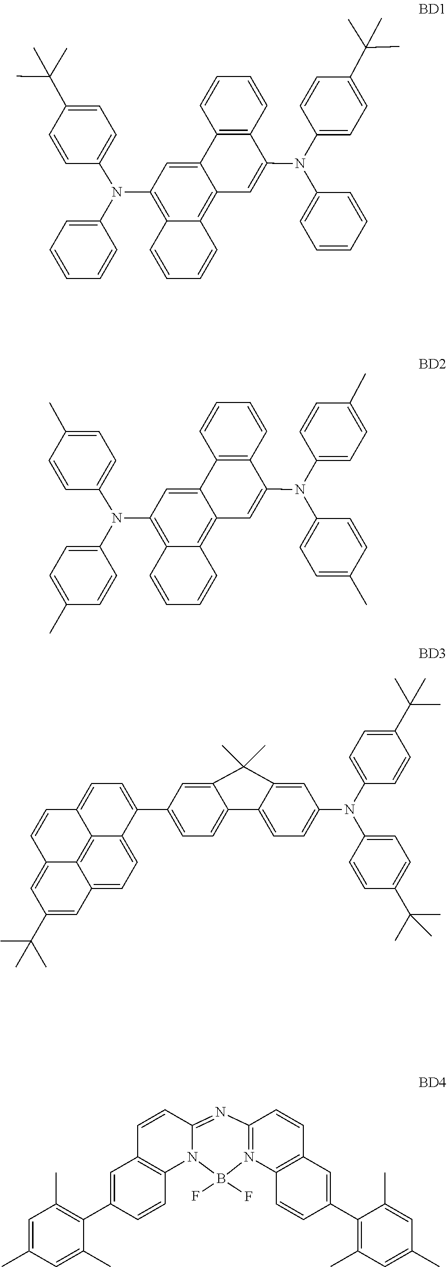

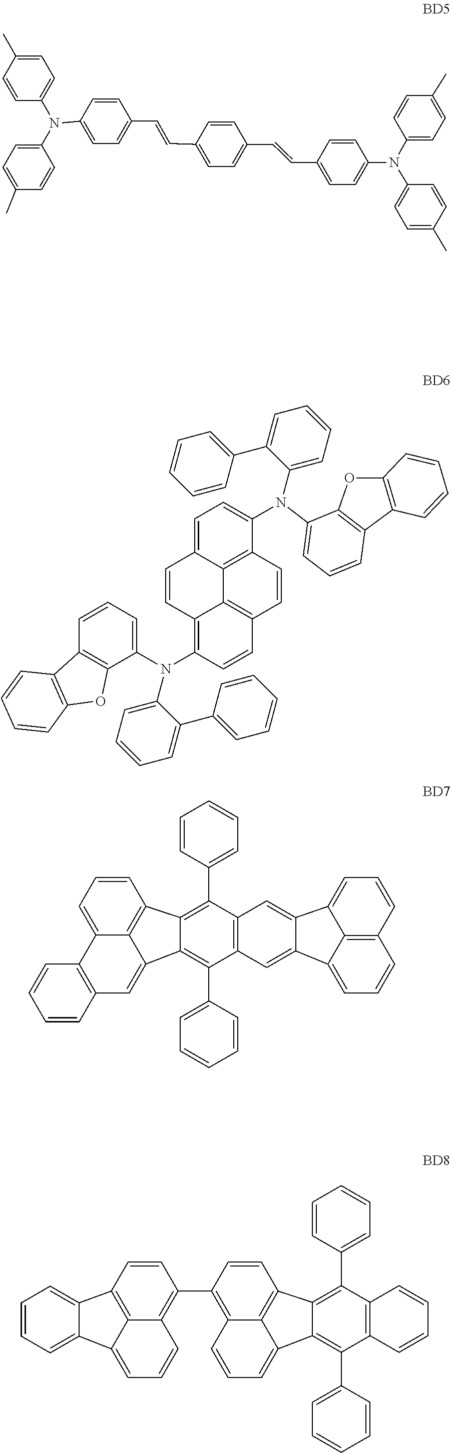

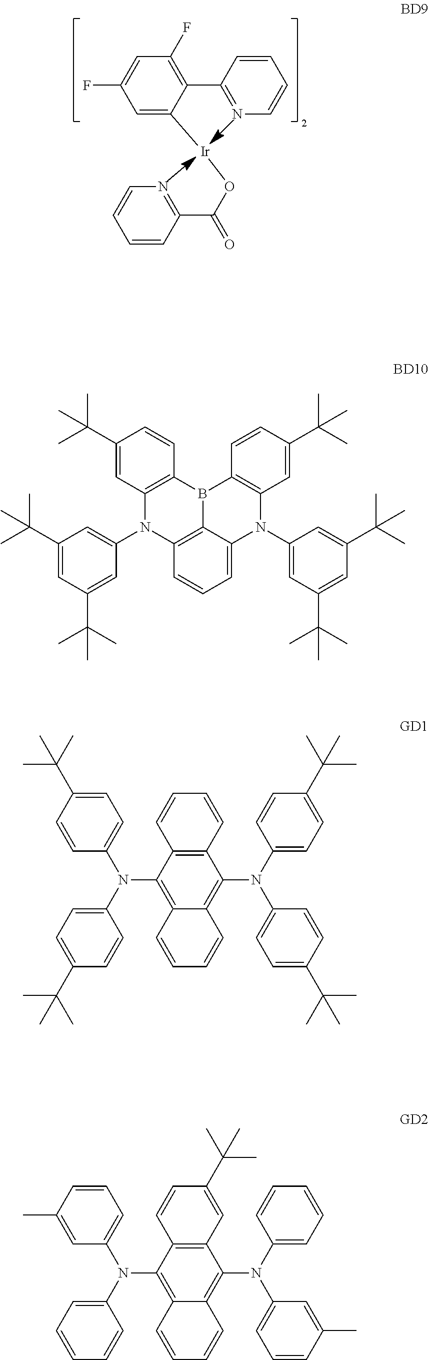

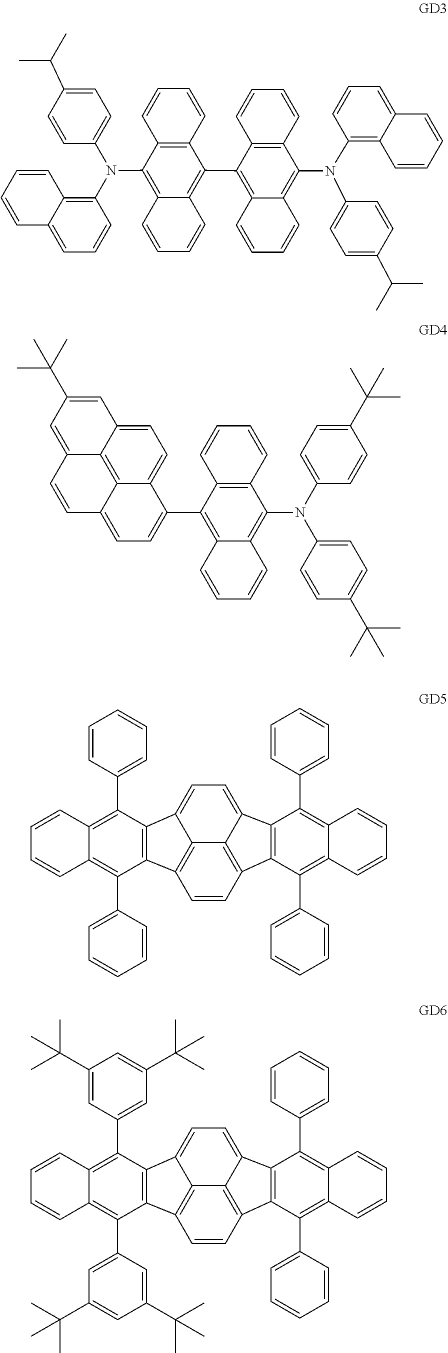

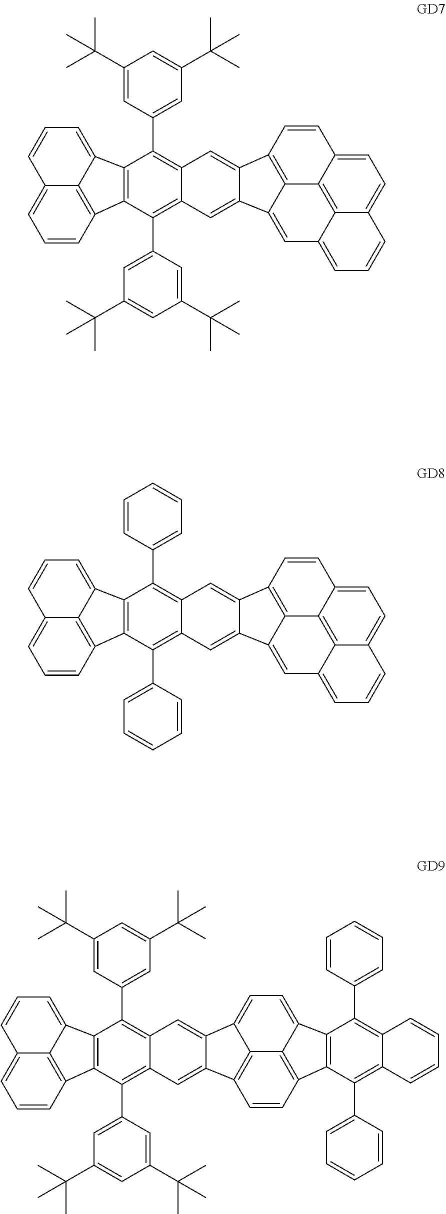

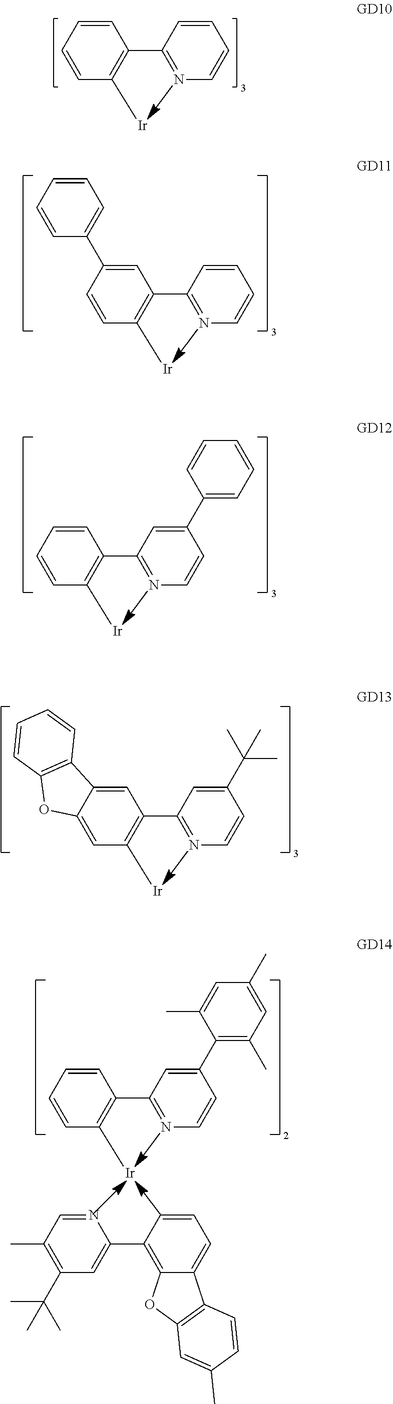

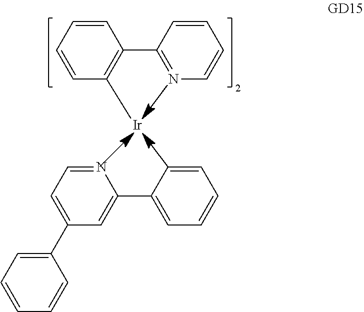

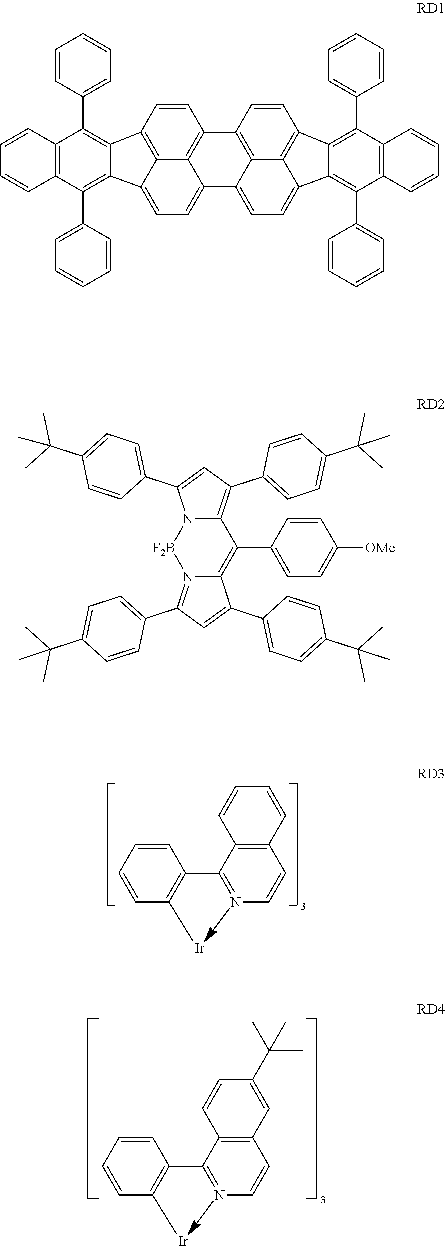

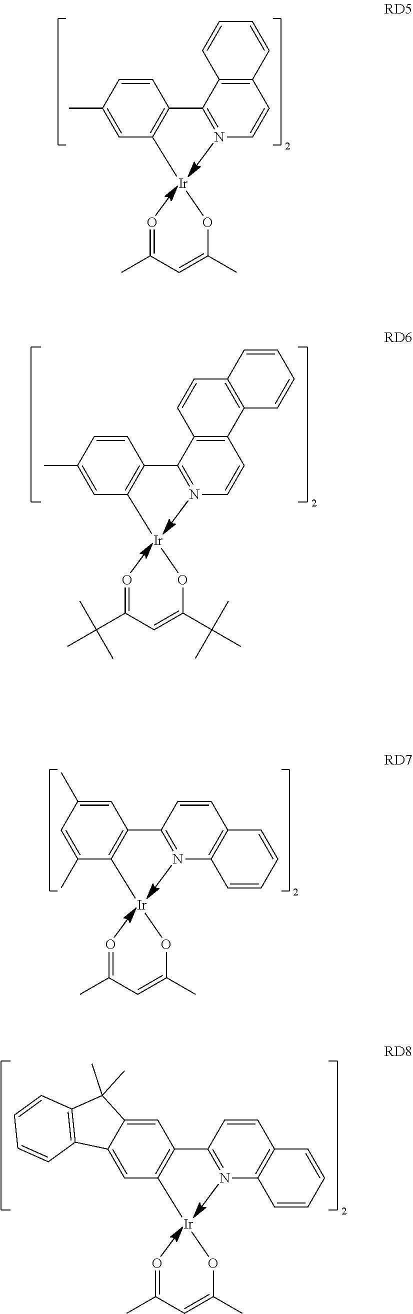

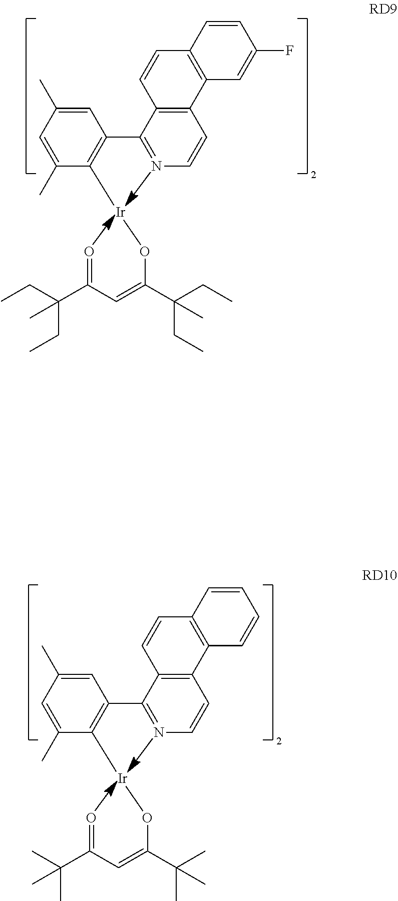

It is preferable that the light emitting material be a hydrocarbon compound from the viewpoint that a decrease in emission efficiency due to formation of an exciplex and a decrease in color purity caused by a change in emission spectrum of the light emitting material due to formation of an exciplex can be reduced. The hydrocarbon compound is a compound formed of only carbon and hydrogen, and corresponds to BD7, BD8, GD5 to GD9, and RD1 in the exemplary compounds shown above. In a case where the light emitting material is a fused polycycle having a 5-membered ring, since the ionization potential is high, oxidation is unlikely to be made, and an element with high durability and a long life is obtained, which is preferable. Such a light emitting material corresponds to BD7, BD8, GD5 to GD9, and RD1 among the exemplary compounds shown above.

Examples of the host material or the assist material contained in the light emitting layer include an aromatic hydrocarbon compound and a derivative thereof, a carbazole derivative, a dibenzofuran derivative, a dibenzothiophene derivative, an organic aluminum complex such as tris(8-quinolinolato)aluminum, and an organic beryllium complex. Specific examples of the compound used as the host material or the assist material contained in the light emitting layer are shown below, but the present disclosure is not limited thereto.

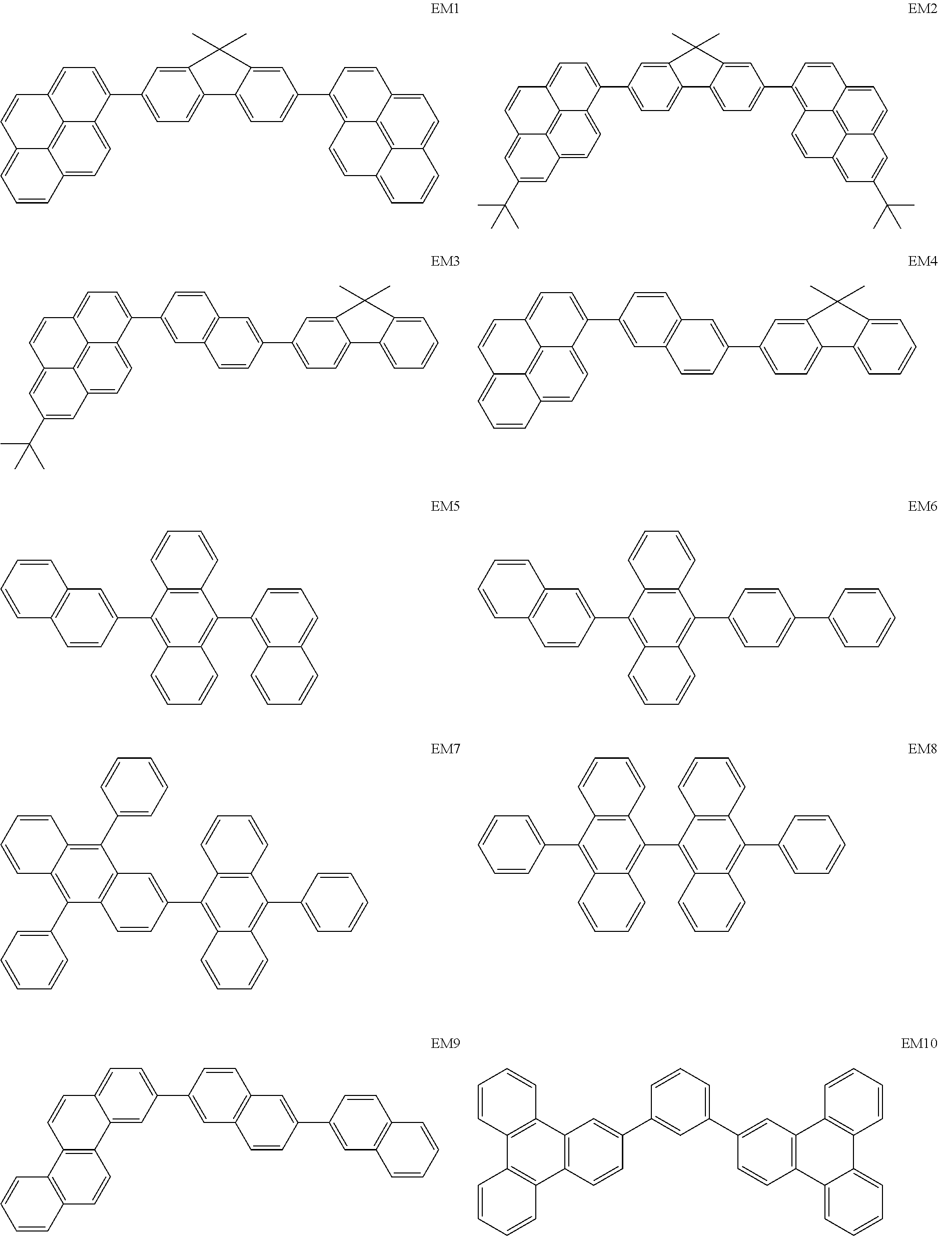

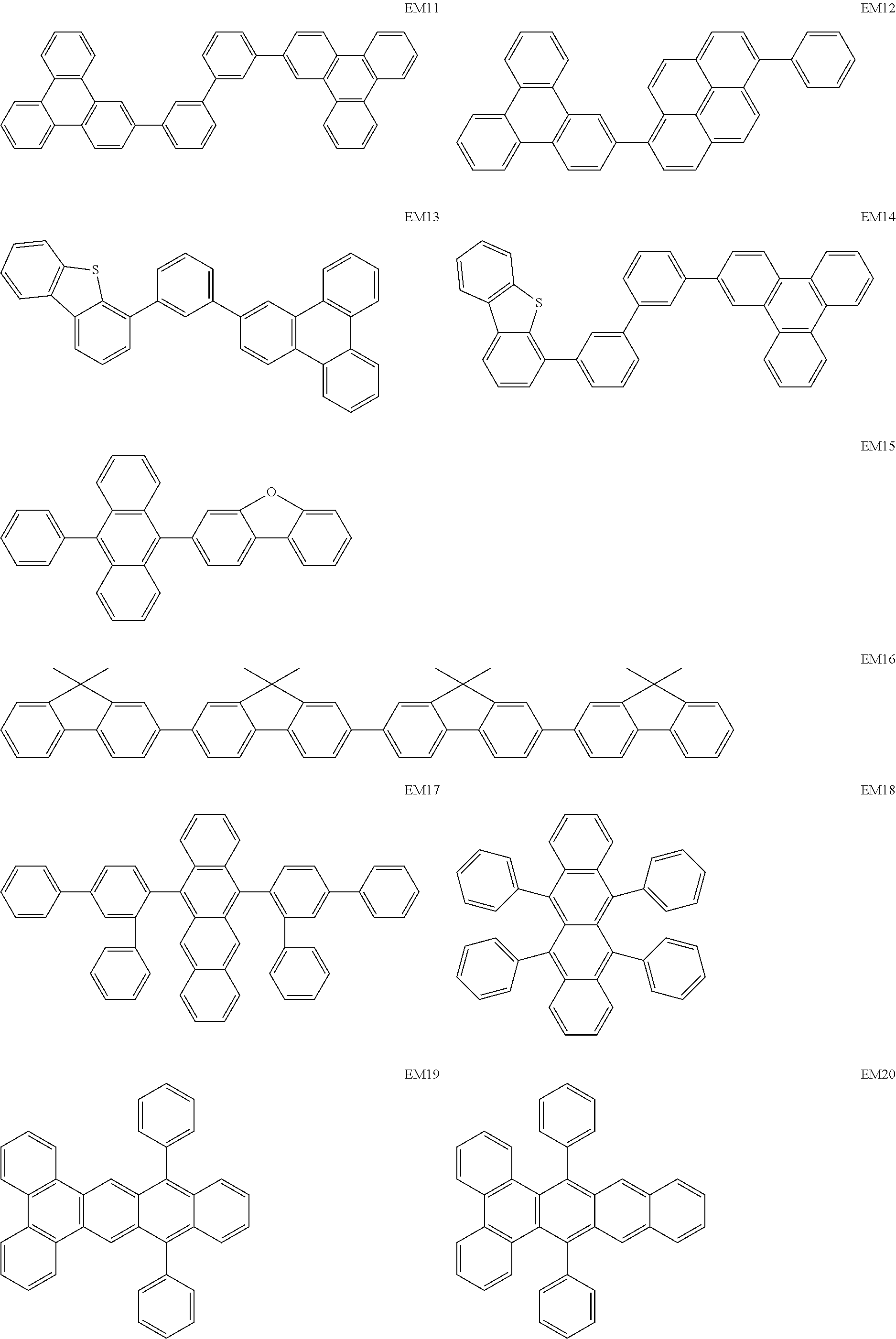

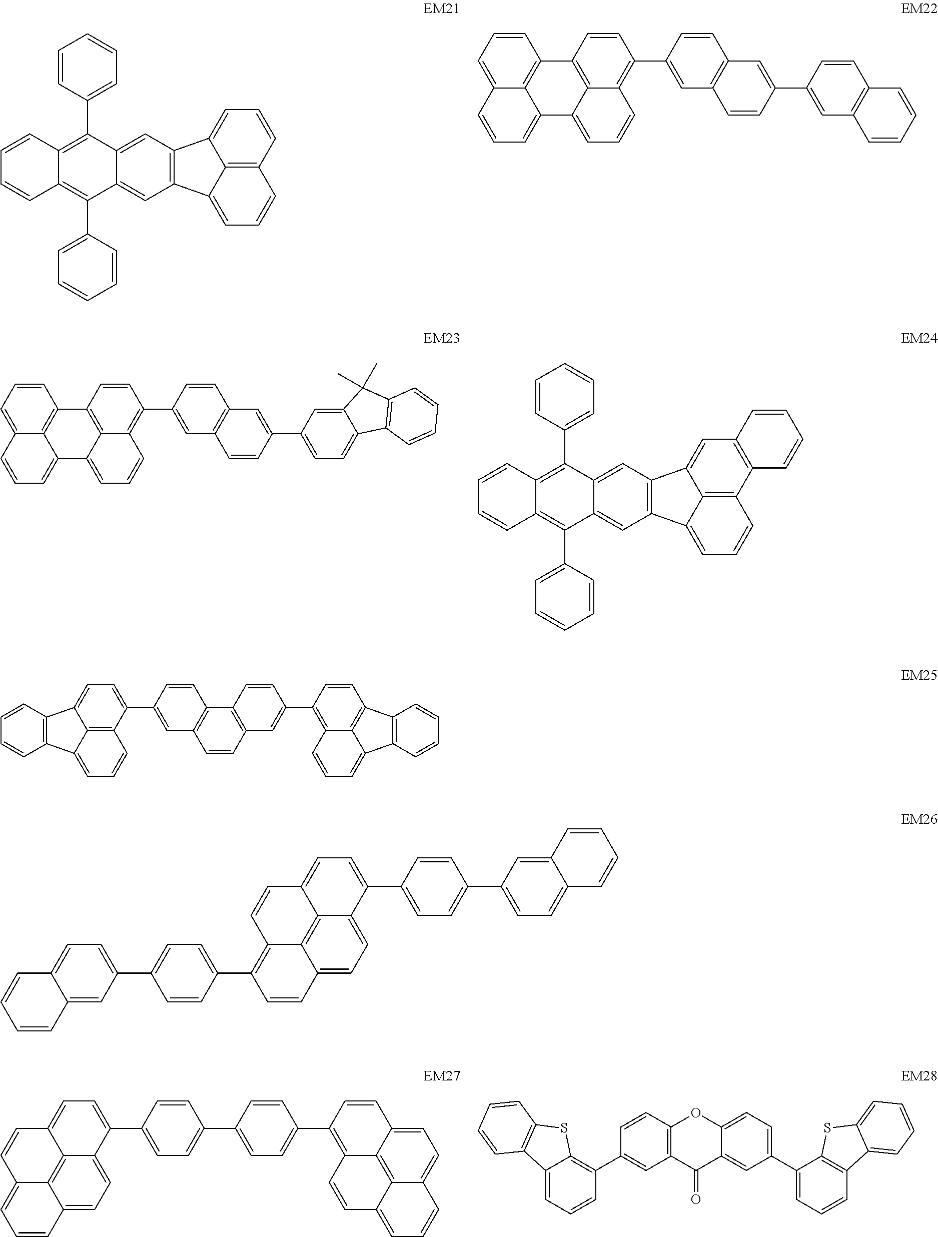

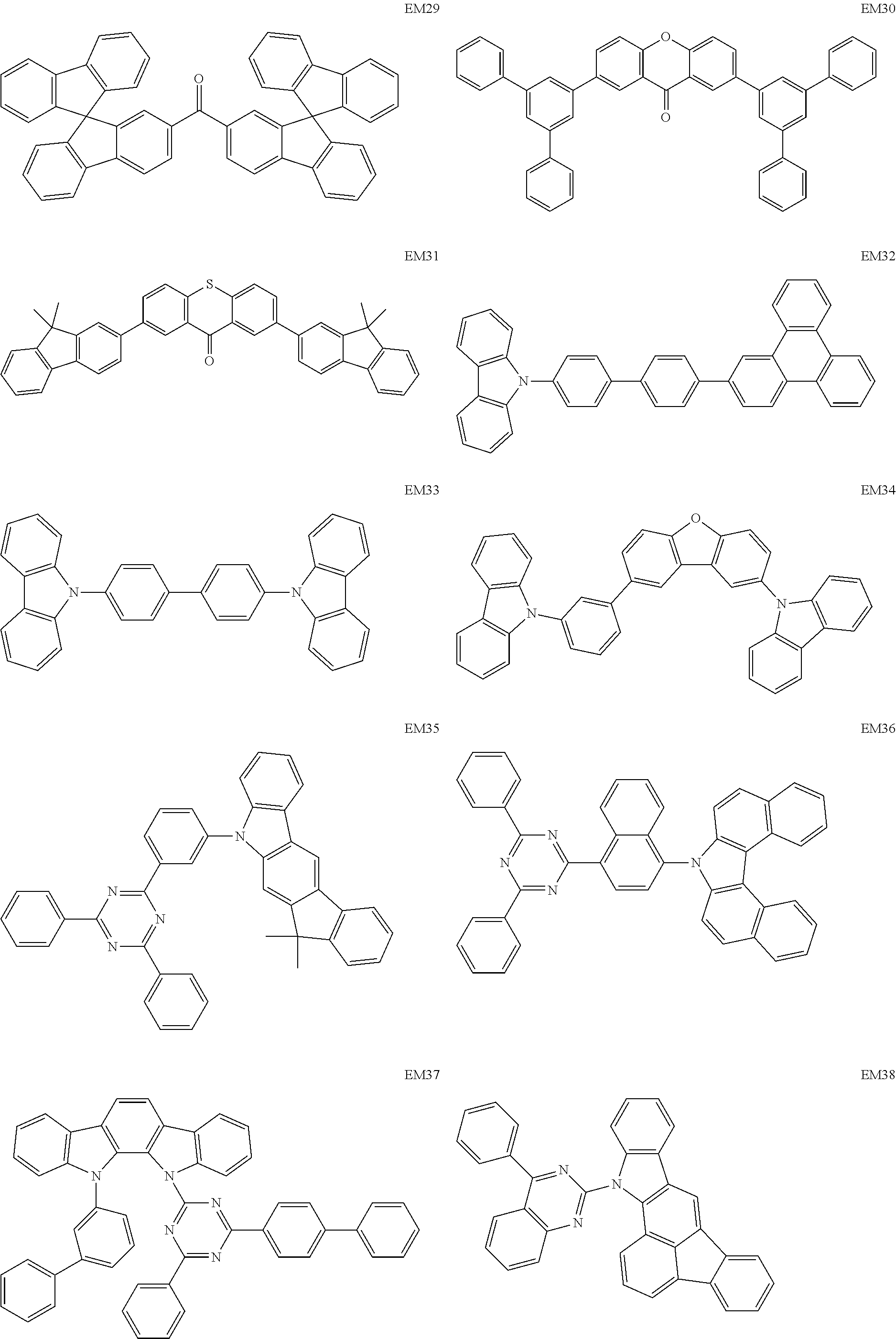

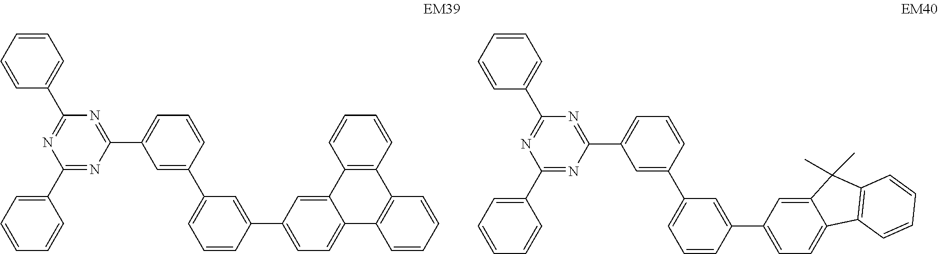

In a case where the host material is a hydrocarbon compound, since the organic compound according to the present embodiment is likely to trap electrons and positive holes, the effect of increasing the efficiency is high, which is preferable. The hydrocarbon compound is a compound formed of only carbon and hydrogen, and corresponds to EM1 to EM26 among the exemplary compounds shown above.

The electron transporting material can be arbitrarily selected from materials capable of transporting electrons injected from the cathode to the light emitting layer, and is selected in consideration of the balance or the like with the hole mobility of the hole transporting material. Examples of the material having an electron transporting ability include an oxadiazole derivative, an oxazole derivative, a pyrazine derivative, a triazole derivative, a triazine derivative, a quinoline derivative, a quinoxaline derivative, a phenanthroline derivative, an organic aluminum complex, and a fused ring compound (such as a fluorene derivative, a naphthalene derivative, a chrysene derivative, or an anthracene derivative). Further, the electron transporting material is also suitably used as the hole blocking layer. Specific examples of the compound used as the electron transporting material are shown below, but the present disclosure is not limited thereto.

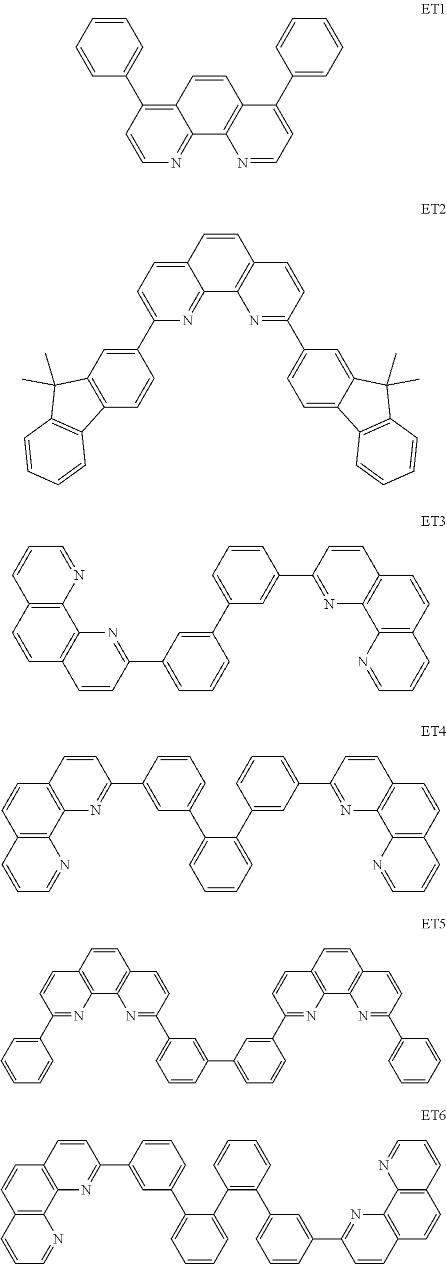

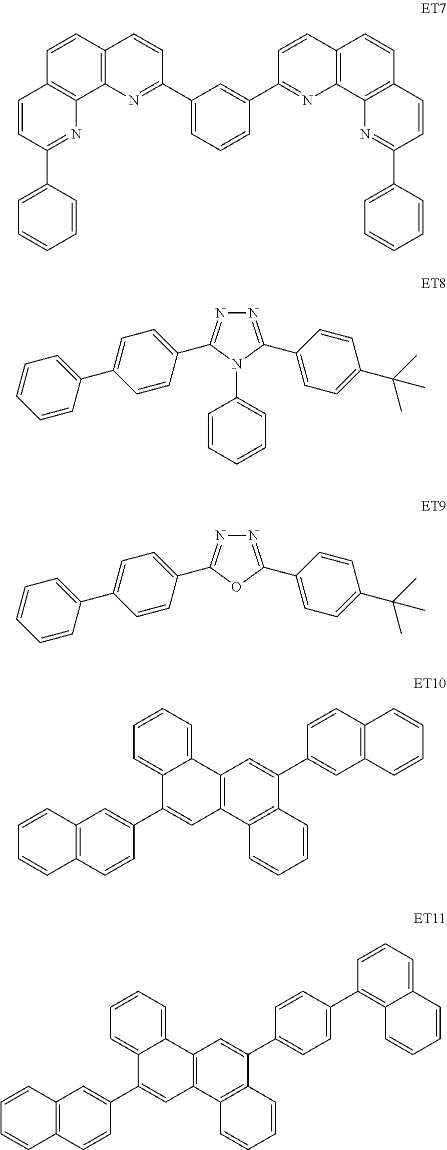

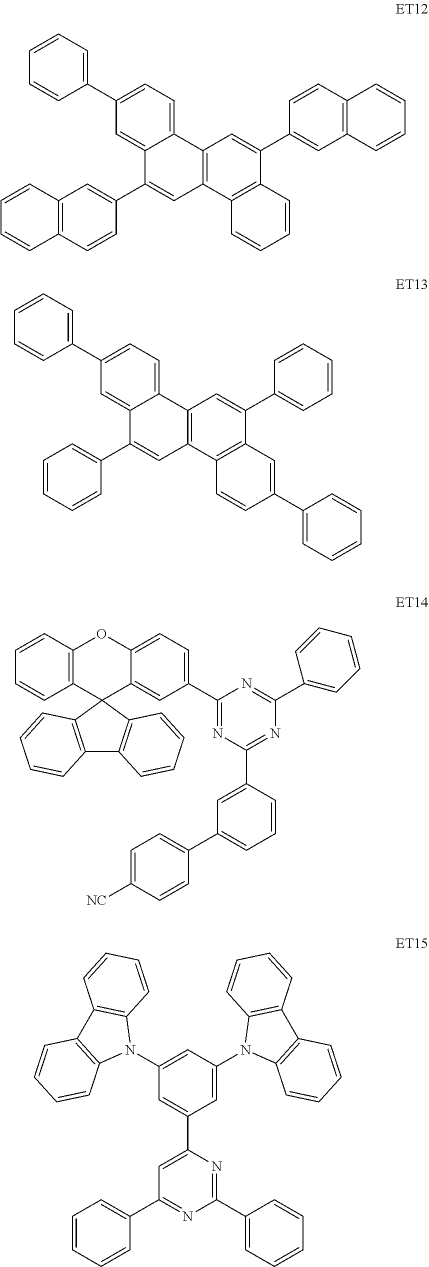

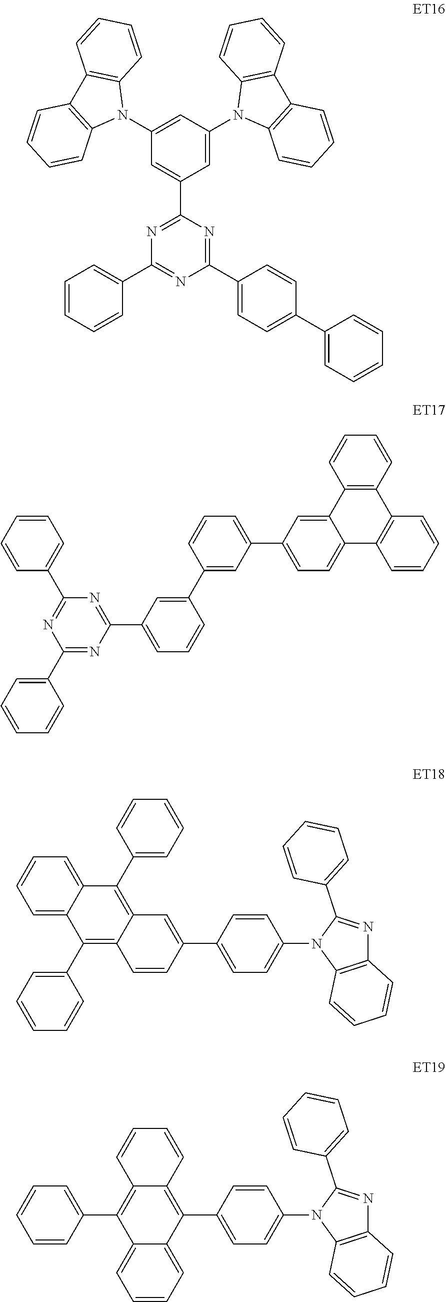 [SMILES: c1ccc(-c2ccc(-c3nc(-c4ccccc4)nc(-c4cc(-n5c6ccccc6c6ccccc65)cc(-n5c6ccccc6c6ccccc65)c4)n3)cc2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2c3ccccc3c(-c3ccccc3)c3cc(-c4ccc(-n5c(-c6ccccc6)nc6ccccc65)cc4)ccc23)cc1 ; c1ccc(-c2c3ccccc3c(-c3ccc(-n4c(-c5ccccc5)nc5ccccc54)cc3)c3ccccc23)cc1]

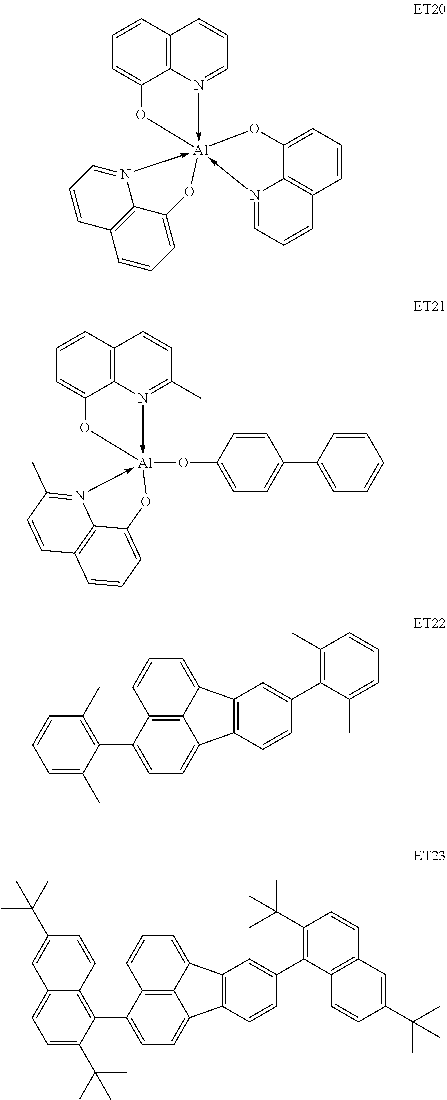

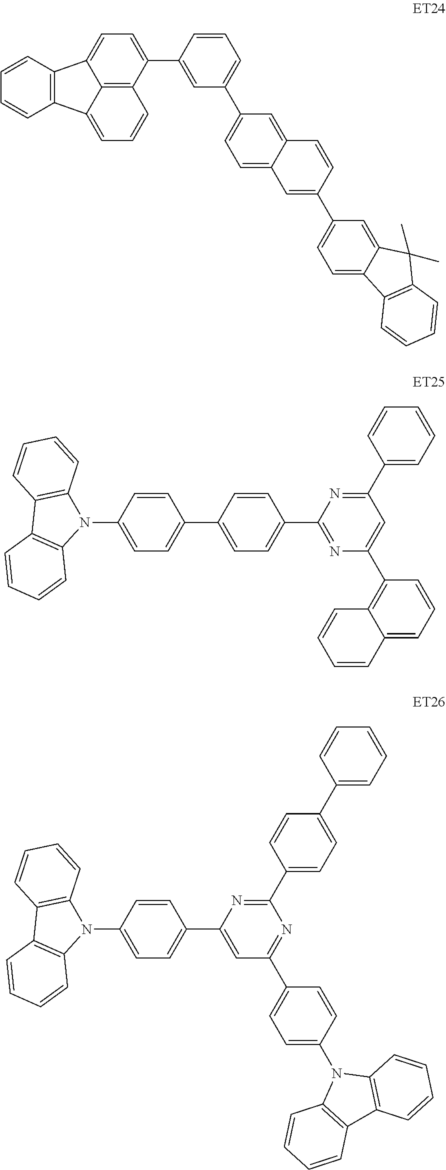

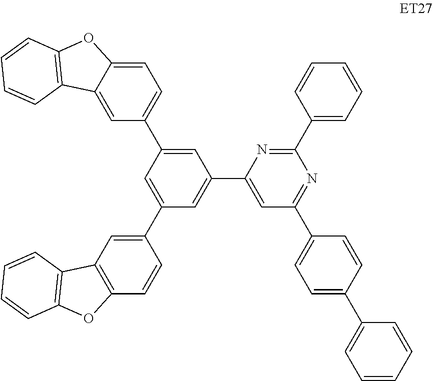 [SMILES: c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

The electron transporting material can be arbitrarily selected from materials capable of easily injecting electrons from the cathode, and is selected in consideration of the balance or the like with the positive hole injection property. The electron injecting material also include an n-type dopant and a reducing dopant as organic compounds. Examples thereof include a compound containing an alkali metal such as lithium fluoride, a lithium complex such as lithium quinolinol, a benzoimidazolidene derivative, an imidazolidine derivative, a fulvalene derivative, and an acridine derivative. Further, the electron injecting material can also be used in combination with the above-described electron transporting materials.

### <Configuration of Organic Light Emitting Element>

The organic light emitting element is provided by forming an insulating layer, a first electrode, an organic compound layer, and a second electrode on a substrate. A protective layer, a color filter, a microlens, or the like may be provided on the second electrode. When a color filter is provided, a flattening layer may be provided between the color filter and the protective layer. The flattening layer can be formed of an acrylic resin or the like. The same applies to a case where the flattening layer is provided between the color filter and the microlens.

### [Substrate]

Examples of the substrate include quartz, glass, a silicon wafer, a resin, and a metal. Further, a switching element such as a transistor or a wiring is provided on the substrate, and an insulating layer may also be provided thereon. The insulating layer may be formed of any material as long as a contact hole can be formed such that a wiring can be formed between the insulating layer and the first electrode and insulation with an unconnected wiring can be ensured. For example, a resin such as polyimide, silicon oxide, silicon nitride, or the like can be used as the material of the insulating layer.

### [Electrode]

A pair of electrodes can be used as the electrodes. The pair of electrodes may be an anode and a cathode. When an electric field is applied in a direction in which the organic light emitting element emits light, the electrode with a higher potential is an anode and the other electrode is a cathode. Further, it can also be said that the electrode supplying holes to the light emitting layer is an anode and the electrode supplying electrons to the light emitting layer is a cathode.

A material having a work function as large as possible is suitable as the constituent material for the anode. Examples of such a material include a single metal such as gold, platinum, silver, copper, nickel, palladium, cobalt, selenium, vanadium, or tungsten, a mixture containing these metals, an alloy obtained by combining these metals, and a metal oxide such as tin oxide, zinc oxide, indium oxide, indium tin oxide (ITO), or indium zinc oxide. Further, a conductive polymer such as polyaniline, polypyrrole, or polythiophene can also be used.

These electrode materials may be used alone or in combination of two or more kinds thereof. Further, the anode may be formed of a single layer or a plurality of layers.

For example, a material obtained by laminating chromium, aluminum, silver, titanium, tungsten, molybdenum, or an ally thereof can be used when the material is used as a reflective electrode. The above-described material can function as a reflective film without having a role of an electrode. Further, a transport conductive layer formed of an oxide such as indium tin oxide (ITO) or indium zinc oxide can be used when the material is used as a transparent electrode, but the present disclosure is not limited thereto. The electrode can be formed by using a photolithography technique.

Meanwhile, a material having a small work function is preferable as the constituent material for the cathode. Examples thereof include an alkali metal such as lithium, an alkaline earth metal such as calcium, a single metal such as aluminum, titanium, manganese, silver, lead, or chromium, and a mixture thereof. Alternatively, an alloy obtained by combining these single metals can also be used. For example, magnesium-silver, aluminum-lithium, aluminum-magnesium, silver-copper, zinc-silver, or the like can be used. A metal oxide such as indium tin oxide (ITO) can also be used. These electrode materials may be used alone or in combination of two or more kinds thereof. Further, the cathode may be formed of a single layer or a plurality of layers. Among the examples, it is preferable to use silver and more preferable to use a silver alloy from the viewpoint of reducing aggregation of silver. The alloy ratio is not limited as long as the aggregation of silver can be reduced. For example, the alloy ratio of silver to other metals may be 1:1, 3:1, or the like.

The cathode may be used as a top emission element by using an oxide conductive layer such as ITO or a bottom emission element by using a reflective electrode such as aluminum (Al), and the use thereof is not particularly limited. A method of forming the cathode is not particularly limited, but it is preferable to use a direct current sputtering method or an alternating current sputtering method from the viewpoint that the film coverage is satisfactory and the resistance is easily lowered.

### [Organic Compound Layer]

The organic compound layer may be formed of a single layer or a plurality of layers. In a case where the organic compound layer is formed of a plurality of layers, the layers may be referred to as a hole injection layer, a hole transport layer, an electron blocking layer, a light emitting layer, a hole blocking layer, an electron transport layer, and an electron injection layer depending on the functions thereof. The organic compound layer is formed of an organic compound, but may contain inorganic atoms and inorganic compounds. For example, the organic compound layer may contain copper, lithium, magnesium, aluminum, iridium, platinum, molybdenum, zinc, or the like. The organic compound layer may be disposed between the first electrode and the second electrode or may be disposed in contact with the first electrode and the second electrode.

The organic compound layer (such as a positive hole injection layer, a positive hole transport layer, an electron blocking layer, a light emitting layer, a positive hole blocking layer, an electron transport layer, or an electron injection layer) constituting the organic light emitting element according to an embodiment of the present disclosure is formed by the following method.

The organic compound layer constituting the organic light emitting element according to an embodiment of the present disclosure can be formed by a dry process such as a vacuum deposition method, an ionization deposition method, a sputtering method, or a plasma method. Further, a wet process of dissolving the material in an appropriate solvent to form a layer by a known coating method (such as a spin coating method, a dipping method, a cast method, an LB method, or an ink jet method) can also be used in place of the dry process.

Here, when a layer is formed by a vacuum deposition method or a solution coating method, crystallization or the like is unlikely to occur and temporal stability is excellent. Further, a film can also be formed by combining the material with an appropriate binder resin when the film formation is performed by a coating method.

Examples of the binder resin include a polyvinyl carbazole resin, a polycarbonate resin, a polyester resin, an ABS resin, an acrylic resin, a polyimide resin, a phenol resin, an epoxy resin, a silicon resin, and a urea resin, but the present disclosure is not limited thereto.

Further, these binder resins may be used alone or in the form of a mixture of two or more kinds thereof, as a homopolymer or a copolymer. Further, the binder resins may be used in combination with known additives such as a plasticizer, an antioxidant, and an ultraviolet absorbing agent as necessary.

### [Protective Layer]

A protective layer may be provided on the second electrode. For example, infiltration of water or the like to the organic compound layer can be reduced by making glass provided with a moisture absorbent adhere onto the second electrode, and thus occurrence of display failure can be reduced. Further, as another embodiment, a passivation film formed of silicon nitride or the like is provided on the second electrode so that the infiltration of water or the like to the organic compound layer may be reduced. For example, the second electrode is formed and transported to another chamber without breaking the vacuum, and a silicon nitride film having a thickness of 2 μm is formed by a CVD method and then used as a protective layer. A protective layer may be provided by an atomic layer deposition method (ALD method) after film formation using the CVD method. The material of the film obtained by the ALD method is not limited, and examples thereof include silicon nitride, silicon oxide, and aluminum oxide. Silicon nitride may be further formed by the CVD method on the film formed by the ALD method. The film formed by the ALD method may be a film thickness less than the film thickness of the film formed by the CVD method. Specifically, the film thickness of the film formed by the ALD method may be 50% or less or 10% or less of the film thickness of the film formed by the CVD method.

### [Color Filter]

A color filter may be provided on the protective layer. For example, a color filter prepared in consideration of the size of the organic light emitting element is provided on another substrate and this substrate and the substrate provided with the organic light emitting element may be bonded to each other, or a color filter may be patterned on the protective layer described above using a photolithography technique. The color filter may be formed of high molecules.

### [Flattening Layer]

A flattening layer may be provided between the color filter and the protective layer. The flattening layer is provided for the purpose of reducing the unevenness of the underlying layer. The flattening layer is also referred to as a material resin layer in some cases without limiting the purpose thereof. The flattening layer may be formed of an organic compound, low molecules, or high molecules, but it is preferable that the flattening layer be formed of high molecules.

The flattening layer may be provided above and below the color filter, and the constituent materials may be the same as or different from each other. Specific examples of the constituent materials include a polyvinyl carbazole resin, a polycarbonate resin, a polyester resin, an ABS resin, an acrylic resin, a polyimide resin, a phenol resin, an epoxy resin, a silicon resin, and a urea resin.

### [Microlens]

The organic light emitting element or the organic light emitting device may include an optical member such as a microlens on a light emission side thereof. The microlens can be formed of an acrylic resin, an epoxy resin, or the like. The purpose of the microlens may be to increase the amount of light extracted from the organic light emitting element or the organic light emitting device and to control the direction of light to be extracted. The microlens may have a hemispherical shape. When the microlens has a hemispherical shape, a tangent line in parallel with an insulating layer is present among tangent lines in contact with the hemisphere, and the contact point between the tangent line and the hemisphere is the apex of the microlens. The apex of the microlens can be similarly determined in any cross-sectional view. That is, a tangent line in parallel with an insulating layer is present among tangent lines in contact with the semicircle of the microlens in a cross-sectional view, and the contact point between the tangent line and the semicircle is the apex of the microlens.

Further, a midpoint of the microlens can also be defined. In a cross section of the microlens, a line segment from a point where the shape of a circular arc ends to a point where the shape of another circular arc ends is assumed, and the midpoint of the line segment can be referred to as the midpoint of the microlens. The cross section that determines the apex and the midpoint may be a cross section perpendicular to the insulating layer.

### [Counter Substrate]

A counter substrate may be provided on the flattening layer. The counter substrate is provided at a position corresponding to the substrate described above, and thus is referred to as a counter substrate. The constituent material for the counter substrate may be the same as the constituent material of the substrate described above. The counter substrate may be a second substrate when the above-described substrate is defined as a first substrate.

### [Pixel Circuit]

The organic light emitting device including the organic light emitting element may include a pixel circuit connected to the organic light emitting element. The pixel circuit may be of an active matrix type to control light emission of each of the first light emitting element and the second light emitting element independently. The active matrix type circuit may be of a voltage programming type or a current programming type. The driving circuit has a pixel circuit for each pixel. The pixel circuit may have a light emitting element, a transistor that controls light emission brightness of the light emitting element, a transistor that controls the emission timing, a capacity that maintains the gate voltage of the transistor controlling the light emission brightness, and a transistor for connection to GND without using the light emitting element.

The light emitting device has a display region and a peripheral region disposed around the display region. The display region includes a pixel circuit, and the peripheral region includes a display control circuit. The mobility of the transistor constituting the pixel circuit may be less than the mobility of the transistor constituting the display control circuit. The inclination of the current voltage characteristic of the transistor constituting the pixel circuit may be smaller than the inclination of the current voltage characteristic of the transistor constituting the display control circuit. The inclination of the current voltage characteristic can be measured by a so-called Vg-Ig characteristic. The transistor constituting the pixel circuit is a transistor connected to a light emitting element such as a first light emitting element.

### [Pixel]

The organic light emitting device including the organic light emitting element may have a plurality of pixels. The pixels have subpixels emitting light of different colors. The subpixels may each have emission colors of red, green, and blue.

The pixel has a region emitting light, which is also referred to as a pixel aperture. The region is the same as a first region. The pixel aperture may be 5 μm or greater and 15 μm or less. More specifically, the pixel aperture may be 11 μm, 9.5 μm, 7.4 μm, 6.4 μm, or the like. The pixel aperture between subpixels may be 10 μm or less, and specifically, 8 μm, 7.4 μm, or 6.4 μm.

The pixel can employ a known arrangement form in plan view. Examples of the arrangement form include stripe arrangement, delta arrangement, pentile arrangement, and Bayer arrangement. The subpixel may employ any of known shapes in plan view. Examples thereof include a quadrangular shape such as a rectangular shape or a rhombus shape, and a hexagonal shape. Further, the rectangular shape includes a shape that is close to a rectangle without being required to have an exact figure. The shapes of subpixels and the pixel arrangements can be used in combination.

### <Applications of Organic Light Emitting Element>

The organic light emitting element according to the present embodiment can be used as a constituent member of a display device or a lighting device. Further, the organic light emitting element can also be used as an exposure light source of an electrophotographic image forming apparatus, a backlight of a liquid crystal display device, a light emitting device having a color filter in white light source, or the like.

The display device may be an image information processing device that includes an image input unit inputting image information from an area CCD, a linear CCD, a memory card, or the like and an information processing unit processing the input information and displays the input image on a display unit. The display device has a plurality of pixels, and at least one of the plurality of pixels may include the organic light emitting element according to the present embodiment and a transistor connected to the organic light emitting element.

Further, a display unit of an imaging device or an ink jet printer may have a touch panel function. The driving type of this touch panel function is not particularly limited, and may be an infrared type, a capacitance type, a resistive film type, or an electromagnetic induction type. Further, the display device may be used as a display unit of a multi-function printer.

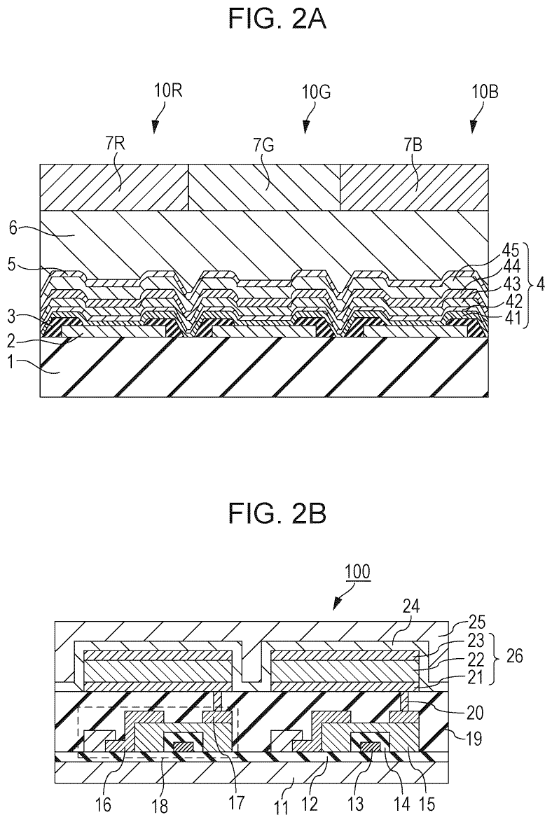

Next, the display device according to the present embodiment will be described with reference to the accompanying drawings. FIGS. 2A and 2B are schematic cross-sectional views showing an example of a display device that includes an organic light emitting element and a transistor connected to the organic light emitting element. The transistor is an example of an active element. The transistor may be a thin film transistor (TFT).

FIG. 2A shows an example of a pixel as a constituent element of the display device according to the present embodiment. The pixel includes subpixels 10. The subpixels are divided into 10R, 10G, and 10B depending on the light emission thereof. The emission color of may be distinguished by the wavelength of light emitted from the light emitting layer, and light emitted from the subpixels may be selectively transmitted or may undergo color conversion through a color filter or the like. Each of the subpixels 10 includes a reflective electrode serving as a first electrode 2 on an interlayer insulating layer 1, an insulating layer 3 covering an end of the first electrode 2, an organic compound layer 4 covering the first electrode 2 and the insulating layer 3, a transparent electrode serving as a second electrode 5, a protective layer 6, and a color filter 7.

The interlayer insulating layer 1 has a transistor and a capacitive element below or inside the layer. The transistor and the first electrode 2 may be electrically connected to each other via a contact hole (not shown).

The insulating layer 3 is also referred to as a bank or a pixel separation film. The insulating layer 3 covers an end of the first electrode 2 and is disposed to surround the first electrode 2. A portion where the insulating layer 3 is not provided is a light emitting region that is in contact with the organic compound layer 4.

The organic compound layer 4 includes a positive hole injection layer 41, a positive hole transport layer 42, a first light emitting layer 43, a second light emitting layer 44, and an electron transport layer 45.

The second electrode 5 may be a transparent electrode or a reflective electrode or may be a semi-transparent electrode.

The protective layer 6 reduces infiltration of moisture to the organic compound layer 4. The protective layer 6 is shown to be formed of a single layer, but may be formed of a plurality of layers. Each layer may be formed of an inorganic compound layer and an organic compound layer.

The color filter 7 is divided into 7R, 7G, and 7B depending on the color thereof. The color filter 7 may be formed on a flattening film (not shown). Further, a resin protective layer (not shown) may be provided on the color filter 7. Further, the color filter 7 may be formed on the protective layer 6. Alternatively, the color filter 7 may be provided on a counter substrate such as a glass substrate to be bonded thereto.

A display device 100 of FIG. 2B includes an organic light emitting element 26 and a TFT 18 as an example of a transistor. The display device 100 also includes a substrate 11 such as glass or silicon and an insulating layer 12 on the substrate 11. An active element such as the TFT 18 is disposed on the insulating layer 12, and a gate electrode 13 of the active element, a gate insulating film 14, and a semiconductor layer 15 are disposed on the insulating layer 12. The TFT 18 is also formed of a drain electrode 16 and a source electrode 17. An insulating film 19 is provided on the TFT 18. An anode 21 constituting the organic light emitting element 26 and the source electrode 17 are connected to each other via a contact hole 20 provided on the insulating film 19.

In addition, the electrical connection type between electrodes (the anode 21 and a cathode 23) of the organic light emitting element 26 and electrodes (the source electrode 17 and the drain electrode 16) of the TFT 18 is not limited to the aspect shown in FIG. 2B. That is, any one of the anode 21 or the cathode 23 and any one of the source electrode 17 and the drain electrode 16 of the TFT 18 may be electrically connected. The TFT denotes a thin film transistor.

In the display device 100 of FIG. 2B, the organic compound layer 22 is shown to be formed of one layer, but the organic compound layer 22 may be formed of a plurality of layers. A first protective layer 24 or a second protective layer 25 is provided on the cathode 23 in order to reduce deterioration of the organic light emitting element 26.

In the display device 100 of FIG. 2B, a transistor is used as a switching element, but a different element may also be used as a switching element.

Further, the transistor used in the display device 100 of FIG. 2B is not limited to a transistor obtained by using a single crystal silicon wafer, but may be a thin film transistor having an active layer on an insulating surface of a substrate. Examples of the active layer include single crystal silicon, non-single crystal silicon such as amorphous silicon or microcrystalline silicon, and a non-single crystal oxide semiconductor such as an indium zinc oxide or an indium gallium zinc oxide. Further, the thin film transistor is also referred to as a TFT element.

The transistor in the display device 100 of FIG. 2B may be formed in a substrate such as a Si substrate. Here, the expression “formed in a substrate” denotes that a transistor is prepared by processing the substrate such as a Si substrate. That is, the concept of the transistor being formed in a substrate can also denote that the substrate and the transistor are integrally formed.

The light emission brightness of the organic light emitting element according to the present embodiment is controlled by the TFT which is an example of a switching element, and in a case where a plurality of the organic light emitting elements are provided in a plane, an image can be displayed by the light emission brightness of each organic light emitting element. Further, the switching element according to the present embodiment is not limited to a TFT, and may be a transistor formed of low-temperature polysilicon or an active matrix driver formed on a substrate such as a Si substrate. The formation can be made not only on the substrate but also in the substrate. Whether the transistor is provided in the substrate or the TFT is used is selected depending on the size of the display unit, and it is preferable that the organic light emitting element be provided on a Si substrate when the size of the display unit is, for example, about 0.5 inches.

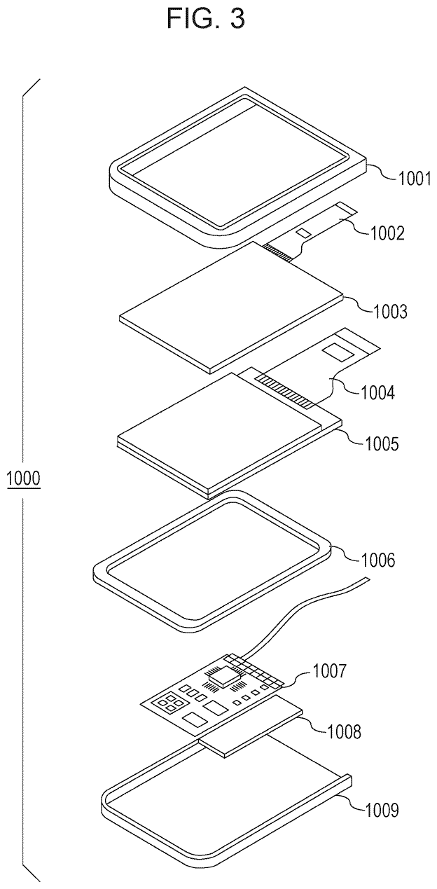

FIG. 3 is a schematic view showing an example of the display device according to the present embodiment. A display device 1000 may include a touch panel 1003, a display panel 1005, a frame 1006, a circuit board 1007, and a battery 1008 between an upper cover 1001 and a lower cover 1009. Flexible printed circuits FPC 1002 and 1004 are respectively connected to the touch panel 1003 and the display panel 1005. A transistor is printed on the circuit board 1007. The battery 1008 may not be provided unless the display device is a portable device, and may be provided at a different position even when the display device is a portable device.

The display device according to the present embodiment may include color filters having a red color, a green color, and a blue color. The color filter may be provided such that the red color, the green color, and the blue color are arranged in delta arrangement.

The display device according to the present embodiment may be used as a display unit of a portable terminal. In this case, the display device may have both a display function and an operation function. Examples of the portable terminal include a mobile phone such as a smartphone, a tablet, and a head-mounted display.

The display device according to the present embodiment may be used as a display unit of an imaging device including an optical unit that has a plurality of lenses and an imaging element that receives light having passed through the optical unit. The imaging device may include a display unit displaying information acquired by the imaging element. Further, the display unit may be a display unit exposed to the outside of the imaging device or a display unit disposed in a viewfinder. The imaging device may be a digital camera or a digital video camera.

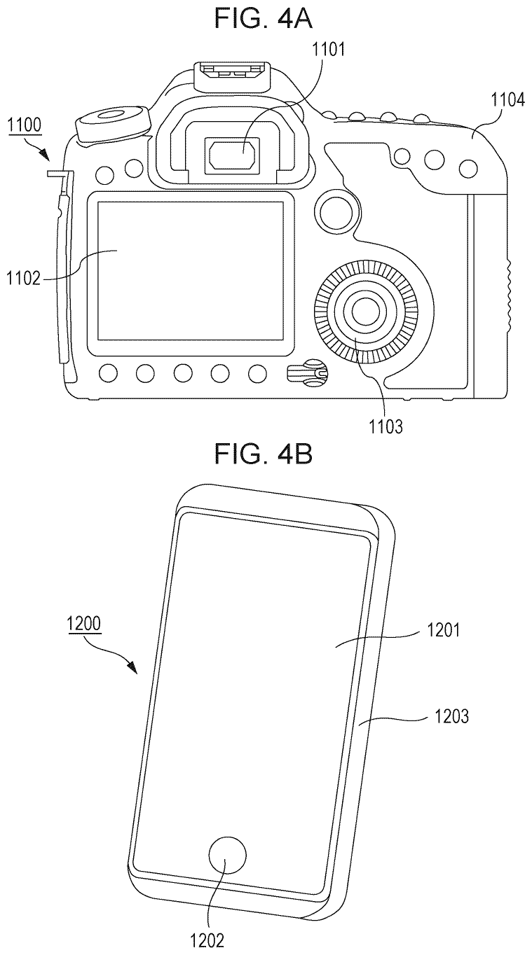

FIG. 4A is a schematic view showing an example of an imaging device according to the present embodiment. An imaging device 1100 may include a viewfinder 1101, a rear display 1102, an operation unit 1103, and a housing 1104. The viewfinder 1101 may include the display device according to the present embodiment. In this case, the display device may display not only an image to be imaged but also environmental information, imaging instructions, and the like. The environmental information may include the intensity of external light, the orientation of external light, the moving speed of a subject, and the possibility that a subject is shielded by a shielding material.

The suitable timing for imaging is only a short time, and thus information is required to be displayed as early as possible. Therefore, it is preferable that a display device formed of the organic light emitting element according to the present embodiment be used from the viewpoint that the organic light emitting element has a fast response speed. The display device formed of the organic light emitting element can be more suitably used than these devices and a liquid crystal display device required to have a high display speed.

The imaging device 1100 includes an optical unit (not shown). The optical unit includes a plurality of lenses and forms an image on an imaging element accommodated in the housing 1104. The focal point can be adjusted by adjusting the relative positions of the plurality of lenses. This operation can also be automatically performed. The imaging device may also be referred to as a photoelectric conversion device. The photoelectric conversion device is capable of capturing an image, without capturing images sequentially, by an imaging method such as a method of detecting a difference from a previous image or a method of cutting out an image from an image constantly recorded.

FIG. 4B is a schematic view showing an example of an electronic device according to the present embodiment. An electronic device 1200 includes a display unit 1201, an operation unit 1202, and a housing 1203. The housing 1203 may include a circuit, a printed circuit board including the circuit, a battery, and a communication unit. The operation unit 1202 may be in the form of a button or may be a touch panel type reaction unit. The operation unit 1202 may be a biometric authentication unit that identifies fingerprints, performs unlocking, and the like. The electronic device including a communication unit can also be used as a communication device. The electronic device 1200 may further have a camera function by including a lens and an imaging element. An image captured using a camera function is displayed on the display unit 1201. Examples of the electronic device 1200 include a smartphone and a notebook computer.

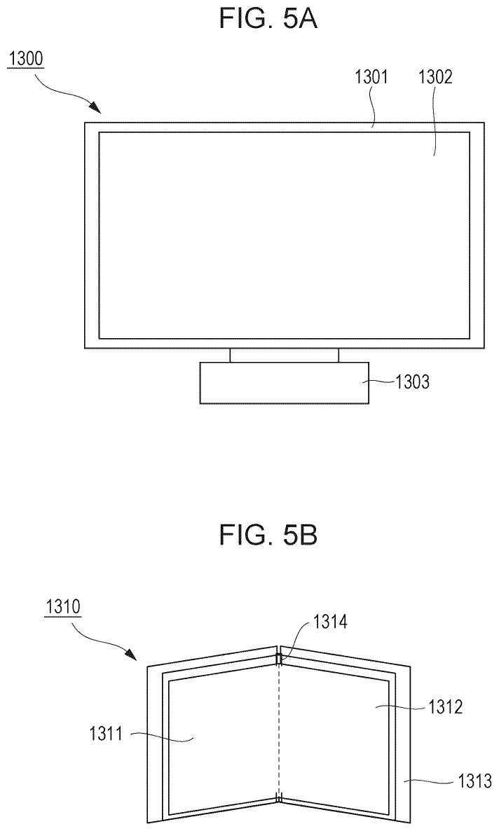

FIGS. 5A and 5B are schematic views showing examples of the display device according to the present embodiment. FIG. 5A shows a display device such as a television monitor or a PC monitor. A display device 1300 includes a frame 1301 and a display unit 1302. The display unit 1302 may be formed of the light emitting element according to the present embodiment. The display device includes a base 1303 that supports the frame 1301 and the display unit 1302. The base 1303 is not limited to the form shown in FIG. 5A. The lower side of the base 1301 may also serve as a base. Further, the frame 1301 and the display unit 1302 may be curved. The curvature radius thereof may be 5000 mm or greater and 6000 mm or less.

FIG. 5B is a schematic view showing another example of the display device according to the present embodiment. A display device 1310 of FIG. 5B is a so-called foldable display device that is formed to be foldable. The display device 1310 includes a first display unit 1311, a second display unit 1312, a housing 1313, and a bending point 1314. The first display unit 1311 and the second display unit 1312 may include the light emitting element according to the present embodiment. The first display unit 1311 and the second display unit 1312 may be one seamless display device. The first display unit 1311 and the second display unit 1312 can be divided at the bending point. The first display unit 1311 and the second display unit 1312 may each display different images or the first display unit and the second display unit may also display one image.

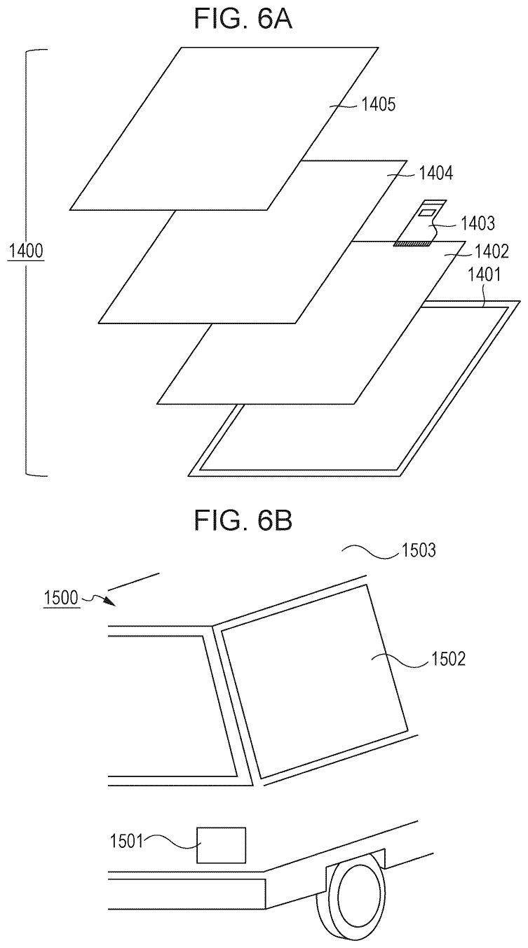

FIG. 6A is a schematic view showing an example of a lighting device according to the present embodiment. A lighting device 1400 may include a housing 1401, a light source 1402, a circuit board 1403, and an optical filter 1404 and a light diffusion unit 1405 that transmit light emitted by the light source 1402. The light source 1402 may include the organic light emitting element according to the present embodiment. The optical filter 1404 may be a filter that improves the color rendering properties of the light source. The light diffusion unit 1405 effectively diffuses light of the light source by performing lighting up or the like and thus can deliver the light to a wide range. The optical filter 1404 and the light diffusion unit 1405 may be provided on a light emission side of lighting. A cover may be provided on the outermost portion.

The lighting device is, for example, a device that lights up a room. The lighting device may emit light of white, neutral white, and any other colors from blue to red. The lighting device may include a light control circuit that controls light of these colors. The lighting device may include the organic light emitting element of the present embodiment and a power supply circuit connected to the organic light emitting element. The power supply circuit is a circuit that converts an alternating current voltage to a direct current voltage. Further, white has a color temperature of 4200K and neutral white has a color temperature of 5000K. The lighting device may include a color filter.

Further, the lighting device according to the present embodiment may include a heat radiation unit. The heat radiation unit releases heat inside the device to the outside of the device, and examples thereof include a metal with high specific heat and liquid silicon.

FIG. 6B is a schematic view showing an automobile as an example of a moving body according to the present embodiment. The automobile includes a tail lamp which is an example of a lamp. An automobile 1500 includes a tail lamp 1501 and may be in the form of turning on the tail lamp when a brake operation is performed.

The tail lamp 1501 may include the organic light emitting element according to the present embodiment. The tail lamp 1501 may include a protective member that protects the organic light emitting element. The protective member is not limited as long as the protective member has a certain high degree of strength and is transparent, but it is preferable that the protective member be formed of polycarbonate or the like. The polycarbonate may be mixed with a furandicarboxylic acid derivative, an acrylonitrile derivative, or the like.

The automobile 1500 may include a car body 1503 and a window 1502 attached to the car body 1503. The window 1502 may be a transparent display when the window is not used to confirm the front and rear of the automobile. The transparent display may include the organic light emitting element according to the present embodiment. In this case, the constituent material such as the electrode of the organic light emitting element is formed of a transparent member.

The moving body according to the present embodiment may be a ship, an aircraft, a drone, or the like. The moving body may include a machine body and a lamp provided on the machine body. The lamp may emit light to inform of the position of the machine body. The lamp includes the organic light emitting element according to the present embodiment.

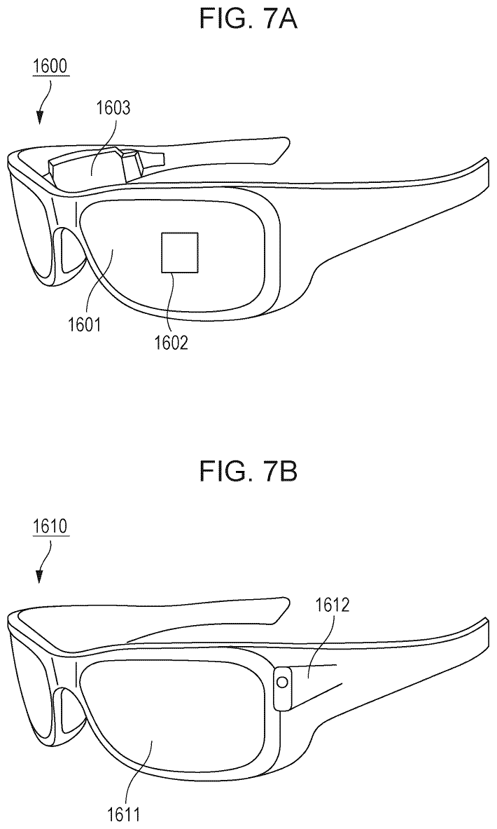

Application examples of the display device according to each of the above-described embodiments will be described with reference to FIGS. 7A and 7B. The display device can be applied to a system that can be mounted as a wearable device such as smart glasses, a HMD, or a smart contact. An imaging display device used in such application examples includes an imaging device capable of photoelectrically converting visible light and a display device capable of emitting visible light.

FIG. 7A is a schematic view showing an example of a wearable device according to an embodiment of the present disclosure. Glasses 1600 (smart glasses) according to one application example will be described with reference to FIG. 7A. An imaging device 1602 such as a CMOS sensor or a SPAD is provided on the front surface side of a lens 1601 of the glasses 1600. Further, the display device according to each embodiment described is provided on the rear surface side of the lens 1601.

The glasses 1600 further include a control device 1603. The control device 1603 functions as a power supply that supplies power to the imaging device 1602 to the display device. Further, the control device 1603 controls the operations of the imaging device 1602 and the display device. An optical system for condensing light on the imaging device 1602 is formed on the lens 1601.

FIG. 7B is a schematic view showing another example of a wearable device according to an embodiment of the present disclosure. Glasses 1610 (smart glasses) according to one application example will be described with reference to FIG. 7B. The glasses 1610 include a control device 1612, and the control device 1612 is equipped with an imaging device corresponding to the imaging device 1602 of FIG. 7A and a display device. A lens 1611 is formed with the imaging device in the control device 1612 and an optical system for projecting light emitted from the display device, and an image is projected on the lens 1611. The control device 1612 functions as a power supply that supplies power to the imaging device and the display device and controls the operations of the imaging device and the display device.

The control unit 1612 may include a visual line detection unit that detects the visual line of a wearer. The visual line may be detected by infrared rays. An infrared light emitting unit emits infrared light to the eyeballs of a user gazing a displayed image. A captured image of the eyeballs is obtained by detecting reflected light from the eyeballs to which infrared light has been emitted, using an imaging unit including a light receiving element. Degradation of the image quality is reduced by providing a reduction unit that reduces light from the infrared light emitting unit to the display unit in plan view. The visual line of a user with respect to the displayed image from the captured image of the eyeballs obtained by capturing infrared light is detected. The detection of the visual line using the captured image of the eyeballs can be performed by employing any known method. As an example, a method of detecting the visual line based on a Purkinje image using reflection of light radiated to the cornea can be used. More specifically, a visual line detection treatment is performed by a pupillary corneal reflection method. The visual line of the user is detected by calculating a visual line vector representing the orientation (rotation angle) of the eyeballs based on the pupil image and the Purkinje image included in the captured image of the eyeballs.

The display device according to an embodiment of the present disclosure includes an imaging device having a light receiving element and may control a displayed image of the display device based on visual line information of the user from the imaging device. Specifically, the display device determines a first visual field region at which the user gazes and a second visual field region other than the first visual field region. The first visual field region and the second visual field region may be determined by the control device of the display device, or an external control device determines any of the regions and the result may be received. In a display region of the display device, the display resolution of the first visual field region may be controlled to be higher than the display resolution of the second visual field region. That is, the resolution of the second visual field region may be set to be less than the resolution of the first visual field region.

Further, the display region has the first display region and the second display region different from the first display region, and a region with high priority is determined from the first display region and the second display region based on visual line information. The first display region and the second display region may be determined by the control device of the display device, or an external control device determines any of the regions and the result may be received. The resolution of the region with a high priority may be controlled to be higher than the resolution of the region other than the region with a high priority. That is, the resolution of the region with a relatively lower priority may be decreased.

Further, the first visual field region and the region with a higher priority may be determined by using AI. The AI may be a model formed to estimate the angle of the visual line from the image of the eyeballs and the distance from the eyeballs of the image to the object in front of the visual line, using the image of the eyeballs and the direction in which the eyeballs of the image are actually gazing as teaching data. The display device, the imaging device, or an external device may have an AI program. When an external device has the AI program, the AI program is transmitted to the display device through communication.

When display is controlled based on visual line detection, an imaging device that captures an image of the outside can be preferably applied to smart glasses. The smart glasses can display captured external information in real time.

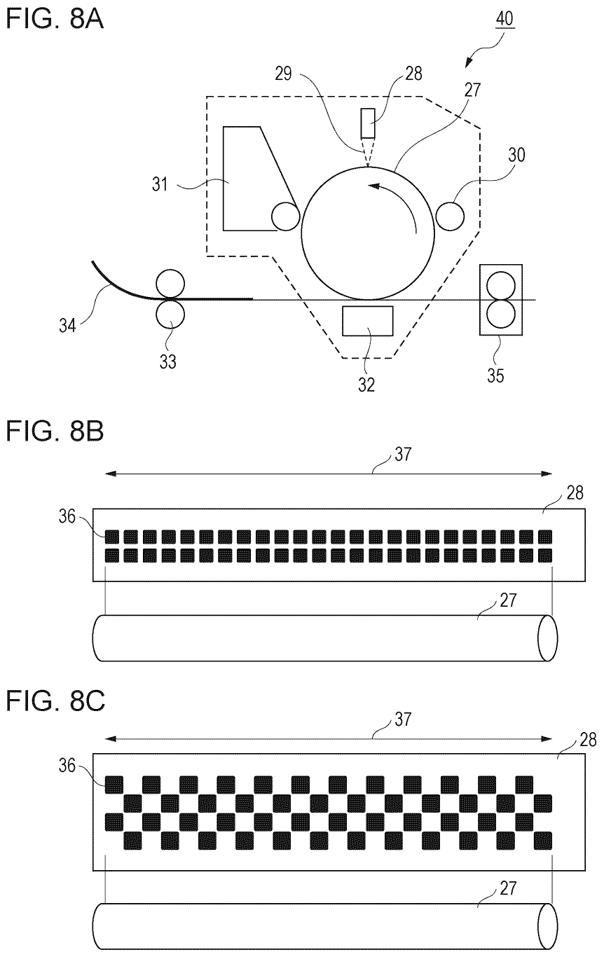

FIG. 8A is a schematic view showing an example of an image forming apparatus according to an embodiment of the present disclosure. An image forming apparatus 40 is an electrophotographic image forming apparatus and includes a photoreceptor 27, an exposure light source 28, a charging unit 30, a developing unit 31, a transfer device 32, a transport roller 33, and a fixing device 35. Light 29 is radiated from the exposure light source 28 to form an electrostatic latent image on a surface of the photoreceptor 27. The exposure light source 28 includes the organic light emitting element according to the present embodiment. The developing unit 31 includes a toner and the like. The charging unit 30 charges the photoreceptor 27. The transfer device 32 transfers the developed image to a recording medium 34. The transport roller 33 transports the recording medium 34. The recording medium 34 is, for example, paper. The fixing device 35 fixes the image formed on the recording medium 34.

FIGS. 8B and 8C show the exposure light source 28 and schematically show an aspect in which a plurality of the light emitting units 36 are arranged on a long substrate. An arrow 37 indicates a direction parallel to an axis of the photoreceptor and represents a column direction in which organic light emitting elements are aligned. The column direction is the same direction as the direction of an axis around which the photoreceptor 27 rotates. The direction can also be referred to as a major axis direction of the photoreceptor 27. FIG. 8B shows a form in which the light emitting units 36 are arranged in the major axis direction of the photoreceptor 27. FIG. 8C shows a form which is different from the form of FIG. 8B and in which the light emitting units 36 in each of the first column and the second column are alternately arranged in the column direction. The light emitting units 36 in the first column and the second column are arranged at different positions in the row direction. A plurality of the light emitting units 36 in the first column are arranged at intervals. In the second column, the light emitting units 36 are arranged at positions corresponding to the intervals of the light emitting units 36 in the first column. That is, a plurality of the light emitting units 36 are arranged at intervals even in the row direction. The arrangement of FIG. 8C can also be expressed as, for example, a grid-like arrangement state, a zigzag arrangement state, or a checkered pattern.

As described above, an image with a satisfactory image quality can be stably displayed for a long time by using a device formed of the organic light emitting element according to the present embodiment.

### EXAMPLES

Hereinafter, the present disclosure will be described based on examples. However, the present disclosure is not limited thereto.

### Example 1 (Synthesis of Exemplary Compound F-1)

An exemplary compound F-1 was synthesized according to the following scheme.

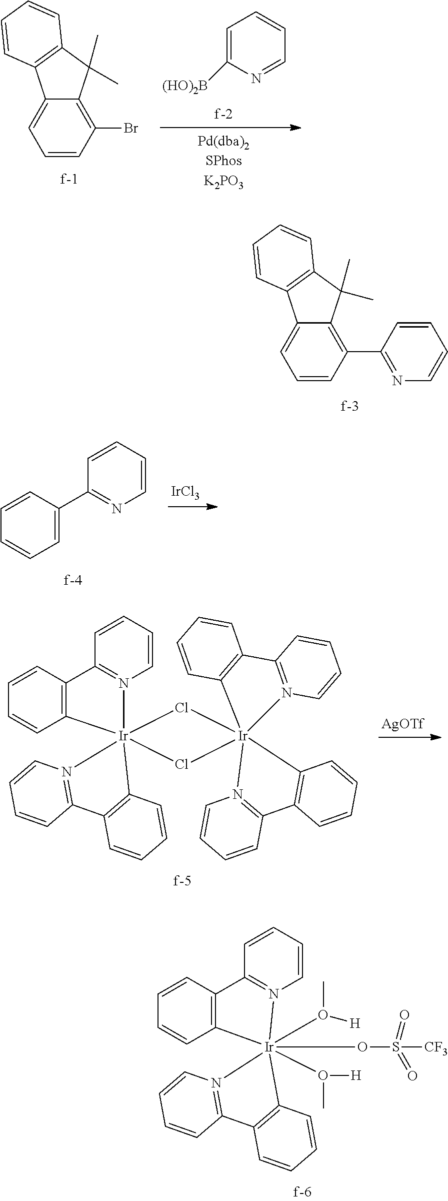

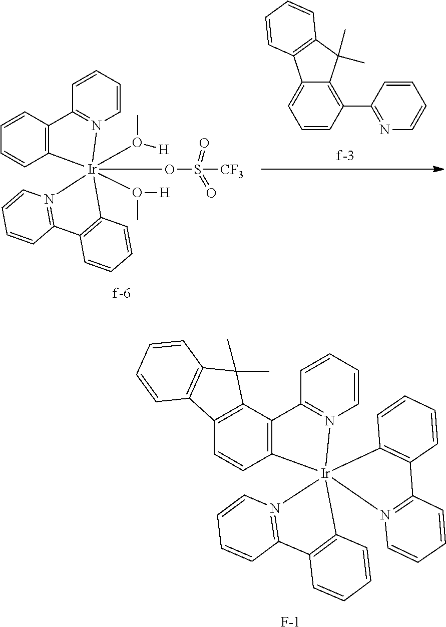

### (1) Synthesis of Compound f-3

A 200 ml eggplant flask was charged with reagents and solvents described below.
Compound f-1: 6.08 g (20.0 mmol)
Compound f-2: 2.27 g (20.0 mmol)
Sodium carbonate: 5.3 g (50.0 mmol)
Pd(PPh₃)₄: 578 mg
Toluene: 35 ml
Water: 35 ml
Ethanol: 10 ml

Next, the reaction solution was heated and stirred at 60° C. for 5 hours in a nitrogen gas stream. After completion of the reaction, the solution was subjected to extraction with toluene, and the organic layer was concentrated, dried, and solidified. The obtained solid was purified by silica gel column chromatography (toluene and ethyl acetate were mixed), thereby obtaining 3.0 g of a transparent solid (f-3) (yield: 58%).

### (2) Synthesis of Compound f-5

A 50 ml eggplant flask was charged with reagents and solvents described below.
Compound f-4: 3.10 g (20.0 mmol)
Iridium chloride hydrate: 1.60 g
Ethoxyethanol: 18 ml
Water: 6 ml

Next, the reaction solution was heated and stirred at 130° C. for 5 hours in a nitrogen gas stream. After completion of the reaction, the reaction solution was filtered, and the obtained solid was washed with water and methanol on a filter, thereby obtaining 3.4 g of a yellow solid (f-5) (yield: 63%).

### (3) Synthesis of Compound f-6

A 100 ml eggplant flask was charged with reagents and solvents described below.
Compound f-5: 1.07 g (1.00 mmol)
Silver triflate: 0.514 g (2.00 mmol)
Methylene chloride: 30 ml
Methanol: 1.3 ml

Next, the reaction solution was heated and stirred at room temperature for 7 hours in a nitrogen gas stream. After completion of the reaction, the solvent of the reaction solution was distilled off at 40° C., thereby obtaining 1.56 g of a yellowish brown solid (f-6).

### (4) Synthesis of Compound F-1

A 100 ml eggplant flask was charged with reagents and a solvent described below.
Compound f-6: 1.50 g
Compound f-3: 2.55 g (1.00 mmol)
Ethanol: 50 ml

Next, the reaction solution was heated and stirred at 90° C. for 5 hours in a nitrogen gas stream. After completion of the reaction, the reaction solution was filtered, and the obtained solid was washed with water and methanol on a filter. The obtained solid was purified by silica gel column chromatography (toluene and ethyl acetate were mixed), thereby obtaining 0.17 g of a yellow solid (exemplary compound F-1) (yield: 23%).

Further, the exemplary compound F-1 was subjected to mass spectrometry using MALDI-TOF-MS (Autoflex LRF, manufactured by Bruker).

### [MALDI-TOF-MS]

Measured value: m/z=771, calculated value: C₄₂H₃₂IrN₃=771

### Comparative Example 1

A compound g-2 was synthesized in the same manner as in “(1) synthesis of compound f-3” of Example 1 except that the raw material f-2 was changed to a raw material g-1 shown in the following scheme. However, the target object g-2 could not be obtained. The reason for this is considered to be steric hindrance between the phenyl group of the pyridine ring and the methyl group of the fluorene ring.

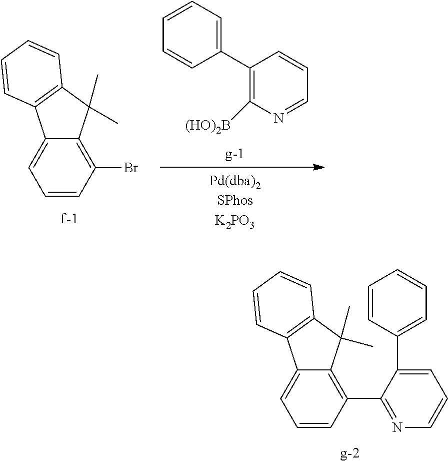 [SMILES: CC1(C)c2ccccc2-c2cccc(Br)c21 ; OB(O)c1ncccc1-c1ccccc1 ; CC1(C)c2ccccc2-c2cccc(-c3ncccc3-c3ccccc3)c21]

### Examples 2 to 20 (Synthesis of Exemplary Compounds)

As listed in Tables 3 to 5, exemplary compounds were synthesized in the same manner as in Example 1 except that the raw material f-1, the raw material f-2, and the raw material f-4 of Example 1 were respectively changed to the raw material 1, the raw material 2, and the raw material 3 in the exemplary compounds shown in Examples 2 to 20. Further, the measured values (m/z) as the results of mass spectrometry measured in the same manner as in Example 1 are listed in Tables 3 to 5.

TABLE 3

| | Exemplary | | Raw material | | |
|---|---|---|---|---|---|
| Example | compound | Raw material 1 | 2 | Raw material 3 | m/z |
| 2 | D-1 | 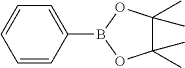 | 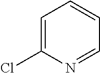 | 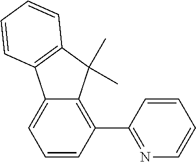 [SMILES: CC1(C)c2ccccc2-c2cccc(-c3ccccn3)c21] | 887 |
| 3 | D-2 | 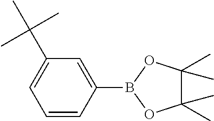 [SMILES: CC(C)(C)c1cccc(B2OC(C)(C)C(C)(C)O2)c1] | 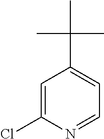 | 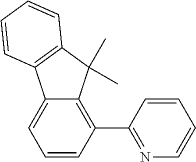 [SMILES: CC1(C)c2ccccc2-c2cccc(-c3ccccn3)c21] | 999 |
| 4 | D-4 | 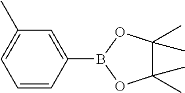 [SMILES: Cc1cccc(B2OC(C)(C)C(C)(C)O2)c1] | 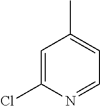 | 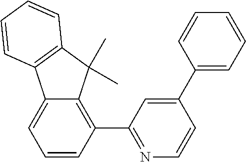 [SMILES: CC1(C)c2ccccc2-c2cccc(-c3cc(-c4ccccc4)ccn3)c21] | 915 |
| 5 | E-1 | 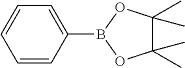 | 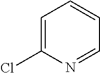 | 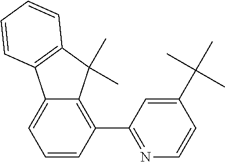 [SMILES: CC(C)(C)c1ccnc(-c2cccc3c2C(C)(C)c2ccccc2-3)c1] | 999 |
| 6 | E-2 | 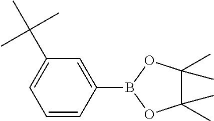 [SMILES: CC(C)(C)c1cccc(B2OC(C)(C)C(C)(C)O2)c1] | 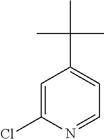 | 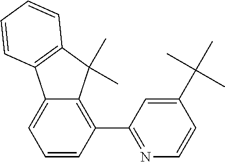 [SMILES: CC(C)(C)c1ccnc(-c2cccc3c2C(C)(C)c2ccccc2-3)c1] | 1111 |
| 7 | E-5 | 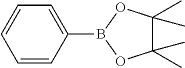 | 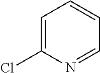 | 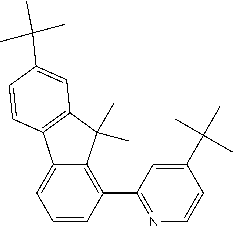 [SMILES: CC(C)(C)c1ccnc(-c2cccc3c2C(C)(C)c2cc(C(C)(C)C)ccc2-3)c1] | 1111 |

TABLE 4

| | Exemplary | | | | |
|---|---|---|---|---|---|
| Example | compound | Raw material 1 | Raw material 2 | Raw material 3 | m/z |
| 8 | F-2 | 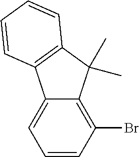 [SMILES: CC1(C)c2ccccc2-c2cccc(Br)c21] | 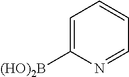 | 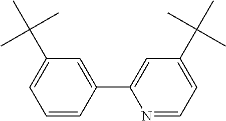 [SMILES: CC(C)(C)c1cccc(-c2cc(C(C)(C)C)ccn2)c1] | 995 |
| 9 | F-3 | 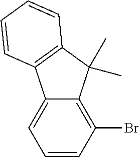 [SMILES: CC1(C)c2ccccc2-c2cccc(Br)c21] | 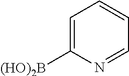 | 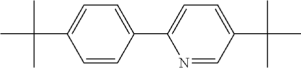 [SMILES: CC(C)(C)c1ccc(-c2ccc(C(C)(C)C)cn2)cc1] | 995 |
| 10 | F-7 | 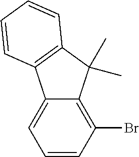 [SMILES: CC1(C)c2ccccc2-c2cccc(Br)c21] | 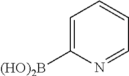 | 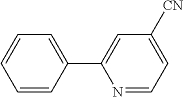 [SMILES: N#Cc1ccnc(-c2ccccc2)c1] | 821 |
| 11 | G-1 | 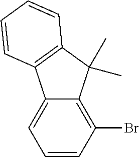 [SMILES: CC1(C)c2ccccc2-c2cccc(Br)c21] | 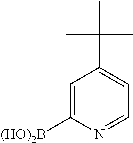 | 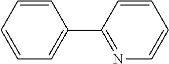 [SMILES: c1ccc(-c2ccccn2)cc1] | 827 |
| 12 | G-2 | 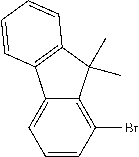 [SMILES: CC1(C)c2ccccc2-c2cccc(Br)c21] | 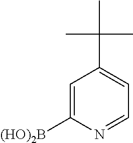 | 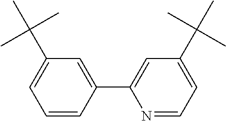 [SMILES: CC(C)(C)c1cccc(-c2cc(C(C)(C)C)ccn2)c1] | 1052 |
| 13 | G-3 | 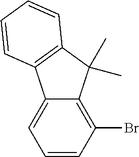 [SMILES: CC1(C)c2ccccc2-c2cccc(Br)c21] | 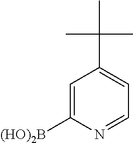 | 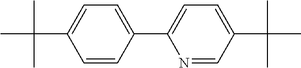 [SMILES: CC(C)(C)c1ccc(-c2ccc(C(C)(C)C)cn2)cc1] | 1052 |
| 14 | G-7 | 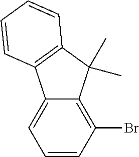 [SMILES: CC1(C)c2ccccc2-c2cccc(Br)c21] | 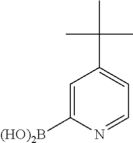 | 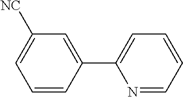 [SMILES: N#Cc1cccc(-c2ccccn2)c1] | 875 |

TABLE 5

| | Exemplary | | | | |
|---|---|---|---|---|---|
| Example | compound | Raw material 1 | \|Raw material 2 | Raw material 3 | m/z |
| 15 | J-2 | 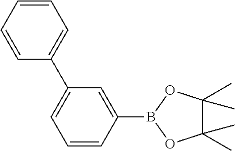 [SMILES: CC1(C)OB(c2cccc(-c3ccccc3)c2)OC1(C)C] | 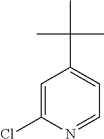 | 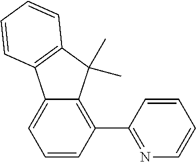 [SMILES: CC1(C)c2ccccc2-c2cccc(-c3ccccn3)c21] | 1006 |
| 16 | J-10 | 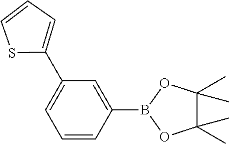 [SMILES: CC1(C)OB(c2cccc(-c3cccs3)c2)OC1(C)C] | 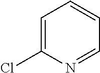 | 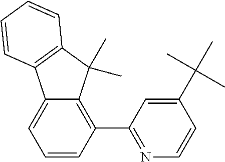 [SMILES: CC(C)(C)c1ccnc(-c2cccc3c2C(C)(C)c2ccccc2-3)c1] | 969 |
| 17 | J-16 | 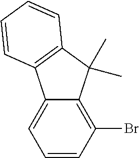 [SMILES: CC1(C)c2ccccc2-c2cccc(Br)c21] | 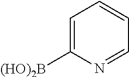 | 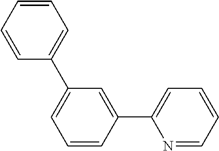 [SMILES: c1ccc(-c2cccc(-c3ccccn3)c2)cc1] | 923 |
| 18 | J-17 | 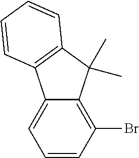 [SMILES: CC1(C)c2ccccc2-c2cccc(Br)c21] | 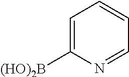 | 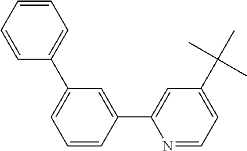 [SMILES: CC(C)(C)c1ccnc(-c2cccc(-c3ccccc3)c2)c1] | 1035 |
| 19 | J-19 | 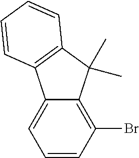 [SMILES: CC1(C)c2ccccc2-c2cccc(Br)c21] | 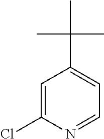 | 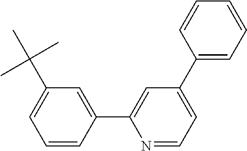 [SMILES: CC(C)(C)c1cccc(-c2cc(-c3ccccc3)ccn2)c1] | 1092 |
| 20 | J-22 | 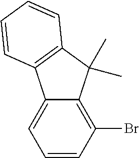 [SMILES: CC1(C)c2ccccc2-c2cccc(Br)c21] | 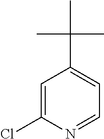 | 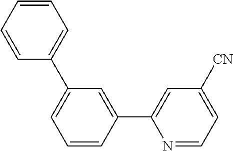 [SMILES: N#Cc1ccnc(-c2cccc(-c3ccccc3)c2)c1] | 1018 |

### Example 21 (Synthesis of Exemplary Compound D-11)

An exemplary compound D-11 was synthesized according to the following scheme.

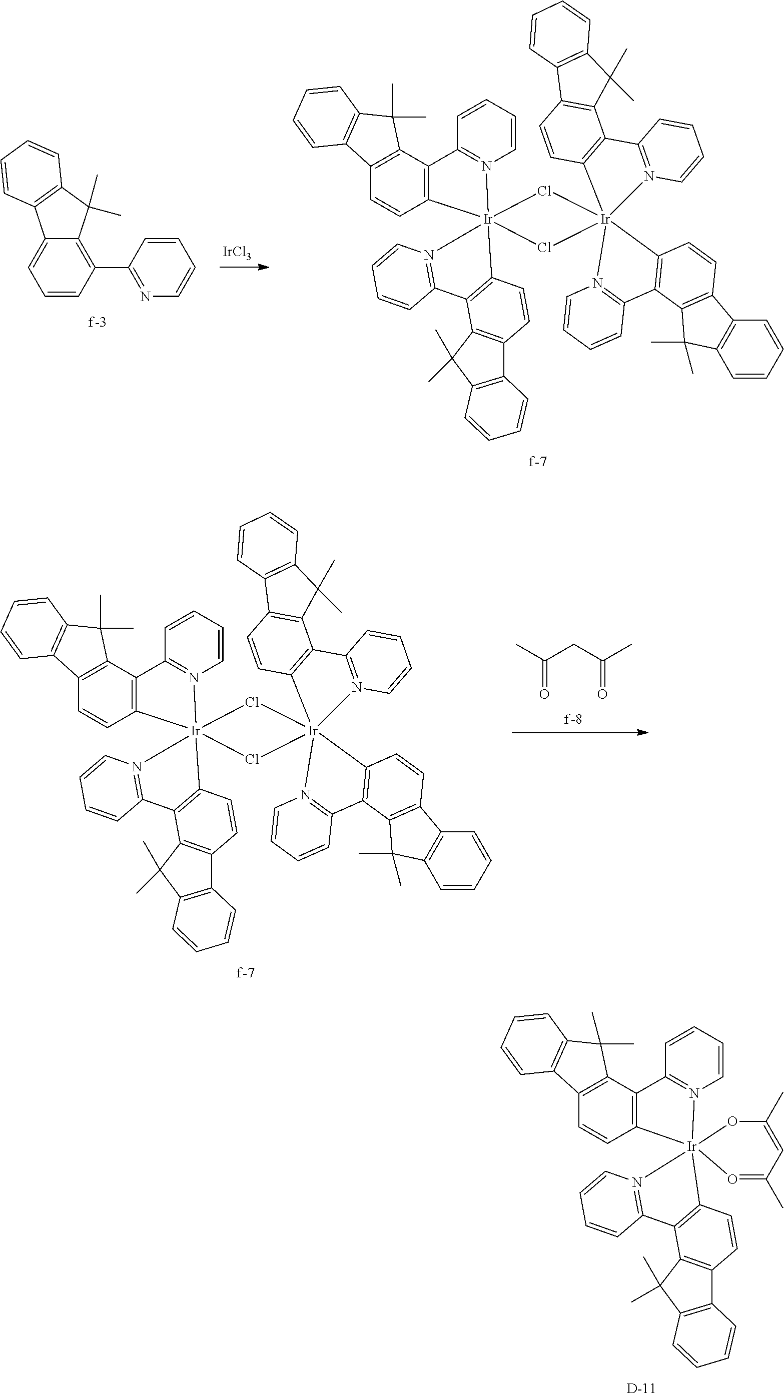

### (1) Synthesis of Compound f-7

A 100 ml eggplant flask was charged with reagents and solvents described below.
Compound f-3: 5.42 g (20.0 mmol)
Iridium chloride hydrate: 1.60 g
Ethoxyethanol: 45 ml
Water: 15 ml

Next, the reaction solution was heated and stirred at 130° C. for 5 hours in a nitrogen gas stream. After completion of the reaction, the reaction solution was filtered, and the obtained solid was washed with water and methanol on a filter, thereby obtaining 3.8 g of a yellow solid (f-7) (yield: 49%).

### (2) Synthesis of Exemplary Compound D-11

A 100 ml eggplant flask was charged with reagents and solvents described below.
Compound f-7: 1.54 g (1.00 mmol)
Compound f-8: 0.40 g (4.00 mmol)
Sodium carbonate: 1.06 g (10.0 mmol)
Ethoxyethanol: 30 ml
Water: 12 ml

Next, the reaction solution was heated and stirred at 100° C. for 6 hours in a nitrogen gas stream. After the solution was cooled, methanol was added thereto, and the resulting solution was filtered and washed with methanol, thereby obtaining 0.37 g of a yellow solid (D-11) (yield: 45%).

The exemplary compound D-11 was subjected to mass spectrometry in the same manner as in Example 1.

### [MALDI-TOF-MS]

Measured value: m/z=832, calculated value: C₄₅H₃₉IrO₂N₃=832

### Examples 22 to 26 (Synthesis of Exemplary Compounds)

As listed in Table 6, exemplary compounds were synthesized in the same manner as in Example 21 except that the raw material f-3 and the raw material f-8 of Example 21 were respectively changed to the raw material 1 and the raw material 2 in the exemplary compounds shown in Examples 22 to 26. Further, the measured values (m/z) as the results of mass spectrometry measured in the same manner as in Example 21 are listed in Table 6.

TABLE 6

| | Exemplary | | | |
|---|---|---|---|---|
| Example | compound | Raw material 1 | Raw material 2 | m/z |
| 22 | D-12 | 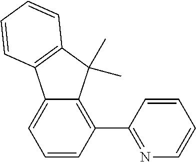 [SMILES: CC1(C)c2ccccc2-c2cccc(-c3ccccn3)c21] | 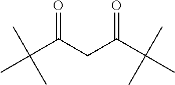 | 916 |
| 23 | D-14 | 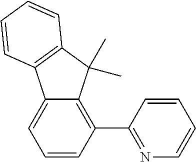 [SMILES: CC1(C)c2ccccc2-c2cccc(-c3ccccn3)c21] | 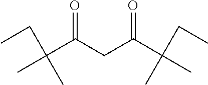 | 944 |
| 24 | G-11 | 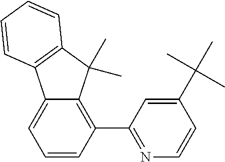 [SMILES: CC(C)(C)c1ccnc(-c2cccc3c2C(C)(C)c2ccccc2-3)c1] | 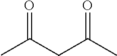 | 944 |
| 25 | G-12 | 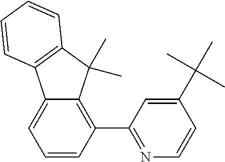 [SMILES: CC(C)(C)c1ccnc(-c2cccc3c2C(C)(C)c2ccccc2-3)c1] | 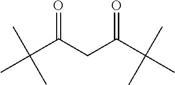 | 996 |
| 26 | G-15 | 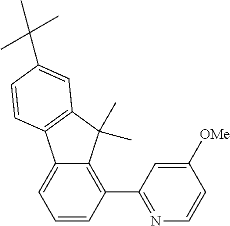 [SMILES: COc1ccnc(-c2cccc3c2C(C)(C)c2cc(C(C)(C)C)ccc2-3)c1] | 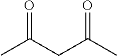 | 944 |

### Example 27 (Synthesis of Exemplary Compound H-1)

An exemplary compound H-1 was synthesized according to the following scheme.

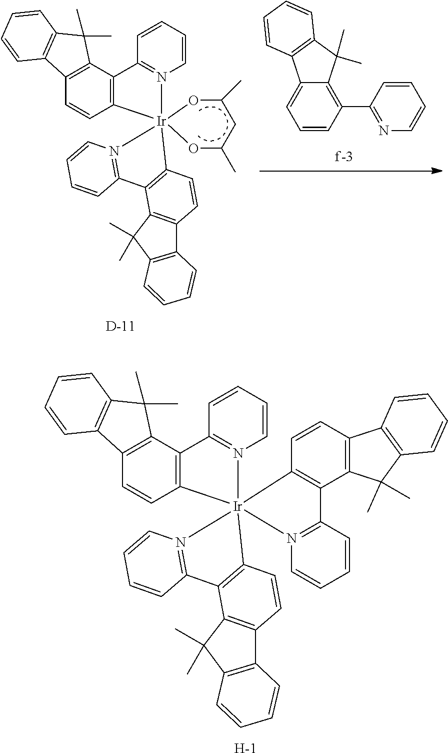

A 100 ml eggplant flask was charged with reagents and solvents described below.
Compound D-11: 0.83 g (1.00 mmol)
Compound f-3: 0.68 g (2.50 mmol)
Sodium carbonate: 1.06 g (10.0 mmol)
Glycerol: 30 ml

Next, the reaction solution was heated and stirred at 180° C. for 6 hours in a nitrogen gas stream. After the solution was cooled, methanol was added thereto, and the resulting solution was filtered and washed with methanol. The obtained solid was purified by silica gel column chromatography (toluene and ethyl acetate were mixed), thereby obtaining 0.17 g of a yellow solid (exemplary compound H-1) (yield: 17%).

The exemplary compound H-1 was subjected to mass spectrometry in the same manner as in Example 1.

### [MALDI-TOF-MS]

Measured value: m/z=1,003, calculated value: C₆₀H₄₀IrN₃=1,003

### Examples 28 and 29 (Synthesis of Exemplary Compounds)

As listed in Table 5, exemplary compounds were synthesized in the same manner as in Example 27 except that the raw material D-11 and the raw material f-3 of Example 27 were respectively changed to the raw material 1 and the raw material 2 in the exemplary compounds shown in Examples 28 and 29. Further, the measured values (m/z) as the results of mass spectrometry measured in the same manner as in Example 27 are listed in Table 7.

TABLE 7

| | Exemplary | Raw material | | |
|---|---|---|---|---|
| Example | compound | 1 | Raw material 2 | m/z |
| 28 | I-1 | E-11 | 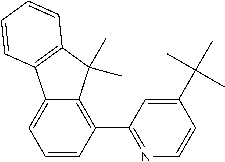 [SMILES: CC(C)(C)c1ccnc(-c2cccc3c2C(C)(C)c2ccccc2-3)c1] | 1172 |
| 29 | I-3 | E-15 | 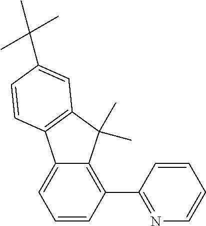 [SMILES: CC(C)(C)c1ccc2c(c1)C(C)(C)c1c(-c3ccccn3)cccc1-2] | 1172 |

### Example 30

An organic light emitting element having a bottom emission type structure, in which an anode, a positive hole injection layer, a positive hole transport layer, an electron blocking layer, a light emitting layer, a positive hole blocking layer, an electron transport layer, an electron injection layer, and a cathode were formed in this order on a substrate, was prepared.

First, an ITO electrode (anode) was formed by forming an ITO film on a glass substrate and performing desired patterning processing. Here, the film thickness of the ITO electrode was set to 100 nm. The following step was performed by using the substrate on which the ITO electrode had been formed in the above-described manner as an ITO substrate. Next, vacuum deposition was performed by resistance heating in a vacuum chamber at 1.3×10⁻⁴ Pa, and an organic compound layer and an electrode layer listed in Table 8 were continuously formed on the ITO substrate. At this time, the electrode area of the opposing electrodes (the metal electrode layer and the cathode) was set to 3 mm².

TABLE 8

| | | | Film |
|---|---|---|---|
| | | | thickness |
| | Material | | (nm) |
| Cathode | Al | | 100 |
| Electron injection layer (EIL) | LiF | | 1 |
| Electron transport layer (ETL) | ET2 | | 20 |
| Positive hole blocking layer (HBL) | ET10 | | 20 |
| Light emitting layer (EML) | Host | Dopant | 30 |
| | material | material | |
| | Q-1-23 | D-1 | |
| Mass ratio (%) in light emitting layer | 85 | 15 | |

| | | |
|---|---|---|
| Electron blocking layer (EBL) | HT7 | 15 |
| Positive hole transport layer (HTL) | HT2 | 20 |
| Positive hole injection layer (HIL) | HT16 | 5 |

The characteristics of the obtained element were measured and evaluated. The efficiency of the light emitting element was 61 cd/A. Further, a continuous driving test was performed at a current density of 50 mA/cm², and the time when the brightness deterioration rate reached 5% was measured. In Examples 31 to 37 and Comparative Examples 2 to 5, the time when the brightness deterioration rate reached 5% is expressed as a rate when the time of the present example was set to 1.0

In the present example, specifically, the current voltage characteristics were measured using a microammeter 4140B (manufactured by Hewlett-Packard Company) and the light emission brightness was measured using BM7 (manufactured by Topcon Corporation) as a measuring device.

### Examples 31 to 37 and Comparative Examples 2 to 5

Organic light emitting elements were prepared by the same method as in Example 30 except that the materials were appropriately changed to the materials listed in Table 9. Further, a compound Q-2-1, a compound T-1, and a compound T-2 are compounds shown below.

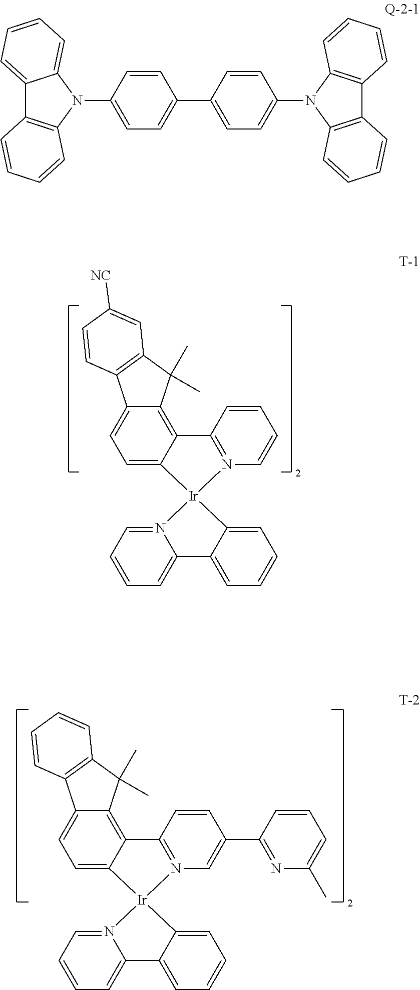

The obtained elements were evaluated in the same manner as in Example 30. The time when the bright deterioration rate reached 5% is expressed as the rate when the time of Example 30 was set to 1.0. The measurement results are listed in Table 9.

TABLE 9

| | |
|---|---|
| EML | Brightness |

| | Host | Dopant | Efficiency | deterioration |
|---|---|---|---|---|
| | material | material | Cd/A | rate |
| Example 31 | Q-1-23 | D-2 | 60 | 1.1 |
| Example 32 | Q-1-23 | E-1 | 59 | 1.0 |
| Example 33 | Q-1-16 | F-1 | 58 | 1.2 |
| Example 34 | Q-1-10 | F-2 | 60 | 1.1 |
| Example 35 | Q-1-19 | G-1 | 60 | 1.0 |
| Example 36 | Q-1-23 | J-16 | 59 | 0.7 |
| Example 37 | Q-1-19 | J-17 | 60 | 0.7 |
| Comparative | Q-1-23 | T-1 | 54 | 0.4 |
| Example 2 | | | | |
| Comparative | Q-1-22 | T-2 | 54 | 0.4 |
| Example 3 | | | | |
| Comparative | Q-2-1 | D-1 | 56 | 0.2 |
| Example 4 | | | | |
| Comparative | HT19 | D-2 | 53 | 0.3 |
| Example 5 | | | | |

As listed in Table 9, it was found that the light emitting elements of the examples exhibited light emission with high efficiency and showed less brightness deterioration. In the light emitting elements of Comparative Examples 2 and 3, since the light emitting dopant had a cyano group or a pyridyl group in the pyridylfluorene ligand, the polarity of the ligand was high, the interaction between the dopant and the host material which was a hydrocarbon was weak, the emission efficiency was poor, and the brightness deterioration was significant. In the light emitting elements of Comparative Examples 4 and 5, since the host material had atoms with high polarity, such as a nitrogen atom and an oxygen atom, the interaction between the host material and the compound represented by General Formula [1] according to the present embodiment was weak, the emission efficiency was low, the stability of the host material was poor, and thus the brightness deterioration was significant.

As described above, an element with high efficiency and excellent durability can be provided by using the compound represented by General Formula [1] according to the present embodiment as the light emitting dopant and selecting a preferable host material.

### Example 38

An organic light emitting element was prepared by the same method as in Example 30 except that the compound and the film thickness were changed as listed in Table 10.

TABLE 10

| | | | | Film |
|---|---|---|---|---|
| | | | | thickness |
| | Material | | | (nm) |
| Cathode | Al | | | 100 |
| Electron injection layer (EIL) | LiF | | | 1 |
| Electron transport layer (ETL) | ET2 | | | 20 |
| Positive hole blocking layer | ET10 | | | 20 |
| (HBL) | | | | |
| Light emitting layer (EML) | Host | Assist | Dopant | 30 |
| | material | material | material | |
| | Q-1-23 | S-1-25 | E-1 | |
| Mass ratio (%) in light emitting | 60 | 30 | 10 | |
| layer | | | | |

| | | |
|---|---|---|
| Electron blocking layer (EBL) | HT7 | 15 |
| Positive hole transport layer | HT2 | 20 |
| (HTL) | | |
| Positive hole injection layer | HT16 | 5 |
| (HIL) | | |

The obtained element was evaluated in the same manner as in Example 30. The efficiency of the light emitting element was 63 cd/A. Further, in Examples 39 to 43 and Comparative Examples 6 to 8, the time when the bright deterioration rate reached 5% is expressed as the rate when the time of the present example was set to 1.0.

### Examples 39 to 43 and Comparative Examples 6 to 8

Organic light emitting elements were prepared by the same method as in Example 38 except that the materials were appropriately changed to the materials listed in Table 11. Further, a compound 0-2-1, a compound Q-2-2, and a compound S-4-1 are compounds shown below.

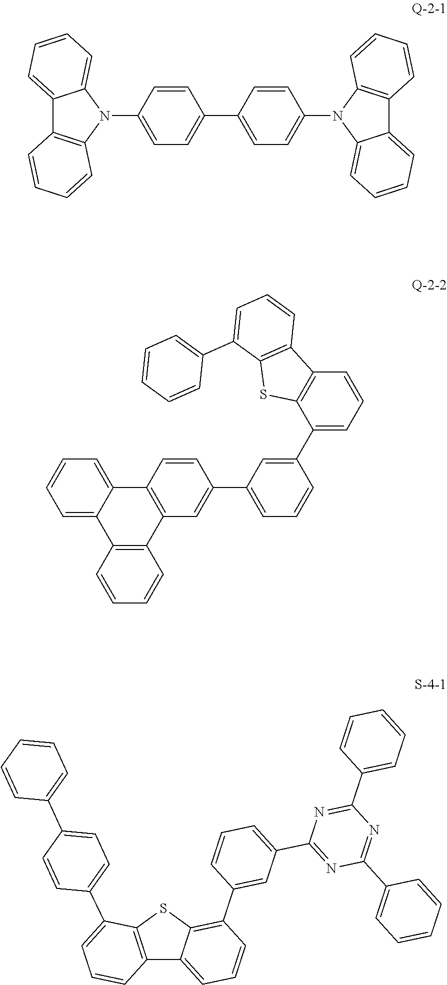 [SMILES: c1ccc2c(c1)c1ccccc1n2-c1ccc(-c2ccc(-n3c4ccccc4c4ccccc43)cc2)cc1 ; c1ccc(-c2cccc3c2sc2c(-c4cccc(-c5ccc6c7ccccc7c7ccccc7c6c5)c4)cccc23)cc1 ; c1ccc(-c2ccc(-c3cccc4c3sc3c(-c5cccc(-c6nc(-c7ccccc7)nc(-c7ccccc7)n6)c5)cccc34)cc2)cc1]

The obtained elements were evaluated in the same manner as in Example 38. The time when the bright deterioration rate reached 5% is expressed as the rate when the time at which the brightness deterioration rate of Example 38 reached 5% was set to 1.0. The measurement results are listed in Table 11.

TABLE 11

| | EML | | | | Brightness |
|---|---|---|---|---|---|
| | Host | Assist | Dopant | Efficiency | deterioration |
| | material | material | material | Cd/A | rate |
| Example 38 | Q-1-22 | S-1-25 | E-2 | 62 | 1.0 |
| Example 39 | Q-1-18 | S-1-25 | F-1 | 63 | 1.1 |
| Example 40 | Q-1-17 | S-1-4 | G-1 | 62 | 1.0 |
| Example 41 | Q-1-10 | S-2-2 | G-2 | 61 | 1.1 |
| Example 42 | Q-1-40 | S-2-8 | J-16 | 60 | 0.8 |
| Comparative | Q-2-1 | S-1-25 | E-2 | 58 | 0.2 |
| Example 6 | | | | | |
| Comparative | Q-2-2 | S-4-1 | G-1 | 55 | 0.5 |
| Example 7 | | | | | |
| Comparative | Q-2-2 | S-4-1 | J-16 | 55 | 0.3 |
| Example 8 | | | | | |

As listed in Table 11, it was found that the light emitting elements of the examples exhibited light emission with high efficiency and showed less brightness deterioration. In the light emitting elements of Comparative Examples 6 to 8, since the light emitting dopant had atoms with high polarity, such as a nitrogen atom and an oxygen atom, the interaction between the host material and the compound represented by General Formula [1] according to the present embodiment was weak, the emission efficiency was low, the stability of the host material was poor, and thus the brightness deterioration was significant. Further, in the light emitting elements of Comparative Examples 7 and 8, the emission efficiency was poorer. Since the light emitting elements had the assist material in the triazine skeleton, an exciplex was considered to be formed with the compound represented by General Formula [1] according to the present embodiment.

As described above, an element with high efficiency and excellent durability can be provided by using the compound represented by General Formula [1] according to the present embodiment as the light emitting dopant and selecting a preferable host material.

According to the present disclosure, it is possible to provide an organic light emitting element with high color purity and excellent emission efficiency and an organic compound.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

1. An organic light emitting element comprising:
an anode;
a light emitting layer; and
a cathode in this order,
wherein the light emitting layer contains at least a dopant material and a host material,
the dopant material is a compound represented by Formula [1], and
the host material is a hydrocarbon, 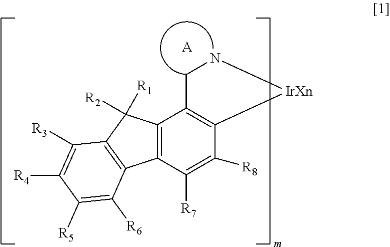
in Formula [1], R₁ to R₈ are each independently selected from the group consisting of a hydrogen atom, a deuterium atom, a substituted or unsubstituted alkyl group, a substituted or unsubstituted silyl group, and a substituted or unsubstituted aryl group, where R₁ to R₈ do not represent a cyano group,
m represents an integer of 1 or greater and 3 or less, and n represents an integer of 0 or greater and 2 or less, where m+n is 3,
X represents a bidentate ligand, and a partial structure IrX is any one of structures represented by Formulae [2] and [3], 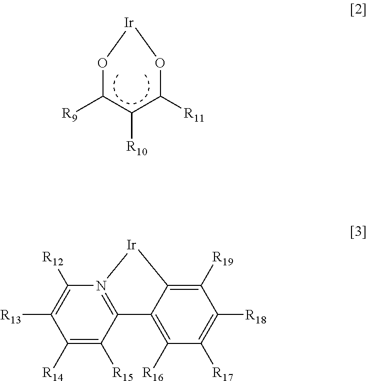
in Formulae [2] and [3], R₉ to R₁₉ are each independently selected from the group consisting of a hydrogen atom, a deuterium atom, a halogen atom, a cyano group, a substituted or unsubstituted alkyl group, a substituted or unsubstituted alkoxy group, a substituted or unsubstituted silyl group, a substituted or unsubstituted aryl group, and a substituted or unsubstituted heterocyclic group, R₁₆ to R₁₉ adjacent to each other may be bonded to each other to form a ring,
a ring A has any one of structures represented by Formulae [4] to [7], 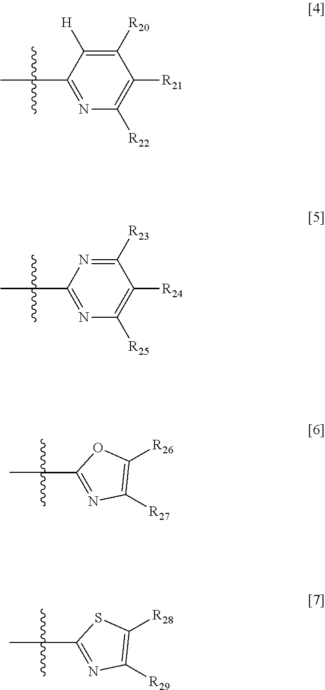
in Formulae [4] to [7], R₂₀ to R₂₉ are each independently selected from the group consisting of a hydrogen atom, a deuterium atom, a halogen atom, a cyano group, a substituted or unsubstituted alkyl group, a substituted or unsubstituted alkoxy group, a substituted or unsubstituted silyl group, and a substituted or unsubstituted aryl group.

2. The organic light emitting element according to claim 1,
wherein at least one of R₁ to R₈ represents a tertiary alkyl group.

3. The organic light emitting element according to claim 2,
wherein the tertiary alkyl group is a tertiary butyl group.

4. The organic light emitting element according to claim 1,
wherein the ring A has a structure represented by Formula [4].

5. The organic light emitting element according to claim 4,
wherein R₂₀ represents a tertiary butyl group.

6. The organic light emitting element according to claim 1,
wherein the partial structure IrX is a structure represented by Formula [3], and R₁₂ to R₁₉ are each independently selected from the group consisting of a hydrogen atom, a deuterium atom, a substituted or unsubstituted alkyl group, and a substituted and unsubstituted silyl group.

7. The organic light emitting element according to claim 1,
wherein at least one of Ry to R₁ or at least one of R₁₂ to R₁₉ represents a tertiary alkyl group.

8. The organic light emitting element according to claim 7,
wherein the tertiary alkyl group is a tertiary butyl group.

9. The organic light emitting element according to claim 1,
wherein the host material contains, in a skeleton, at least any one member selected from the group consisting of fluoranthene, benzo[e]pyrene, benzo[g]chrysene, benzo[c]chrysene, coronene, benzofluorene, chrysene, picene, naphthalene, phenanthrene, triphenylene, and fluorene.

10. The organic light emitting element according to claim 1,
wherein the host material contains at least any one member selected from the group consisting of a chrysene ring, a picene ring, a phenanthrene ring, a triphenylene ring, and a fluoranthene ring in a skeleton.

11. The organic light emitting element according to claim 1,
Wherein the host material does not have SP³ carbon.

12. The organic light emitting element according to claim 1,
wherein the light emitting layer contains an assist material.

13. The organic light emitting element according to claim 12,
wherein the assist material is a compound partially having any of the following structures, 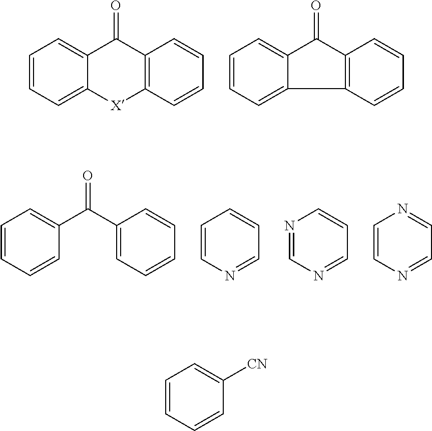
in the structures, X′ represents any of an oxygen atom, a sulfur atom, or a substituted or unsubstituted carbon atom.

14. An organic compound which is represented by Formula [1], 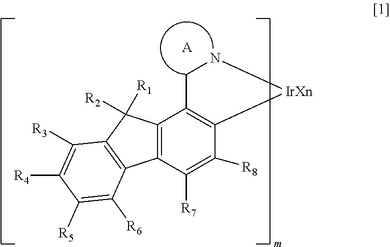
in Formula [1], R₁ to R₈ are each independently selected from the group consisting of a hydrogen atom, a deuterium atom, a substituted or unsubstituted alkyl group, a substituted or unsubstituted silyl group, and a substituted or unsubstituted aryl group, where at least one of R₁ to R₈ represents a tertiary alkyl group,
m represents an integer of 1 or greater and 3 or less, and n represents an integer of 0 or greater and 2 or less, where m+n is 3,
X represents a bidentate ligand, and a partial structure IrX is any one of structures represented by Formulae [2] and [3], 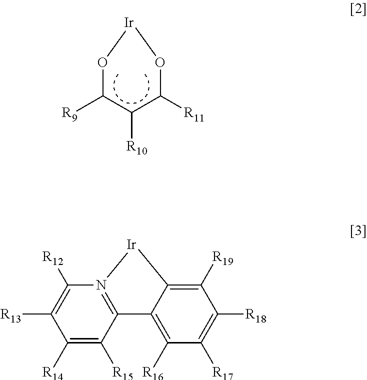
in Formulae [2] and [3], R₉ to R₁₉ are each independently selected from the group consisting of a hydrogen atom, a deuterium atom, a halogen atom, a cyano group, a substituted or unsubstituted alkyl group, a substituted or unsubstituted alkoxy group, a substituted or unsubstituted silyl group, a substituted or unsubstituted aryl group, and a substituted or unsubstituted heterocyclic group, R₁₆ to R₁₉ adjacent to each other may be bonded to each other to form a ring,
a ring A has any one of structures represented by Formulae [4] to [7], 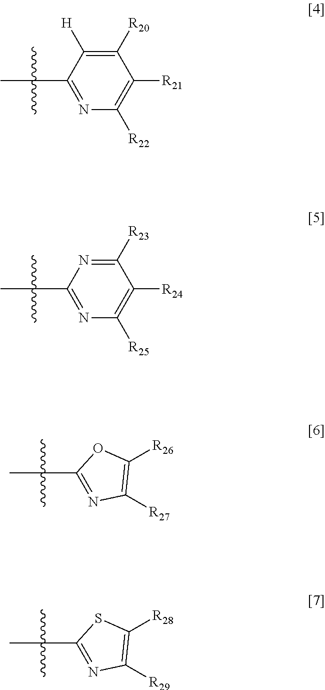
in Formulae [4] to [7], R₂₀ to R₂₉ are each independently selected from the group consisting of a hydrogen atom, a deuterium atom, a halogen atom, a cyano group, a substituted or unsubstituted alkyl group, a substituted or unsubstituted alkoxy group, a substituted or unsubstituted silyl group, and a substituted or unsubstituted aryl group.

15. The organic compound according to claim 14,
wherein R₁ to R₈ do not represent a cyano group.

16. The organic compound according to claim 14,
wherein the tertiary alkyl group is a tertiary butyl group.

17. The organic compound according to claim 14,
wherein the ring A has a structure represented by Formula [4].

18. The organic compound according to claim 17,
wherein R₂₀ represents a tertiary butyl group.

19. The organic compound according to claim 14,
wherein the partial structure IrX is a structure represented by Formula [3], and R₁₂ to R₁₉ are each independently selected from the group consisting of a hydrogen atom, a deuterium atom, a substituted or unsubstituted alkyl group, and a substituted or unsubstituted silyl group.

20. The organic compound according to claim 14,
wherein at least one of Ry to Ru or at least one of R₁₂ to R₁₉ represents a tertiary alkyl group.

21. The organic compound according to claim 20,
wherein the tertiary alkyl group is a tertiary butyl group.

22. A display device comprising:
a plurality of pixels,
wherein at least one of the plurality of pixels includes the organic light emitting element according to claim 1 and a transistor connected to the organic light emitting element.

23. A photoelectric conversion device comprising:
an optical unit that includes a plurality of lenses;
an imaging element that receives light allowed to pass through the optical unit; and
a display unit that displays an image captured by the imaging element,
wherein the display unit includes the organic light emitting element according to claim 1.

24. An electronic device comprising:
a display unit that includes the organic light emitting element according to claim 1;
a housing where the display unit is provided; and
a communication unit that is provided in the housing and communicates with an outside.

25. A lighting device comprising:
a light source that includes the organic light emitting element according to claim 1; and
a light diffusion unit or an optical filter that transmits light emitted by the light source.

26. A moving body comprising:
a lamp that includes the organic light emitting element according to claim 1; and
a machine body where the lamp is provided.

27. An exposure light source of an electrophotographic image forming apparatus, comprising:
the organic light emitting element according to claim 1.
